(19) United States
(12) Patent Application Publication
(10) Pub. No.: US 2025/0048591 A1
(43) Pub. Date: Feb. 6, 2025

(54) VAPOR CHAMBER AND ELECTRONIC APPARATUS

(71) Applicant: DAI NIPPON PRINTING CO., LTD., Tokyo-to (JP)

(72) Inventors: Shinichiro TAKAHASHI, Tokyo-to (JP); Kazunori ODA, Tokyo-to (JP); Takayuki OTA, Tokyo-to (JP); Makoto YAMAKI, Tokyo-to (JP); Youji KOZURU, Tokyo-to (JP); Toshihiko TAKEDA, Tokyo-to (JP); Shinya KIURA, Tokyo-to (JP); Takayuki TERAUCHI, Tokyo-to (JP); Naohiro TAKAHASHI, Tokyo-to (JP)

(73) Assignee: DAI NIPPON PRINTING CO., LTD., Tokyo-to (JP)

(21) Appl. No.: 18/717,091

(22) PCT Filed: Dec. 6, 2022
(86) PCT No.: PCT/JP2022/044874

§ 371 Date: Jun. 6, 2024

(30) Foreign Application Priority Data
Dec. 6, 2021 (JP) 2021-198039
Dec. 16, 2021 (JP) 2021-204523
Dec. 22, 2021 (JP) 2021-208635
Feb. 25, 2022 (JP) 2022-028635
Sep. 30, 2022 (WO) PCT/JP2022/036767
Nov. 11, 2022 (WO) PCT/JP2022/042105

(51) Int. Cl. H05K 7/20; F28D 15/02

(52) U.S. Cl. CPC H05K 7/2029; F28D 15/0233

(57) ABSTRACT

A vapor chamber includes a body sheet, and a first sheet stacked on the body sheet. The body sheet includes a vapor flow channel portion through which vapor of a working fluid flows and a liquid flow channel portion which is in communication with the vapor flow channel portion and through which liquid of the working fluid flows. The vapor flow channel portion includes a vapor passage extending in a first direction. The first sheet includes a first sheet inner surface facing the body sheet and a first sheet groove provided in the first sheet inner surface. The first sheet groove is provided at a position of overlapping with the vapor passage in a plan view and extends in a direction intersecting with the first direction.

### TECHNICAL FIELD

The present disclosure relates to a vapor chamber and an electronic apparatus.

### BACKGROUND ART

Devices that involve heat generation such as central processing units (CPUs), light emitting diodes (LED), and power semiconductors used for mobile terminals and the like, including portable terminals and tablet terminals, are cooled by heat dissipation members such as heat pipes (see, for example, Patent Literatures 1 and 2). In recent years, for the purpose of providing thinner mobile terminals and the like, low-profile heat dissipation members are also demanded and, therefore, development of vapor chambers that can offer a further lower profile than heat pipes has been proceeding. A working fluid is enclosed in a vaper chamber. The working fluid absorbs and diffuses the heat of a device inside the vapor chamber, thereby cooling the device.

More specifically, the working fluid in the vapor chamber receives heat from the device at a portion that is proximate to the device (vaporizing portion) to turn into vapor (working vapor). The working vapor diffuses in a direction of going away from the vaporizing portion inside a vapor flow channel portion to cool and thus condense into liquid (working liquid). A liquid flow channel portion serving as a capillary structure (wick) is provided inside the vapor chamber. The working liquid enters the liquid flow channel portion from the vapor flow channel portion, flows through the liquid flow channel portion, and goes toward the vaporizing portion. Then, the working liquid vaporizes by receiving heat at the vaporizing portion again. In this way, the working fluid transfers the heat of the device by circulating inside the vapor chamber while repeating phase changes, that is, vaporization and condensation, thus enhancing heat dissipation efficiency.

### CITATION LIST

### Patent Literature

PTL 1: Japanese Unexamined Patent Application Publication No. 2018-204841
PTL 2: Japanese Patent No. 6877513

### SUMMARY OF INVENTION

### Technical Problem

An object of the present disclosure is to provide a vapor chamber and an electronic apparatus capable of improving heat dissipation efficiency.

### Solution to Problem

A first mode of the present disclosure is a vapor chamber in which a working fluid is enclosed, including: a body sheet; and a first sheet stacked on the body sheet, wherein the body sheet includes a vapor flow channel portion through which vapor of the working fluid flows and a liquid flow channel portion which is in communication with the vapor flow channel portion and through which liquid of the working fluid flows, the vapor flow channel portion includes a vapor passage extending in a first direction, and the first sheet includes a first sheet inner surface facing the body sheet and a first sheet groove provided in the first sheet inner surface, the first sheet groove is provided at a position of overlapping with the vapor passage in a plan view and extends in a direction intersecting with the first direction.

As a second mode of the present disclosure, in the vapor chamber according to the first mode described above, the liquid flow channel portion may include a liquid flow channel mainstream groove extending in the first direction, and a cross-sectional passage area of the first sheet groove may be smaller than a cross-sectional passage area of the liquid flow channel mainstream groove.

As a third mode of the present disclosure, in the vapor chamber according to the first mode described above, the liquid flow channel portion may include a liquid flow channel mainstream groove extending in the first direction, and a cross-sectional passage area of the first sheet groove may be larger than a cross-sectional passage area of the liquid flow channel mainstream groove.

As a fourth mode of the present disclosure, in the vapor chamber according to each of the first to third modes described above, the first sheet groove may be provided also over a position of overlapping with the liquid flow channel portion in a plan view.

As a fifth mode of the present disclosure, in the vapor chamber according to the fourth mode described above, the first sheet groove may be provided so as to traverse the vapor passage in the direction intersecting with the first direction.

As a sixth mode of the present disclosure, in the vapor chamber according to the fourth mode described above, the first sheet groove may include a first end portion provided at a position of overlapping with the vapor passage in a plan view and a second end portion provided at a position of overlapping with the liquid flow channel portion in a plan view.

As a seventh mode of the present disclosure, in the vapor chamber according to the fourth mode described above, the first sheet may include a plurality of first sheet grooves, and the plurality of first sheet grooves may include the first sheet groove provided so as to traverse the vapor chamber in the direction intersecting with the first direction and the first sheet groove including a first end portion provided at a position of overlapping with the vapor passage in a plan view and a second end portion provided at a position of overlapping with the liquid flow channel portion in a plan view.

As an eighth mode of the present disclosure, in the vapor chamber according to each of the sixth and seventh modes described above, the first sheet groove may be formed in such a way as to have a decreasing cross-sectional passage area from the second end portion toward the first end portion.

As a ninth mode of the present disclosure, in the vapor chamber according to each of the sixth and seventh modes described above, the first sheet groove may be formed in such a way as to have a decreasing cross-sectional passage area from the first end portion toward the second end portion.

As a tenth mode of the present disclosure, in the vapor chamber according to each of the sixth to ninth modes described above, the first sheet groove may be disposed in an inclined manner with respect to the first direction in a plan view.

As an eleventh mode of the present disclosure, in the vapor chamber according to each of the sixth to tenth modes described above, the first sheet may include a plurality of first sheet grooves, and the plural first sheet grooves may be arranged in a radial layout in a plan view.

As a twelfth mode of the present disclosure, in the vapor chamber according to each of the first to eleventh modes described above, the first sheet may include a plurality of first sheet grooves and a communication groove providing communication between the first sheet grooves located next to each other.

As a thirteenth mode of the present disclosure, in the vapor chamber according to each of the first to twelfth modes described above, the body sheet may include a first body surface facing the first sheet inner surface and a second body surface located at a side opposite of the first body surface, and the liquid flow channel portion may be provided in the first body surface.

As a fourteenth mode of the present disclosure, the vapor chamber according to the thirteenth mode described above may further include a second sheet stacked on the second body surface of the body sheet, wherein the liquid flow channel portion may be provided also in the second body surface, and the second sheet may include a second sheet inner surface facing the second body surface and a second sheet groove provided in the second sheet inner surface, the second sheet groove is provided at a position of overlapping with the vapor passage in a plan view and extends in the direction intersecting with the first direction.

As a fifteenth mode of the present disclosure, the vapor chamber according to each of the first to fourteenth modes described above may include a depressed region where the first sheet is depressed toward the vapor passage, and the first sheet groove may be located at the depressed region.

As a sixteenth mode of the present disclosure, in the vapor chamber according to each of the first to fifteenth modes described above, the body sheet may include a plurality of lands and a coupling portion, the liquid flow channel portion being provided in the plurality of lands, the plurality of lands extending in the first direction, the plurality of lands being arranged in a second direction orthogonal to the first direction, the coupling portion coupling the lands located next to each other, and the first sheet groove may be provided at a position of facing the coupling portion.

As a seventeenth mode of the present disclosure, in the vapor chamber according to each of the first to sixteenth modes described above, the body sheet may include a plurality of lands and a coupling portion, the liquid flow channel portion being provided in the plurality of lands, the plurality of lands extending in the first direction, the plurality of lands being arranged in a second direction orthogonal to the first direction, the coupling portion coupling the lands located next to each other, and the first sheet groove may be provided at a region adjacent to the coupling portion in the first direction in a plan view.

As an eighteenth mode of the present disclosure, the vapor chamber according to each of the first to seventeenth modes described above may include a bending region where the vapor chamber is bent along a bending line, and the first sheet groove may be located at the bending region.

A nineteenth mode of the present disclosure is a vapor chamber in which a working fluid is enclosed, including: a body sheet including a first body surface and a second body surface located at a side opposite of the first body surface; a first sheet located at the first body surface of the body sheet; a second sheet located at the second body surface of the body sheet; and a space portion provided in the body sheet and covered by the first sheet and the second sheet, wherein the body sheet includes a plurality of lands located inside the space portion and extending in a first direction, the second sheet includes a second sheet outer surface located at an opposite side facing away from the body sheet, the vapor chamber includes a bending region where the vapor chamber is bent along a bending line extending in a direction intersecting with the first direction in a plan view, and a second sheet outer surface recess is located in the second sheet outer surface at the bending region.

As a twentieth mode of the present disclosure, in the vapor chamber according to the nineteenth mode described above, the second sheet may be located at an inner side of a bending relative to the body sheet.

As a twenty-first mode of the present disclosure, in the vapor chamber according to each of the nineteenth and twentieth modes described above, the second sheet outer surface recess may extend along the bending line and traverse the space portion.

As a twenty-second mode of the present disclosure, in the vapor chamber according to the twenty-first mode described above, a plurality of second sheet outer surface recesses may be located in the second sheet outer surface at the bending region, and the plural second sheet outer surface recesses may be arranged in the first direction.

As a twenty-third mode of the present disclosure, in the vapor chamber according to each of the nineteenth and twentieth modes described above, a plurality of second sheet outer surface recesses may be located in the second sheet outer surface at the bending region, the plural second sheet outer surface recesses may be arranged along the bending line, and at least some of the plural second sheet outer surface recesses may overlap with the space portion.

As a twenty-fourth mode of the present disclosure, in the vapor chamber according to each of the nineteenth to twenty-third modes described above, the bending line may extend in a direction orthogonal to the first direction in a plan view.

As a twenty-fifth mode of the present disclosure, in the vapor chamber according to each of the nineteenth to twenty-third modes described above, the bending line may extend in a direction inclined with respect to the first direction.

As a twenty-sixth mode of the present disclosure, in the vapor chamber according to each of the nineteenth to twenty-fifth modes described above, the first sheet may include a first sheet outer surface located at an opposite side facing away from the body sheet, and a first sheet outer surface recess may be located in the first sheet outer surface at the bending region.

As a twenty-seventh mode of the present disclosure, in the vapor chamber according to each of the nineteenth to twenty-sixth modes described above, a land recess may be located in the first body surface or the second body surface of the land, the land recess may be in non-communication with the space portion, and the land recess may overlap with the second sheet outer surface recess.

As a twenty-eighth mode of the present disclosure, in the vapor chamber according to the twenty-seventh mode described above, the land recess may extend to both sides in the first direction beyond the second sheet outer surface recess.

A twenty-ninth mode of the present disclosure is a vapor chamber in which a working fluid is enclosed, including: a body sheet including a first body surface and a second body surface located at a side opposite of the first body surface; a first sheet located at the first body surface of the body sheet; a second sheet located at the second body surface of the body sheet; and a space portion provided in the body sheet and covered by the first sheet and the second sheet, wherein the body sheet includes a plurality of lands located inside the space portion and extending in a first direction, the second sheet includes a second sheet outer surface located at an opposite side facing away from the body sheet, the vapor chamber is divided into a first region, a second region, and a third region located between the first region and the second region in the first direction, and a second sheet outer surface recess is located in the second sheet outer surface at the third region.

As a thirtieth mode of the present disclosure, in the vapor chamber according to the twenty-ninth mode described above, the second sheet outer surface recess may extend in a direction intersecting with the first direction in a plan view, and traverse the space portion.

As a thirty-first mode of the present disclosure, in the vapor chamber according to the twenty-ninth mode described above, a plurality of second sheet outer surface recesses may be located in the second sheet outer surface at the third region, the plural second sheet outer surface recesses may be arranged in the direction intersecting with the first direction, and at least some of the plural second sheet outer surface recesses may overlap with the space portion.

A thirty-second mode of the present disclosure is an electronic apparatus, including: a housing; a device housed in the housing, and the vapor chamber according to any one of the first to thirty-first modes described above, said vapor chamber being thermally in contact with the device.

### Advantageous Effects of Invention

With the present disclosure, it is possible to improve heat dissipation efficiency.

### BRIEF DESCRIPTION OF DRAWINGS

FIG. 1 is a schematic perspective view for explaining an electronic apparatus according to a first embodiment.

FIG. 2 is a top view illustrating a vapor chamber according to the first embodiment.

FIG. 3 is a cross-sectional view taken along a line A-A of FIG. 2.

FIG. 4 is a top view of a lower sheet illustrated in FIG. 3.

FIG. 5 is a bottom view of an upper sheet illustrated in FIG. 3.

FIG. 6 is a top view of a wick sheet illustrated in FIG. 3.

FIG. 7 is a partially enlarged cross-sectional view for FIG. 3.

FIG. 8 is a top view for FIG. 7.

FIG. 9 is a partially enlarged bottom view for FIG. 5 at a position corresponding to FIG. 8.

FIG. 10 is a partially enlarged top view of the vapor chamber illustrated in FIG. 2 at a position where the wick sheet illustrated in FIG. 8 overlaps with the upper sheet illustrated in FIG. 9.

FIG. 11 is a cross-sectional view taken along a line B-B of FIG. 10.

FIG. 12 is a variation example of FIG. 7.

FIG. 13 is a variation example of FIG. 10.

FIG. 14 is a variation example of FIG. 9.

FIG. 15 is another variation example of FIG. 9.

FIG. 16 is another variation example of FIG. 9.

FIG. 17 is a variation example of FIG. 11.

FIG. 18 is another variation example of FIG. 11.

FIG. 19 is another variation example of FIG. 11.

FIG. 20 is another variation example of FIG. 11.

FIG. 21 is a partially enlarged top view illustrating a vapor chamber according to a second embodiment.

FIG. 22 is a variation example of FIG. 21.

FIG. 23 is a partially enlarged top view illustrating a vapor chamber according to a third embodiment.

FIG. 24 is a partially enlarged top view illustrating a vapor chamber according to a fourth embodiment.

FIG. 25 is a partially enlarged top view illustrating a vapor chamber according to a fifth embodiment.

FIG. 26 is a partially enlarged top view illustrating a vapor chamber according to a sixth embodiment.

FIG. 27 is a partially enlarged top view illustrating a vapor chamber according to a seventh embodiment.

FIG. 28 is a variation example of FIG. 27.

FIG. 29 is another variation example of FIG. 27.

FIG. 30 is a partially enlarged top view illustrating a vapor chamber according to an eighth embodiment.

FIG. 31 is a variation example of FIG. 30.

FIG. 32 is a partially enlarged top view illustrating a vapor chamber according to a ninth embodiment.

FIG. 33 is a variation example of FIG. 32.

FIG. 34 is another variation example of FIG. 32.

FIG. 35 is a partially enlarged cross-sectional view illustrating a vapor chamber according to a tenth embodiment.

FIG. 36 is a partially enlarged cross-sectional view illustrating a vapor chamber according to an eleventh embodiment.

FIG. 37 is a partially enlarged cross-sectional view illustrating a vapor chamber according to a twelfth embodiment.

FIG. 38 is a partially enlarged top view illustrating a vapor chamber according to a thirteenth embodiment.

FIG. 39 is a top view illustrating a vapor chamber according to a fourteenth embodiment.

FIG. 40 is a side view illustrating a vapor chamber bent along a bending line illustrated in FIG. 39.

FIG. 41 is a variation example of FIG. 3.

FIG. 42 is a schematic view illustrating an example of a vapor chamber according to a fifteenth embodiment.

FIG. 43 is a schematic view illustrating another example of a vapor chamber according to the fifteenth embodiment.

FIG. 44 is an external perspective view illustrating a vapor chamber according to the fifteenth embodiment.

FIG. 45 is a plan view of the vapor chamber illustrated in FIG. 42 before being bent.

FIG. 46 is a cross-sectional view taken along a line AA-AA of FIG. 45.

FIG. 47 is a plan view illustrating an inner surface of a first sheet illustrated in FIG. 46.

FIG. 48 is a plan view illustrating an inner surface of a second sheet illustrated in FIG. 46.

FIG. 49 is a cross-sectional view taken along a line BB-BB of FIG. 48.

FIG. 50 is a partially enlarged plan view illustrating a variation example of a second sheet outer surface recess illustrated in FIG. 45.

FIG. 51 is a variation example of FIG. 49.

FIG. 52 is another variation example of FIG. 49.

FIG. 53 is another variation example of FIG. 49.

FIG. 54 is another variation example of FIG. 49.

FIG. 55 is a plan view illustrating a first body surface of a wick sheet illustrated in FIG. 46.

FIG. 56 is a plan view illustrating a second body surface of the wick sheet illustrated in FIG. 46.

FIG. 57 is a partially enlarged cross-sectional view for FIG. 46.

FIG. 58 is a partially enlarged view of a liquid flow channel portion illustrated in FIG. 55.

FIG. 59 is a rough cross-sectional view illustrating a bending region of the vapor chamber illustrated in FIG. 44.

FIG. 60 is a partially enlarged plan view illustrating a variation example of the second sheet outer surface recess illustrated in FIG. 45.

FIG. 61 is a variation example of FIG. 60.

FIG. 62 is another variation example of FIG. 60.

FIG. 63 is another variation example of FIG. 60.

FIG. 64 is a rough cross-sectional view illustrating a variation example of the bending region of the vapor chamber illustrated in FIG. 59.

FIG. 65 is a partially enlarged plan view illustrating a variation example of the vapor chamber illustrated in FIG. 45.

FIG. 66 is a cross-sectional view taken along a line CC-CC of FIG. 65.

FIG. 67 is an external perspective view illustrating a vapor chamber according to a sixteenth embodiment.

FIG. 68 is a plan view of the vapor chamber illustrated in FIG. 67 before being bent.

FIG. 69 is a partially enlarged cross-sectional view illustrating a vapor chamber according to a seventeenth embodiment.

FIG. 70 is a partially enlarged plan view illustrating second sheet outer surface recesses and land recesses illustrated in FIG. 69.

### DESCRIPTION OF EMBODIMENTS

With reference to the drawings, an embodiment of the present disclosure will now be described. In the drawings attached to this specification, a scale and a dimensional aspect ratio, etc. will be altered from an actual scale/ratio, etc. in an exaggerated manner for easier illustration and easier understanding. Components, etc. illustrated in some drawings will sometimes be omitted in other drawings.

Terms that are used in this specification to specify shapes, geometric conditions, physical characteristics, and the degree thereof, for example, terms “parallel”, “perpendicular”, “same”, and the like and values of lengths, angles, physical characteristics, and the like, shall be construed each to encompass a range in which a similar function can be expected, without being limited to its strict sense.

In the drawings, for the sake of clarity, the shapes of a plurality of portions from which similar functions can be expected are illustrated in a regular manner; however, the shapes of the portions may be different from each other within a range in which the fulfillment of the function can be expected, without being limited to the strict sense. In the drawings, borderlines each representing a junction surface between members, etc. are indicated merely by straight lines for the sake of convenience; however, the borderlines are not limited to strict straight lines, and any shape of the borderline can be selected within a range in which desired junction performance can be expected, without being limited to the strict sense.

### First Embodiment

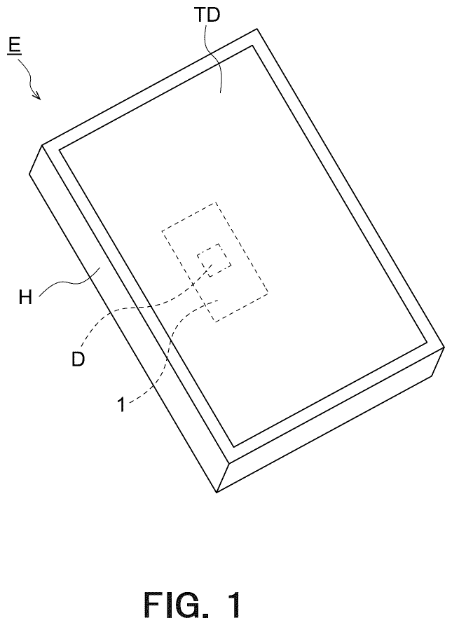

A vapor chamber and an electronic apparatus according to a first embodiment of the present disclosure will now be described with reference to FIGS. 1 to 12. A vapor chamber 1 according to the present embodiment is a gadget mounted in an electronic apparatus E so as to cool a device D (device to be cooled) that is a heat-producing entity housed in the electronic apparatus E. Examples of the electronic apparatus E include mobile terminals such as portable terminals and tablet terminals. Examples of the device D include electronic devices that involve heat generation such as central processing units (CPUs), light emitting diodes (LEDs), and power semiconductors.

First, the electronic apparatus E on which the vapor chamber 1 according to the present embodiment is mounted will be described here while taking a tablet terminal as an example. As illustrated in FIG. 1, the electronic apparatus E (tablet terminal) includes a housing H, the device D housed in the housing H, and the vapor chamber 1. In the electronic apparatus E illustrated in FIG. 1, a touch panel display TD is provided on the front face of the housing H. The vapor chamber 1 is housed in the housing H and is disposed in thermal contact with the device D. With this configuration, the vapor chamber 1 can receive heat generated in the device D during use of the electronic apparatus E. The heat received by the vapor chamber 1 is released to the outside of the vapor chamber 1 via a working fluid 2a, 2b to be described later. In this way, the device D is cooled effectively. In a case where the electronic apparatus E is a tablet terminal, the device D corresponds to a central processing unit or the like.

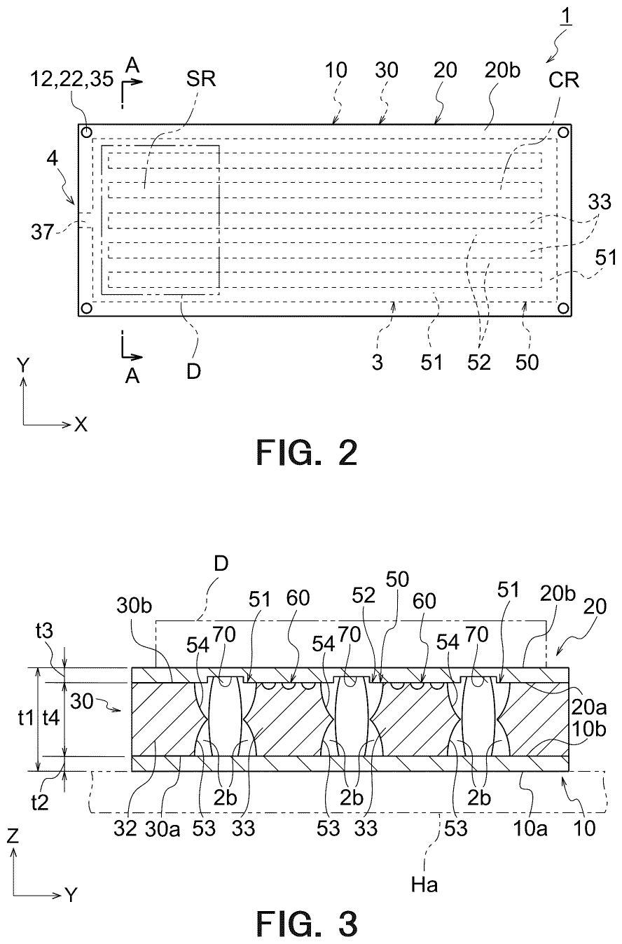

Next, the vapor chamber 1 according to the present embodiment will now be described. As illustrated in FIGS. 2 and 3, the vapor chamber 1 includes a sealed space 3 in which the working fluid 2a, 2b is enclosed. The vapor chamber 1 is configured to cool the device D of the electronic apparatus E described above by flowing throughout the sealed space 3 while repeating phase changes in the working fluid 2a, 2b. Examples of the working fluid 2a, 2b include pure water, ethanol, methanol, acetone, etc., and a mixed solution thereof.

As illustrated in FIGS. 2 and 3, the vapor chamber 1 includes a lower sheet 10 (second sheet), an upper sheet 20 (first sheet), and a wick sheet 30 (body sheet) sandwiched between the lower sheet 10 and the upper sheet 20. In the present embodiment, the vapor chamber 1 is made up of the lower sheet 10, the upper sheet 20, and the wick sheet 30. In the vapor chamber 1 according to the present embodiment, the lower sheet 10, the wick sheet 30, and the upper sheet 20 are stacked in this order. Though the wick sheet 30 has a structure of a single sheet in the example disclosed in the present embodiment, the wick sheet 30 may be made up of two sheets or more. The number of sheets making up the wick sheet 30 may be any number.

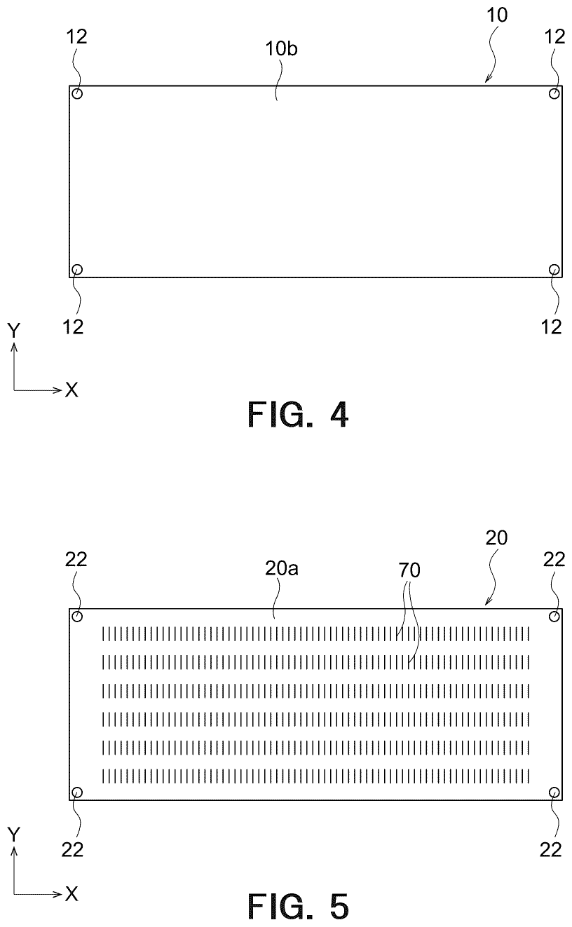

The vapor chamber 1, roughly speaking, has a thin flat plate-like shape. The planar shape of the vapor chamber 1, though not limited to any particular shape, may be a rectangular shape as illustrated in FIG. 2. For example, the planar shape of the vapor chamber 1 may be a rectangular shape with one side having a length of 10 mm or greater and 200 mm or less and the other side having a length of 50 mm or greater and 600 mm or less, or a square shape with one side having a length of 40 mm or greater and 300 mm or less. Its planar dimensions may be any dimensions. In the present embodiment, just as an example, an example in which the planar shape of the vapor chamber 1 is a rectangular shape having an X direction (first direction) as its longer-side direction and a Y direction (second direction) orthogonal to the X direction as its shorter-side direction will be described. In this case, as illustrated in FIGS. 4 to 6, the lower sheet 10, the upper sheet 20, and the wick sheet 30 may also have a planar shape similar to that of the vapor chamber 1. The planar shape of the vapor chamber 1 is not limited to a rectangular shape but may be any shape such as a circular shape, an elliptical shape, an L shape, a T shape, or a U shape.

As illustrated in FIG. 2, the vapor chamber 1 has a vaporization region SR where the working liquid 2b vaporizes and a condensation region CR where the working vapor 2a condenses. The working vapor 2a is a working fluid that is in a gaseous state, that is, vapor of the working fluid. The working liquid 2b is a working fluid that is in a liquid state, that is, liquid of the working fluid.

The vaporization region SR is a region that overlaps with the device D in a plan view and where the device D is to be mounted. The vaporization region SR may be located at any position on the vapor chamber 1. In the illustrated example, the vaporization region SR is formed on the negative side in the X direction (left side in FIG. 2) of the vapor chamber 1. Heat from the device D is transferred to the vaporization region SR, the working liquid 2b vaporizes due to the heat, and the working vapor 2a is thus generated. Heat from the device D can be transferred not only to the region that overlaps with the device D in a plan view but also to the neighborhood of this region. For this reason, the vaporization region SR includes the region that overlaps with the device D and the neighborhood of this region in a plan view.

The term “plan view” as used herein corresponds to a state of view in a direction orthogonal to a surface where the vapor chamber 1 receives heat from the device D and a surface where the received heat is released. In the present embodiment, the surface where the heat is received corresponds to an upper sheet outer surface 20b, which will be described later, of the upper sheet 20, and the surface where the heat is released corresponds to a lower sheet outer surface 10a, which will be described later, of the lower sheet 10. The surface where the heat is received may correspond to the lower sheet outer surface 10a. The surface where the heat is released may correspond to the upper sheet outer surface 20b. For example, as illustrated in FIG. 2, a state of view of the vapor chamber 1 from above or a state of view thereof from below corresponds to a plan view.

The condensation region CR is a region that does not overlap with the device D in a plan view and where, mainly, the working vapor 2a releases heat to condense. The condensation region CR may be paraphrased as a region located around the vaporization region SR. In the illustrated example, the condensation region CR is formed on the positive side in the X direction (right side in FIG. 2) of the vapor chamber 1. Heat from the working vapor 2a is released to the lower sheet 10 at the condensation region CR, the working vapor 2a cools to condense, and the working liquid 2b is thus generated.

When the vapor chamber 1 is installed in a mobile terminal, the upper/lower relation could be disrupted depending on the attitude of the mobile terminal. However, in the present embodiment, for the sake of convenience, the sheet that receives heat from the device D will be referred to as the upper sheet 20 described above, and the sheet that releases the received heat will be referred to as the lower sheet 10 described above. Therefore, the description will be given below while assuming a state where the lower sheet 10 is disposed on the lower side and the upper sheet 20 is disposed on the upper side.

As illustrated in FIG. 3, the lower sheet 10 includes the lower sheet outer surface 10a (second sheet outer surface) provided on the opposite side facing away from the wick sheet 30 and a lower sheet inner surface 10b (second sheet inner surface) facing the wick sheet 30. A housing member Ha, which constitutes a part of the housing H of a mobile terminal or the like, is mounted on the lower sheet outer surface 10a. The entirety of the lower sheet outer surface 10a may be covered by the housing member Ha. The lower sheet 10 may have a flat shape as a whole and may have a constant thickness as a whole.

As illustrated in FIG. 4, alignment holes 12 may be provided at four corners of the lower sheet 10. In the example illustrated in FIG. 4, the planar shape of the alignment hole 12 is a circle but is not limited thereto. The alignment holes 12 may go through the lower sheet 10.

As illustrated in FIG. 3, the upper sheet 20 includes an upper sheet inner surface 20a (first sheet inner surface) facing the wick sheet 30 and the upper sheet outer surface 20b (first sheet outer surface) provided on the side opposite of the upper sheet inner surface 20a. The device D described above is mounted on the upper sheet outer surface 20b. As illustrated in FIGS. 3 and 5, the upper sheet 20 includes upper sheet grooves 70 (first sheet groove) provided in the upper sheet inner surface 20a. A detailed description of the upper sheet groove 70 will be given later.

As illustrated in FIG. 5, alignment holes 22 may be provided at four corners of the upper sheet 20. In the example illustrated in FIG. 5, the planar shape of the alignment hole 22 is a circle but is not limited thereto. The alignment holes 22 may go through the upper sheet 20.

As illustrated in FIG. 3, the wick sheet 30 includes a wick sheet lower surface 30a (second body surface) and a wick sheet upper surface 30b (first body surface) provided on the side opposite of the wick sheet lower surface 30a. The wick sheet lower surface 30a faces the lower sheet inner surface 10b of the lower sheet 10. The wick sheet upper surface 30b faces the upper sheet inner surface 20a of the upper sheet 20.

The lower sheet inner surface 10b and the wick sheet lower surface 30a may be permanently bonded to each other by means of thermal compression bonding. Similarly, the upper sheet inner surface 20a and the wick sheet upper surface 30b may be permanently bonded to each other by means of thermal compression bonding. An example of thermal compression bonding is diffusion bonding. However, the lower sheet 10, the upper sheet 20, and the wick sheet 30 may be bonded using another technique such as brazing instead of diffusion bonding.

The term “permanently bonded” is not limited to its strict meaning but is used as a term that means bonding sufficient for keeping the hermetic property of the sealed space 3 when the vapor chamber 1 is operating.

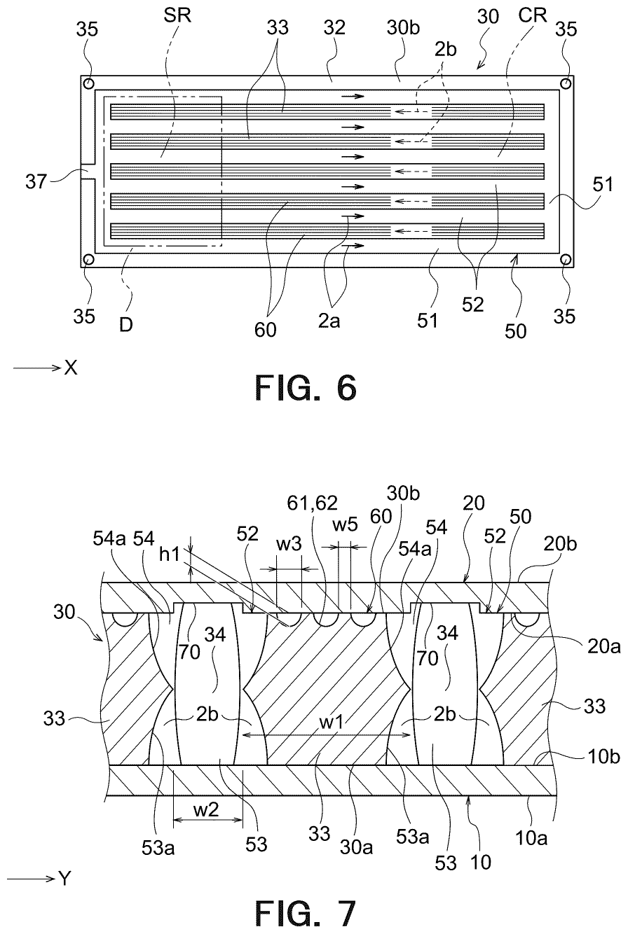

As illustrated in FIGS. 2 and 6, the wick sheet 30 includes a frame portion 32 and a plurality of lands 33 provided inside the frame portion 32. The frame portion 32 and the land portion 33 are portions where the material of the wick sheet 30 is left without being etched away in an etching process to be described later.

In the illustrated example, the frame portion 32 has a shape of a rectangular frame in a plan view. A vapor flow channel portion 50 is provided inside the frame portion 32. The vapor flow channel portion 50 contains the working fluid 2a, 2b. Each of the lands 33 is provided inside the frame portion 32. The vapor flow channel portion 50 is provided around each of the lands 33. Therefore, the working vapor 2a flows around each of the lands 33.

In the illustrated example, each of the lands 33 extends in the X direction (horizontal direction in FIG. 6). The planar shape of each of the lands 33 is an elongated rectangle. The lands 33 are arranged in the Y direction (vertical direction in FIG. 6) orthogonal to the X direction. The lands 33 may be arranged at predetermined intervals in the Y direction. The width w1 (see FIG. 7) of each of the lands 33 may be, for example, 100 μm to 3000 μm. The width w1 of the land 33 means the size of the land 33 in the Y direction, and means the size measured at a position in the Z direction where a penetrating-through portion 34 to be described later is located.

The X direction is defined as a direction in which each second vapor passage 52 of the vapor flow channel portion 50 to be described later extends. The Y direction is defined as a direction orthogonal to the X direction in a plan view. The Z direction is defined as a direction orthogonal to the X direction and the Y direction, and corresponds to the thickness direction of the wick sheet 30.

The frame portion 32 and each of the lands 33 are diffusion-bonded to the lower sheet 10 and the upper sheet 20. This enhances the mechanical strength of the vapor chamber 1. A wall surface 53a of a lower vapor flow channel recessed portion 53 to be described later and a wall surface 54a of an upper vapor flow channel recessed portion 54 to be described later constitute a sidewall of the land portion 33. The wick sheet lower surface 30a and the wick sheet upper surface 30b may be flat throughout the frame portion 32 and each of the lands 33.

As illustrated in FIG. 6, alignment holes 35 may be provided at four corners of the wick sheet 30. In the example illustrated in FIG. 6, the planar shape of the alignment hole 35 is a circle but is not limited thereto. The alignment holes 35 may go through the wick sheet 30.

The wick sheet 30 includes the vapor flow channel portion 50, through which the working vapor 2a flows, and a liquid flow channel portion 60, which is in communication with the vapor flow channel portion 50 and through which the working liquid 2b flows.

The vapor flow channel portion 50 is a channel through which, mainly, the working vapor 2a flows. The working liquid 2b may also flow through the vapor flow channel portion 50. As illustrated in FIGS. 3 and 7, the vapor flow channel portion 50 may span from the wick sheet lower surface 30a to the wick sheet upper surface 30b through the wick sheet 30. The vapor flow channel portion 50 may be covered by the lower sheet 10 at the wick sheet lower surface 30a and covered by the upper sheet 20 at the wick sheet upper surface 30b.

As illustrated in FIG. 6, the vapor flow channel portion 50 may include a first vapor passage 51 and a plurality of second vapor passages 52. The first vapor passage 51 is provided between the frame portion 32 and the land portion 33. The first vapor passage 51 is formed in a continuous manner inside the frame portion 32 and outside the land portion 33. The planar shape of the first vapor passage 51 is a rectangular frame. The second vapor passage 52 is formed between the lands 33 located next to each other. The second vapor passage 52 extends in the X direction. The planar shape of the second vapor passage 52 is an elongated rectangle. The vapor flow channel portion 50 is partitioned into the first vapor passage 51 and the plurality of second vapor passages 52 by the plurality of lands 33.

Though the vapor flow channel portion 50 includes the first vapor passage 51 in the present embodiment, the vapor flow channel portion 50 may be configured not to include the first vapor passage 51. That is, the frame portion 32 and the land portion 33 may be arranged in an adjacent manner, with no vapor passage provided between the frame portion 32 and the land portion 33.

As illustrated in FIGS. 3 and 7, the first vapor passage 51 and the second vapor passage 52 may span from the wick sheet lower surface 30a to the wick sheet upper surface 30b through the wick sheet 30. The first vapor passage 51 and the second vapor passage 52 include the lower vapor flow channel recessed portion 53, which is provided in the wick sheet lower surface 30a, and the upper vapor flow channel recessed portion 54, which is provided in the wick sheet upper surface 30b. The lower vapor flow channel recessed portion 53 and the upper vapor flow channel recessed portion 54 are formed to be in communication with each other such that the first vapor passage 51 and the second vapor passage 52 span from the wick sheet lower surface 30a to the wick sheet upper surface 30b.

The lower vapor flow channel recessed portion 53 is formed in a concave shape in the wick sheet lower surface 30a by etching the wick sheet 30 from the wick sheet lower surface 30a in an etching process to be described later. “Formed in a concave shape in the wick sheet lower surface 30a” means being formed in a recessed manner with respect to the wick sheet lower surface 30a. Due to this etching, as illustrated in FIG. 7, the lower vapor flow channel recessed portion 53 has the wall surface 53a that is curved. The wall surface 53a demarcates the lower vapor flow channel recessed portion 53, and is curved in such a way as to come closer to the opposed wall surface 53a as it goes toward the wick sheet upper surface 30b in the cross section illustrated in FIG. 7. As illustrated in FIGS. 3 and 7, the working liquid 2b could adhere to the wall surface 53a. The lower vapor flow channel recessed portion 53 having this configuration constitutes a part (a lower half) of the first vapor passage 51 and a part (a lower half) of the second vapor passage 52.

The upper vapor flow channel recessed portion 54 is formed in a concave shape in the wick sheet upper surface 30b by etching the wick sheet 30 from the wick sheet upper surface 30b in an etching process to be described later. “Formed in a concave shape in the wick sheet upper surface 30b” means being formed in a recessed manner with respect to the wick sheet upper surface 30b. Due to this etching, as illustrated in FIG. 7, the upper vapor flow channel recessed portion 54 has the wall surface 54a that is curved. The wall surface 54a demarcates the upper vapor flow channel recessed portion 54, and is curved in such a way as to come closer to the opposed wall surface 54a as it goes toward the wick sheet lower surface 30a in the cross section illustrated in FIG. 7. As illustrated in FIGS. 3 and 7, the working liquid 2b could adhere to the wall surface 54a. The upper vapor flow channel recessed portion 54 having this configuration constitutes a part (an upper half) of the first vapor passage 51 and a part (an upper half) of the second vapor passage 52.

As illustrated in FIG. 7, the wall surface 53a of the lower vapor flow channel recessed portion 53 and the wall surface 54a of the upper vapor flow channel recessed portion 54 are connected to each other to form the penetrating-through portion 34. In the illustrated example, the planar shape of the penetrating-through portion 34 in the first vapor passage 51 is a rectangular frame similar to that of the first vapor passage 51, and the planar shape of the penetrating-through portion 34 in the second vapor passage 52 is an elongated rectangle similar to that of the second vapor passage 52. The penetrating-through portion 34 may be defined by a ridgeline formed by the meeting of the wall surface 53a of the lower vapor flow channel recessed portion 53 and the wall surface 54a of the upper vapor flow channel recessed portion 54 in such a way as to protrude inward. At the penetrating-through portion 34, the planar area of the first vapor passage 51 may be the smallest, and the planar area of the second vapor passage 52 may be the smallest. The width w2 (see FIG. 7) of the penetrating-through portion 34 of each vapor passage 51, 52 may be, for example, 400 μm to 1600 μm. The width w2 of the penetrating-through portion 34 of the first vapor passage 51 corresponds to a gap between the lands 33 located next to each other in the Y direction. The width w2 of the penetrating-through portion 34 of the second vapor passage 52 corresponds to a gap between the frame portion 32 and the land portion 33 in the Y direction (or in the X direction).

The position of the penetrating-through portion 34 in the Z direction (vertical direction in FIG. 7) may be the center between the wick sheet lower surface 30a and the wick sheet upper surface 30b. However, this does not imply any limitation. The position thereof may be closer to the lower sheet 10 than the center. The position thereof may be closer to the upper sheet 20 than the center. The position of the penetrating-through portion 34 in the Z direction may be any position.

In the illustrated example, as described above, the cross-sectional shape of each of the first vapor passage 51 and the second vapor passage 52 includes the penetrating-through portion 34 defined by a ridgeline formed in such a way as to protrude inward. However, this does not imply any limitation. For example, the cross-sectional shape of the first vapor passage 51, and the cross-sectional shape of the second vapor passage 52, may be a trapezoid, a rectangle, or a barrel.

The vapor flow channel portion 50 including the first vapor passage 51 and the second vapor passages 52 configured as described above constitute a part of the sealed space 3 described above. As illustrated in FIG. 3, the first vapor passage 51 and the second vapor passages 52 are demarcated by, mainly, the lower sheet 10, the upper sheet 20, and the frame portion 32 and the land portion 33 of the wick sheet 30 described above. Each vapor passage 51, 52 has a relatively large cross-sectional passage area so that the working vapor 2a will flow.

In FIG. 3, for the sake of clarity, the first vapor passage 51, the second vapor passage 52, and the like are illustrated in an enlarged manner, and the number and layout of these vapor passages 51 and 52 and the like are different from those in FIGS. 2, 6 to 10, and the like.

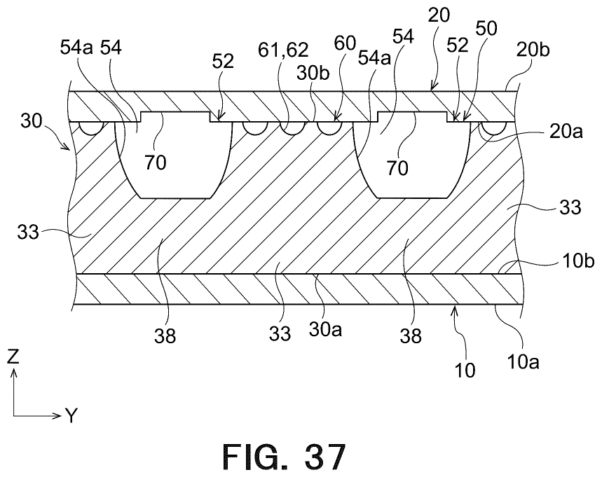

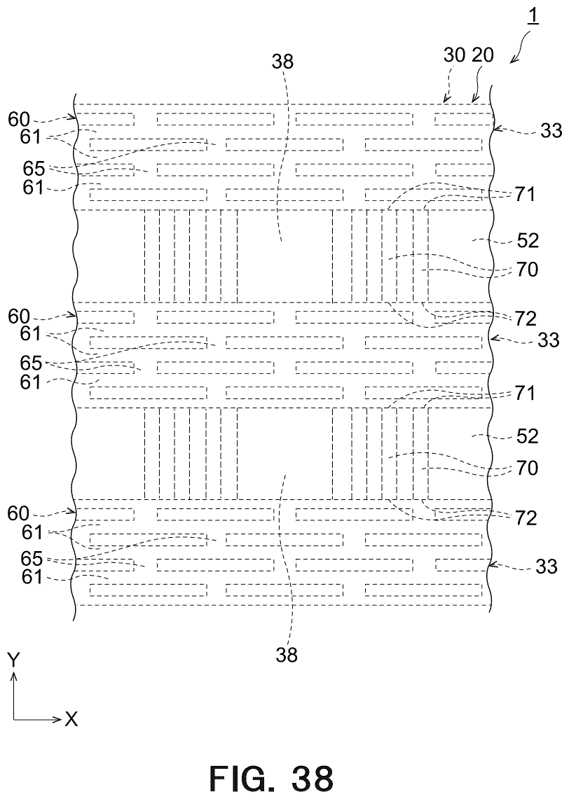

By the way, though not illustrated, a plurality of supports supporting the land portion 33 onto the frame portion 32 may be provided inside the vapor flow channel portion 50. A plurality of couplers 38 (see FIGS. 37 and 38) coupling the lands 33 located next to one another may be provided. The supports and the couplers 38 may be formed in such a way as not to obstruct the flow of the working vapor 2a diffusing in the vapor flow channel portion 50. For example, they may be located near either one, the wick sheet lower surface 30a of the wick sheet 30 or the wick sheet upper surface 30b thereof, and there may be a space that forms a vapor flow channel recessed portion near the other. This makes it possible to make the thickness of the supports and the couplers 38 less than the thickness of the wick sheet 30 and thus prevents the first vapor passage 51 and the second vapor passages 52 from being split in the X direction and the Y direction.

The liquid flow channel portion 60 is a channel through which, mainly, the working liquid 2b flows. The working vapor 2a may also flow through the liquid flow channel portion 60. As illustrated in FIGS. 3, 6, and 7, the liquid flow channel portion 60 may be provided in the wick sheet upper surface 30b of the wick sheet 30. In the illustrated example, the liquid flow channel portion 60 is provided in the wick sheet upper surface 30b at each of the lands 33. The liquid flow channel portion 60 constitutes a part of the sealed space 3 described above and is in communication with the vapor flow channel portion 50. The liquid flow channel portion 60 is configured as a capillary structure (wick) for sending the working liquid 2b to the vaporization region SR. The liquid flow channel portion 60 may be formed throughout the entirety of the wick sheet upper surface 30b at each of the lands 33. The liquid flow channel portion 60 may be formed in the wick sheet upper surface 30b at the frame portion 32.

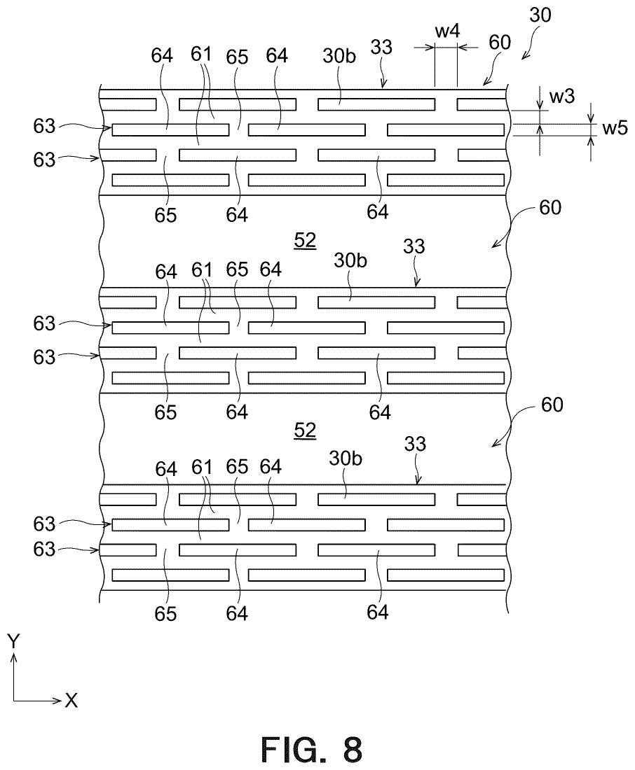

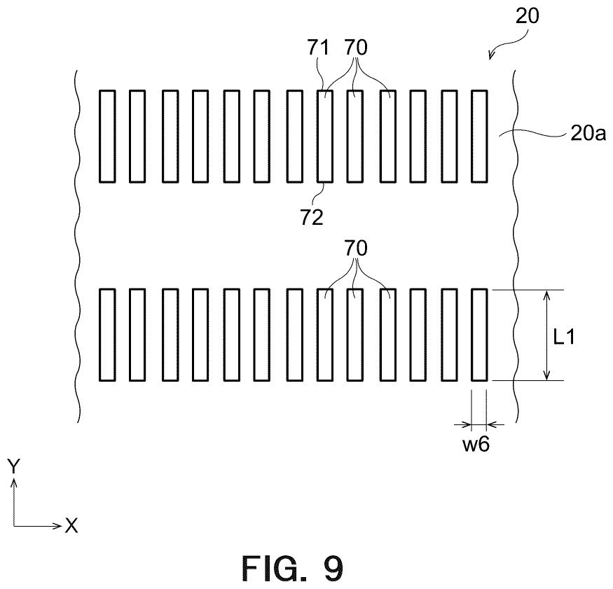

As illustrated in FIG. 8, the liquid flow channel portion 60 may be made up of a plurality of grooves provided in the wick sheet upper surface 30b. More specifically, the liquid flow channel portion 60 may include a plurality of liquid flow channel mainstream grooves 61, through which the working liquid 2b flows, and a plurality of liquid flow channel communication grooves 65, which are in communication with the liquid flow channel mainstream grooves 61.

As illustrated in FIG. 8, each of the liquid flow channel mainstream grooves 61 extends in the X direction. The liquid flow channel mainstream groove 61 has a small cross-sectional passage area so that, mainly, the working liquid 2b will flow by capillary action. The cross-sectional passage area of the liquid flow channel mainstream groove 61 is smaller than that of the vapor passage 51, 52. The liquid flow channel mainstream groove 61 is configured to send, to the vaporization region SR, the working liquid 2b having condensed from the working vapor 2a. The liquid flow channel mainstream grooves 61 may be arranged in the Y direction. The liquid flow channel mainstream grooves 61 may be arranged at predetermined intervals in parallel with one another.

The liquid flow channel mainstream grooves 61 may be formed by etching the wick sheet 30 from the wick sheet upper surface 30b in an etching step to be described later. Due to this etching, as illustrated in FIG. 7, the liquid flow channel mainstream groove 61 may have a wall surface 62 that is curved. The wall surface 62 may demarcate the liquid flow channel mainstream groove 61 and may be curved in a recessed manner toward the wick sheet lower surface 30a.

The width w3 (size in the Y direction) of the liquid flow channel mainstream groove 61 illustrated in FIGS. 7 and 8 is less than the width w2 of the penetrating-through portion 34 of the vapor passage 51, 52 and is less than the width w1 of the land 33. The width w3 of the liquid flow channel mainstream groove 61 may be, for example, 5 μm to 150 μm. The width w3 of the liquid flow channel mainstream groove 61 means the size measured at the wick sheet upper surface 30b. The depth h1 (size in the Z direction) of the liquid flow channel mainstream groove 61 illustrated in FIG. 7 may be, for example, 3 μm to 150 μm.

As illustrated in FIG. 8, each of the liquid flow channel communication grooves 65 extends in a direction intersecting with the X direction. In the illustrated example, each of the liquid flow channel communication grooves 65 extends in the Y direction and is formed perpendicularly to the liquid flow channel mainstream grooves 61. Some of the liquid flow channel communication grooves 65 provide communication between the liquid flow channel mainstream grooves 61 located next to each other. Others of the liquid flow channel communication grooves 65 provide communication between the first vapor passage 51 or the second vapor passage 52 and the liquid flow channel mainstream groove 61. That is, the latter of the liquid flow channel communication grooves 65 extends from an edge of the land portion 33 in the Y direction to the liquid flow channel mainstream groove 61 located next to the edge. In this way, the first vapor passage 51 is in communication with the liquid flow channel mainstream groove 61, and the second vapor passage 52 is in communication with the liquid flow channel mainstream groove 61.

The liquid flow channel communication groove 65 has a small cross-sectional passage area so that, mainly, the working liquid 2b will flow by capillary action. The cross-sectional passage area of the liquid flow channel communication groove 65 is smaller than that of the vapor passage 51, 52. The liquid flow channel communication grooves 65 may be arranged in the X direction. The liquid flow channel communication grooves 65 may be arranged at predetermined intervals in parallel with one another.

The liquid flow channel communication grooves 65 may also be formed using etching, similarly to the liquid flow channel mainstream grooves 61. Due to this etching, the liquid flow channel communication groove 65 may also have a wall surface (not illustrated) that is curved, similarly to the liquid flow channel mainstream groove 61. The width w4 (size in the X direction) of the liquid flow channel communication groove 65 illustrated in FIG. 8 is less than the width w2 of the penetrating-through portion 34 of the vapor passage 51, 52 and is less than the width w1 of the land 33. The width w4 of the liquid flow channel communication groove 65 may be equal to the width w3 of the liquid flow channel mainstream groove 61. However, this does not imply any limitation. The width w4 of the liquid flow channel communication groove 65 may be greater than, or less than, the width w3 of the liquid flow channel mainstream groove 61. The depth of the liquid flow channel communication groove 65 may be equal to the depth h1 of the liquid flow channel mainstream groove 61. However, this does not imply any limitation. The depth of the liquid flow channel communication groove 65 may be greater than, or less than, the depth h1 of the liquid flow channel mainstream groove 61.

As illustrated in FIG. 8, the liquid flow channel portion 60 may include liquid flow channel convex rows 63 provided in the wick sheet upper surface 30b. The liquid flow channel convex row 63 is provided between the liquid flow channel mainstream grooves 61 located next to each other. Each of the liquid flow channel convex rows 63 includes a plurality of liquid flow channel protrusions 64 arranged in the X direction. The liquid flow channel protrusions 64 are in contact with the upper sheet inner surface 20a. Each of the liquid flow channel protrusions 64 has a rectangular shape in a plan view, with its longer-side direction oriented in the X direction. The liquid flow channel mainstream groove 61 is disposed between the liquid flow channel protrusions 64 located next to each other in the Y direction. The liquid flow channel communication groove 65 is disposed between the liquid flow channel protrusions 64 located next to each other in the X direction.

The liquid flow channel protrusion 64 is a portion where the material of the wick sheet 30 is left without being etched away in an etching process to be described later. As illustrated in FIG. 8, the planar shape of the liquid flow channel protrusion 64 (shape at the position of the wick sheet upper surface 30b) may be a rectangle.

As illustrated in FIG. 8, the liquid flow channel protrusions 64 may be arranged in a staggered manner. More specifically, the liquid flow channel protrusions 64 of the liquid flow channel convex rows 63 located next to one another in the Y direction may be arranged in a manner of being shifted from one another in the X direction. The amount of this shift may be a half of the arrangement pitch of the liquid flow channel protrusions 64 in the X direction. The width w5 (size in the Y direction) of the liquid flow channel protrusion 64 illustrated in FIG. 8 may be, for example, 5 μm to 500 μm. The width w5 of the liquid flow channel protrusion 64 means the size measured at the wick sheet upper surface 30b. The width w5 of the liquid flow channel protrusion 64 corresponds to a gap between the liquid flow channel mainstream grooves 61 located next to each other in the Y direction. The layout of the liquid flow channel protrusions 64 is not limited to a staggered layout. An arranged-abreast layout may be adopted. In this case, the liquid flow channel protrusions 64 of the liquid flow channel convex rows 63 located next to each other in the Y direction are lined up in terms of X-directional position, too.

As illustrated in FIG. 2, the vapor chamber 1 may include an injection portion 4 for injecting the working liquid 2b into the sealed space 3. The position of the injection portion 4 may be any position. As illustrated in FIG. 2, the injection portion 4 may be provided at an edge on the negative side in the X direction (left side in FIG. 2) of the vapor chamber 1. The injection portion 4 may include an injection flow channel 37 formed in the wick sheet 30. The injection flow channel 37 may be sealed after the working liquid 2b is injected through itself.

The material of the lower sheet 10, the upper sheet 20, and the wick sheet 30 is not specifically limited as long as it has good thermal conductivity. For example, the lower sheet 10, the upper sheet 20, and the wick sheet 30 may contain copper or copper alloy. In this case, it is possible to make the thermal conductivity of each sheet 10, 20, 30 high and make the heat dissipation efficiency of the vapor chamber 1 high. Moreover, this makes it possible to prevent corrosion in a case where pure water is used as the working fluid 2a, 2b. Any other metal material such as aluminum or titanium or any other metal alloy material such as stainless may be used for these sheets 10, 20, and 30 as long as desired heat dissipation efficiency can be attained in addition to anticorrosion.

The thickness t1 of the vapor chamber 1 illustrated in FIG. 3 may be, for example, 100 μm to 1000 μm. Configuring the thickness t1 of the vapor chamber 1 to be 100 μm or greater makes it possible to ensure an adequate space for the vapor flow channel portion 50 and thus to cause the vapor chamber 1 to fulfill its function properly. On the other hand, configuring the thickness t1 to be 1000 μm or less makes it possible to avoid the vapor chamber 1 from being excessively thick.

The thickness t2 of the lower sheet 10 illustrated in FIG. 3 may be, for example, 6 μm to 100 μm. Configuring the thickness t2 of the lower sheet 10 to be 6 μm or greater makes it possible to ensure sufficient mechanical strength of the lower sheet 10. On the other hand, configuring the thickness t2 of the lower sheet 10 to be 100 μm or less makes it possible to avoid the vapor chamber 1 from being excessively thick. The thickness t3 of the upper sheet 20 illustrated in FIG. 3 may be set similarly as done for the thickness t2 of the lower sheet 10. The thickness t3 of the upper sheet 20 and the thickness t2 of the lower sheet 10 may be different from each other.

The thickness t4 of the wick sheet 30 illustrated in FIG. 3 may be, for example, 50 μm to 400 μm. Configuring the thickness t4 of the wick sheet 30 to be 50 μm or greater makes it possible to ensure an adequate space for the vapor flow channel portion 50 and thus to cause the vapor chamber 1 to fulfill its function properly. On the other hand, configuring it to be 400 μm or less makes it possible to avoid the vapor chamber 1 from being excessively thick.

As described above, the upper sheet 20 of the vapor chamber 1 according to the present embodiment includes the upper sheet groove 70 provided in the upper sheet inner surface 20a. As illustrated in FIGS. 5, 9, and 10, the upper sheet 20 may include a plurality of upper sheet grooves 70.

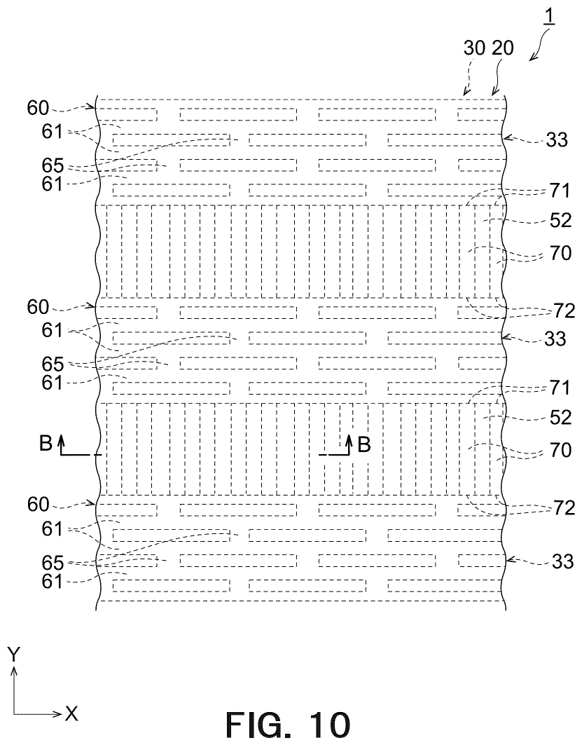

FIG. 10 is a partial enlarged top view illustrating an overlapped state of the wick sheet 30 and the upper sheet 20. As illustrated in FIG. 10, the upper sheet grooves 70 are provided at positions where they overlap with the vapor passage 51, 52 in a plan view. In the illustrated example, the upper sheet grooves 70 are provided at positions where they overlap with the second vapor passages 52 in a plan view, and the entirety of the upper sheet groove 70 overlaps with the second vapor passage 52 in a plan view. It can also be said that the upper sheet grooves 70 are provided between the lands 33 located next to each other in a plan view. The upper sheet grooves 70 may be provided at positions where they overlap with the first vapor passage 51 in a plan view. In this case, the upper sheet grooves 70 may be provided at positions where they overlap with, of the first vapor passage 51, the part extending in the X direction in a plan view.

As illustrated in FIGS. 9 and 10, the upper sheet groove 70 extends in a direction intersecting with the X direction. In the illustrated example, the upper sheet groove 70 extends in the Y direction, which is orthogonal to the X direction. The planar shape of the upper sheet groove 70 is an elongated rectangle. The upper sheet groove 70 includes a first end portion 71 and a second end portion 72 provided at both ends in the Y direction. The first end portion 71 is the end on the positive side in the Y direction (upper side in FIGS. 9 and 10) of the upper sheet groove 70. The second end portion 72 is the end on the negative side in the Y direction (lower side in FIGS. 9 and 10) of the upper sheet groove 70. In the illustrated example, both the first end portion 71 and the second end portion 72 are provided at positions where they overlap with the second vapor passage 52 in a plan view.

As illustrated in FIGS. 9 and 10, the upper sheet grooves 70 may be arranged in the X direction. The upper sheet grooves 70 may be arranged at predetermined intervals in parallel with one another.

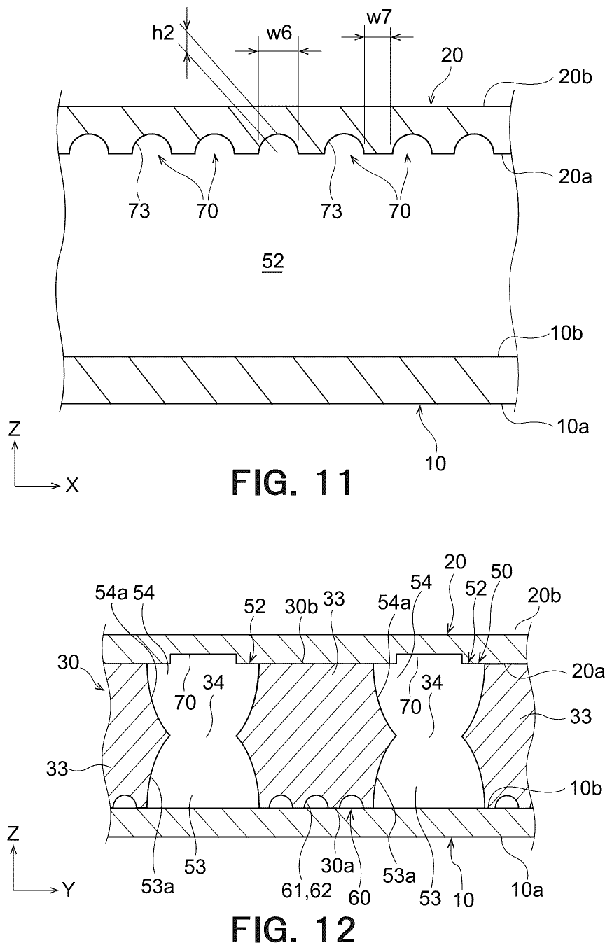

The upper sheet grooves 70 may be formed by etching the upper sheet 20 from the upper sheet inner surface 20a. Due to this etching, as illustrated in FIG. 11, the upper sheet groove 70 may have a wall surface 73 that is curved. The wall surface 73 may demarcate the upper sheet groove 70 and may be curved in a recessed manner from the upper sheet inner surface 20a toward the upper sheet outer surface 20b. In the example illustrated in FIG. 11, the cross-sectional shape of the upper sheet groove 70 is a semicircle.

The upper sheet groove 70 has a small cross-sectional passage area so that, mainly, the working liquid 2b will flow by capillary action. The upper sheet groove 70 is a groove whose cross-sectional passage area is smaller than that of the vapor passage 51, 52. The upper sheet groove 70 facilitates the transfer of the working liquid 2b between the vapor passage 51, 52 and the liquid flow channel portion 60. The cross-sectional passage area of the upper sheet groove 70 may be equal to that of the liquid flow channel mainstream groove 61. However, this does not imply any limitation. The cross-sectional passage area of the upper sheet groove 70 may be smaller than that of the liquid flow channel mainstream groove 61. In this case, through the capillary action of the upper sheet groove 70, a motive force for going from the liquid flow channel portion 60 toward the upper sheet groove 70 is applied to the working liquid 2b. This makes it possible to cause the working liquid 2b present in the liquid flow channel portion 60 to move to the vapor passage 51, 52 quickly through the upper sheet groove 70. The cross-sectional passage area of the upper sheet groove 70 may be larger than that of the liquid flow channel mainstream groove 61. In this case, through the capillary action of the upper sheet groove 70, a motive force for going from the upper sheet groove 70 toward the liquid flow channel portion 60 is applied to the working liquid 2b. This makes it possible to cause the working liquid 2b present in the vapor passage 51, 52 to move to the liquid flow channel portion 60 quickly through the upper sheet groove 70.

The length L1 (size in the Y direction) of the upper sheet groove 70 illustrated in FIG. 9 may be greater than the width w3 (see FIG. 7) of the liquid flow channel mainstream groove 61, and may be greater than the width w5 (see FIG. 8) of the liquid flow channel protrusion 64. As long as the upper sheet groove 70 is a groove whose cross-sectional passage area is smaller than that of the vapor passage 51, 52, the length L1 of the upper sheet groove 70 may be greater than the width w6 of the upper sheet groove 70 to be described below. The length L1 of the upper sheet groove 70 may be, for example, greater than 5 μm.

The width w6 (size in the X direction) of the upper sheet groove 70 illustrated in FIGS. 9 and 11 may be equal to the width w3 (see FIG. 7) of the liquid flow channel mainstream groove 61. However, this does not imply any limitation. The width w6 of the upper sheet groove 70 may be less than, or greater than, the width w3 of the liquid flow channel mainstream groove 61. The width w6 (size in the X direction) of the upper sheet groove 70 may be, for example, 5 μm to 150 μm. The width w6 of the upper sheet groove 70 means the size measured at the upper sheet inner surface 20a.

The depth h2 (size in the Z direction) of the upper sheet groove 70 illustrated in FIG. 11 may be equal to the depth h1 (see FIG. 7) of the liquid flow channel mainstream groove 61. However, this does not imply any limitation. The depth h2 of the upper sheet groove 70 may be greater than, or less than, the depth h1 of the liquid flow channel mainstream groove 61. The depth h2 of the upper sheet groove 70 may be, for example, 3 μm to 150 μm.

The gap w7 between the upper sheet grooves 70 located next to each other in the X direction illustrated in FIG. 11 may be equal to the gap between the liquid flow channel mainstream grooves 61 located next to each other in the Y direction, that is, the width w5 (see FIG. 8) of the liquid flow channel protrusion 64, or may be less than the width w5 of the liquid flow channel protrusion 64. In this case, it is possible to arrange a larger number of upper sheet grooves 70 and thus to cause a sufficient amount of the working liquid 2b to transfer between the vapor passage 51, 52 and the liquid flow channel portion 60. However, this does not imply any limitation. The gap w7 between the upper sheet grooves 70 located next to each other in the X direction may be greater than the width w5 of the liquid flow channel protrusion 64. The gap w7 between the upper sheet grooves 70 located next to each other in the X direction may be, for example, 3 μm to 500 μm.

In the present embodiment, the planar shape of the upper sheet groove 70 is an elongated rectangle, and the cross-sectional shape of the upper sheet groove 70 is a semicircle. However, this does not imply any limitation. The upper sheet groove 70 may have any shape.

In the present embodiment, the upper sheet groove 70 is provided at the entire region of overlapping with the second vapor passage 52 in a plan view. However, this does not imply any limitation. The upper sheet groove 70 may be provided only at a part of the region of overlapping with the vapor passage 51, 52 in a plan view. For example, the upper sheet grooves 70 may be arranged at the vaporization region SR only. In another example, the upper sheet grooves 70 may be arranged at the condensation region CR only.

Next, a method of manufacturing the vapor chamber 1 having the structure described above will now be described.

First, in a sheet preparation process, each sheet 10, 20, 30 is prepared. The sheet preparation process includes a lower sheet preparation process of preparing the lower sheet 10, an upper sheet preparation process of preparing the upper sheet 20, and a wick sheet preparation process of preparing the wick sheet 30.

In the lower sheet preparation process, first, a lower sheet parent material having a desired thickness is prepared. The lower sheet parent material may be a rolled material. Next, the lower sheet 10 having a desired planar shape is formed by etching the lower sheet parent material. Alternatively, the lower sheet 10 having a desired planar shape may be formed by pressing the lower sheet parent material. The lower sheet 10 such as one illustrated in FIG. 4 can be prepared in this way.

Similarly to the lower sheet preparation process, in the upper sheet preparation process, first, an upper sheet parent material having a desired thickness is prepared. The upper sheet parent material may be a rolled material. Next, the upper sheet 20 having a desired planar shape is formed by etching the upper sheet parent material. The upper sheet grooves 70 described above are formed in the upper sheet 20 through this process of etching. Alternatively, the upper sheet 20 having a desired planar shape may be formed by pressing the upper sheet parent material. The upper sheet grooves 70 may be formed by cutting into the upper sheet parent material. The upper sheet 20 such as one illustrated in FIG. 5 can be prepared in this way.

The wick sheet preparation process may include a material sheet preparation process of preparing a metal material sheet and an etching process of etching the metal material sheet. First, in the material sheet preparation process, a flat metal material sheet having a desired thickness is prepared. The metal material sheet may be a rolled material. Next, in the etching process, the wick sheet 30 having a desired planar shape and including the vapor flow channel portion 50 and the liquid flow channel portion 60 is formed by etching the metal material sheet from a first material surface and a second material surface. The wick sheet 30 such as one illustrated in FIG. 6 can be prepared in this way.

In the etching process, the first material surface and the second material surface of the metal material sheet may be etched simultaneously. However, this does not imply any limitation. The etching at the first material surface and the etching at the second material surface may be executed as separate processes. The vapor flow channel portion 50 and the liquid flow channel portion 60 may be formed by simultaneous etching or through separate etching processes. An iron chloride etchant such as aqueous ferric chloride, or a copper chloride etchant such as aqueous copper chloride, may be used as an etchant, for example.

After the sheet preparation process, in a bonding process, the lower sheet 10, the upper sheet 20, and the wick sheet 30 are bonded together. First, the lower sheet 10, the wick sheet 30, and the upper sheet 20 are stacked in this order. When this is performed, the alignment holes 12 of the lower sheet 10, the alignment holes 35 of the wick sheet 30, and the alignment holes 22 of the upper sheet 20 may be used for alignment of each sheet 10, 20, 30. Next, the lower sheet 10, the wick sheet 30, and the upper sheet 20 are temporarily joined. For example, each sheet 10, 20, 30 may be temporarily joined using spot welding or laser welding. Next, the lower sheet 10, the wick sheet 30, and the upper sheet 20 are permanently bonded together using thermal compression bonding. For example, the sheets 10, 20, and 30 may be bonded together using diffusion bonding.

After the bonding process, in an injection process, the working liquid 2b is injected into the sealed space 3 through the injection flow channel 37 of the injection portion 4.

After the injection process, in a sealing process, the injection flow channel 37 is sealed. This sealing blocks communication between the sealed space 3 and the outside and thus hermetically closes the sealed space 3. Therefore, it is possible to obtain the sealed space 3 in which the working liquid 2b is enclosed and prevent the leakage of the working liquid 2b contained in the sealed space 3 to the outside.

Through the processes described above, the vapor chamber 1 according to the present embodiment can be obtained.

Next, a method of operation of the vapor chamber 1, that is, how to cool the device D, will now be described.

The vapor chamber 1 obtained as described above is installed inside the housing H of a mobile terminal or the like. The device D such as a CPU, which is the device to be cooled, is mounted on the upper sheet outer surface 20b of the upper sheet 20 (alternatively, the vapor chamber 1 is attached to the device D). The working liquid 2b contained in the sealed space 3 adheres to the wall surfaces of the sealed space 3 due to its surface tension, specifically, to the wall surface 53a of the lower vapor flow channel recessed portion 53, to the wall surface 54a of the upper vapor flow channel recessed portion 54, and to the wall surface 62 of each liquid flow channel mainstream groove 61 and the wall surface of each liquid flow channel communication groove 65 of the liquid flow channel portion 60. Moreover, the working liquid 2b could adhere also to, of the lower sheet inner surface 10b of the lower sheet 10, the part exposed to the lower vapor flow channel recessed portion 53. Furthermore, the working liquid 2b could adhere also to, of the upper sheet inner surface 20a of the upper sheet 20, the part exposed to the upper vapor flow channel recessed portion 54, the part exposed to the liquid flow channel mainstream grooves 61, and the part exposed to the liquid flow channel communication grooves 65.

When the device D generates heat in this state, the working liquid 2b present at the vaporization region SR (see FIG. 6) receives the heat from the device D. The working liquid 2b vaporizes (gasifies) by absorbing the received heat as latent heat, and the working vapor 2a is thus generated. The working vapor 2a having been generated diffuses inside the first vapor passage 51 and the second vapor passages 52 that constitute the sealed space 3. More specifically, mainly, the working vapor 2a diffuses in the X direction at, of the first vapor passage 51, the part extending in the X direction, and at the second vapor passages 52 (see solid-line arrows in FIG. 6).

Then, the working vapor 2a present in each vapor passage 51, 52 flows away from the vaporization region SR to the condensation region CR where the temperature is relatively low (right-side portion in FIG. 6). At the condensation region CR, the working vapor 2a cools by releasing the heat to, mainly, the lower sheet 10. The heat received by the lower sheet 10 from the working vapor 2a is transferred to outside air via the housing member Ha (see FIG. 3).

By releasing the heat to the lower sheet 10 at the condensation region CR, the working vapor 2a loses the latent heat absorbed at the vaporization region SR. This causes the condensation of the working vapor 2a, and the working liquid 2b is thus generated. The working liquid 2b having been generated adheres to the wall surface 53a, 54a of each vapor flow channel recessed portion 53, 54, to the lower sheet inner surface 10b of the lower sheet 10, and to the upper sheet inner surface 20a of the upper sheet 20. Meanwhile the working liquid 2b keeps vaporizing at the vaporization region SR. Therefore, the working liquid 2b present at, of the liquid flow channel portion 60, a region other than the vaporization region SR (that is, at the condensation region CR) is sent toward the vaporization region SR by capillary action of each of the liquid flow channel mainstream grooves 61 (see broken-line arrows in FIG. 6). Therefore, the working liquid 2b adhering to each wall surface 53a, 54a, the lower sheet inner surface 10b, and the upper sheet inner surface 20a moves to the liquid flow channel portion 60 and enters the liquid flow channel mainstream grooves 61 through the liquid flow channel communication grooves 65. In this way, each of the liquid flow channel mainstream grooves 61 and each of the liquid flow channel communication grooves 65 become filled with the working liquid 2b. The working liquid 2b having filled them up obtains a motive force for going toward the vaporization region SR due to capillary action of each of the liquid flow channel mainstream grooves 61 and is thus sent smoothly toward the vaporization region SR.

At the liquid flow channel portion 60, each liquid flow channel mainstream groove 61 is in communication with another liquid flow channel mainstream groove 61 located next thereto via the corresponding liquid flow channel communication grooves 65. This enables the working liquid 2b to transfer from one to the other of the liquid flow channel mainstream grooves 61 located next to each other, thereby suppressing the occurrence of “dry out” in the liquid flow channel mainstream grooves 61. Therefore, a capillary force is applied to the working liquid 2b present in each of the liquid flow channel mainstream grooves 61; accordingly, the working liquid 2b is sent smoothly toward the vaporization region SR.

The working liquid 2b having reached the vaporization region SR vaporizes by receiving heat from the device D again. The working vapor 2a having turned from the working liquid 2b due to evaporation flows through the liquid flow channel communication grooves 65 inside the vaporization region SR to move to the lower vapor flow channel recessed portion 53 and the upper vapor flow channel recessed portion 54, the cross-sectional passage area of which is larger. Then, the working vapor 2a diffuses inside each vapor flow channel recessed portion 53, 54. In this way, the working fluid 2a, 2b circulates inside the sealed space 3 while repeating phase changes, that is, vaporization and condensation. By this means, the heat of the device D diffuses and dissipates. The device D is cooled as a result of this heat release.

In the present embodiment, the upper sheet groove 70 is provided in the upper sheet inner surface 20a of the upper sheet 20. The upper sheet groove 70 is provided at a position where it overlaps with the vapor passage 51, 52 in a plan view, and extends in a direction intersecting with the X direction. This makes it possible for the working liquid 2b to move smoothly from the vapor passage 51, 52 to the liquid flow channel portion 60 through the upper sheet groove 70 at the condensation region CR and enters the liquid flow channel mainstream groove 61 smoothly thereat. Moreover, this makes it possible for the working liquid 2b to move from the liquid flow channel portion 60 to the vapor passage 51, 52 through the upper sheet groove 70 at the vaporization region SR. Therefore, it is possible to absorb the heat of the device D effectively by means of the working liquid 2b having moved to the vapor passage 51, 52, thereby cooling the device D effectively.

As described above, according to the present embodiment, the upper sheet 20 includes the upper sheet groove 70 provided in the upper sheet inner surface 20a; the upper sheet groove 70 is provided at a position of overlapping with the vapor passage 51, 52 in a plan view and extends in a direction intersecting with the X direction. This facilitates the transfer of the working liquid 2b between the vapor passage 51, 52 and the liquid flow channel portion 60. Therefore, it is possible to facilitate the circulation of the working fluid 2a, 2b inside the vapor chamber 1. Consequently, it is possible to improve the heat dissipation efficiency of the vapor chamber 1.

In the present embodiment, the cross-sectional passage area of the upper sheet groove 70 may be smaller than that of the liquid flow channel mainstream groove 61. Through the capillary action of the upper sheet groove 70, this applies, to the working liquid 2b, a motive force for going from the liquid flow channel portion 60 toward the upper sheet groove 70 and thus makes it possible to cause the working liquid 2b present in the liquid flow channel portion 60 to move to the vapor passage 51, 52 quickly through the upper sheet groove 70. Therefore, in a case where the upper sheet groove 70 having this configuration is disposed at the vaporization region SR, it is possible to facilitate the movement of the working liquid 2b from the liquid flow channel portion 60 to the vapor passage 51, 52 at the vaporization region SR effectively. Consequently, it is possible to further facilitate the circulation of the working fluid 2a, 2b inside the vapor chamber 1.

In the present embodiment, the cross-sectional passage area of the upper sheet groove 70 may be larger than that of the liquid flow channel mainstream groove 61. Through the capillary action of the upper sheet groove 70, this applies, to the working liquid 2b, a motive force for going from the upper sheet groove 70 toward the liquid flow channel portion 60 and thus makes it possible to cause the working liquid 2b present in the vapor passage 51, 52 to move to the liquid flow channel portion 60 quickly through the upper sheet groove 70. Therefore, in a case where the upper sheet groove 70 having this configuration is disposed at the condensation region CR, it is possible to facilitate the movement of the working liquid 2b from the vapor passage 51, 52 to the liquid flow channel portion 60 at the condensation region CR effectively. Consequently, it is possible to further facilitate the circulation of the working fluid 2a, 2b inside the vapor chamber 1.

According to the present embodiment, the liquid flow channel portion 60 is provided in the wick sheet upper surface 30b. As described above, the upper sheet groove 70 is provided in the upper sheet inner surface 20a facing the wick sheet upper surface 30b. This makes it possible for the working liquid 2b having flowed through the upper sheet groove 70 to move smoothly to the vapor passage 51, 52 or the liquid flow channel portion 60. Therefore, it is possible to further facilitate the circulation of the working fluid 2a, 2b inside the vapor chamber 1.

Having been described in the present embodiment above is an example in which the liquid flow channel portion 60 is provided in the wick sheet upper surface 30b. However, this does not imply any limitation. As illustrated in FIG. 12, the liquid flow channel portion 60 may be provided in the wick sheet lower surface 30a.

Even when this configuration is adopted, the working liquid 2b can flow from the liquid flow channel portion 60 through the upper sheet groove 70 by way of the wall surface 53a of the lower vapor flow channel recessed portion 53 and the wall surface 54a of the upper vapor flow channel recessed portion 54, thereby moving to the vapor passage 51, 52. Moreover, the working liquid 2b can flow from the vapor passage 51, 52 through the upper sheet groove 70, and flow by way of the wall surface 53a of the lower vapor flow channel recessed portion 53 and the wall surface 54a of the upper vapor flow channel recessed portion 54, thereby moving to the liquid flow channel portion 60. Therefore, it is possible to facilitate the circulation of the working fluid 2a, 2b inside the vapor chamber 1.

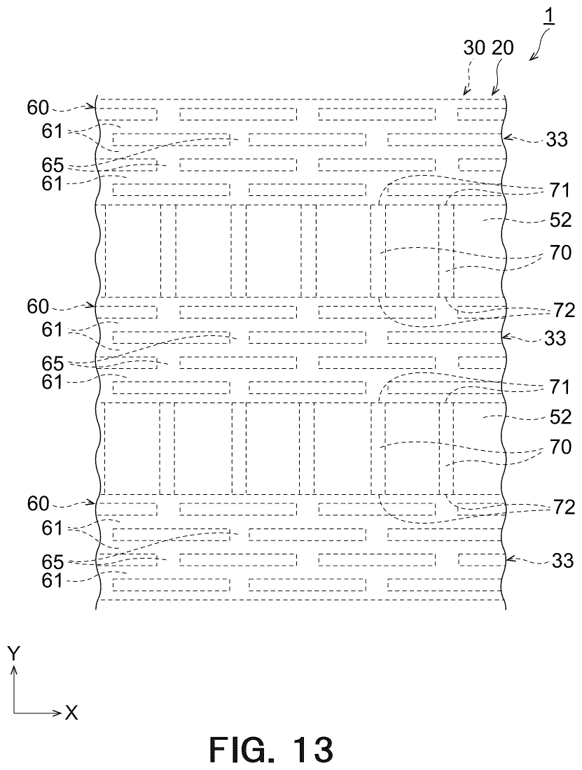

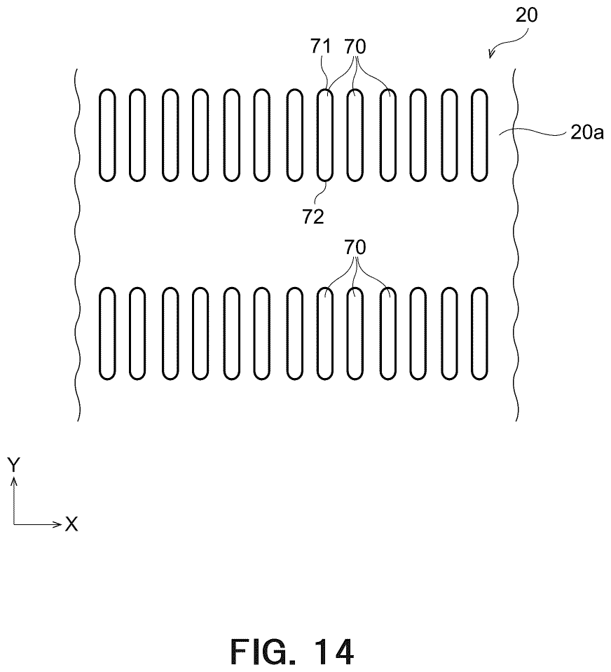

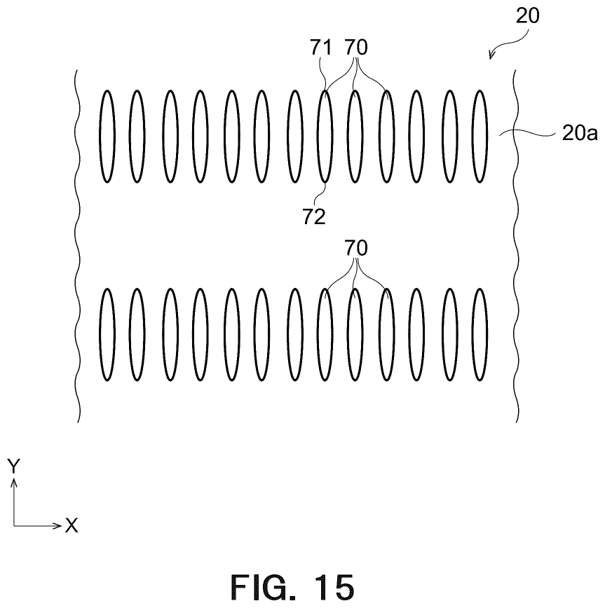

In the present embodiment described above, as illustrated in FIG. 13, the upper sheet grooves 70 may be arranged at positions corresponding to, among the liquid flow channel communication grooves 65 of the liquid flow channel portion 60, those located closest to the vapor passage 51, 52. That is, as illustrated in FIG. 13, the upper sheet grooves 70 may be arranged at the same positions in the X direction as, among the liquid flow channel communication grooves 65 of the liquid flow channel portion 60, those located closest to the vapor passage 51, 52, such that the first end portion 71 or the second end portion 72 faces the liquid flow channel communication groove 65 in the Y direction. Moreover, as illustrated in FIG. 13, the upper sheet grooves 70 may be absent except at these positions in the X direction. In this case, it is possible to facilitate the transfer of the working liquid 2b between the vapor passage 51, 52 and the liquid flow channel portion 60 while suppressing a decrease in mechanical strength of the upper sheet 20 by reducing the number of the upper sheet grooves 70.

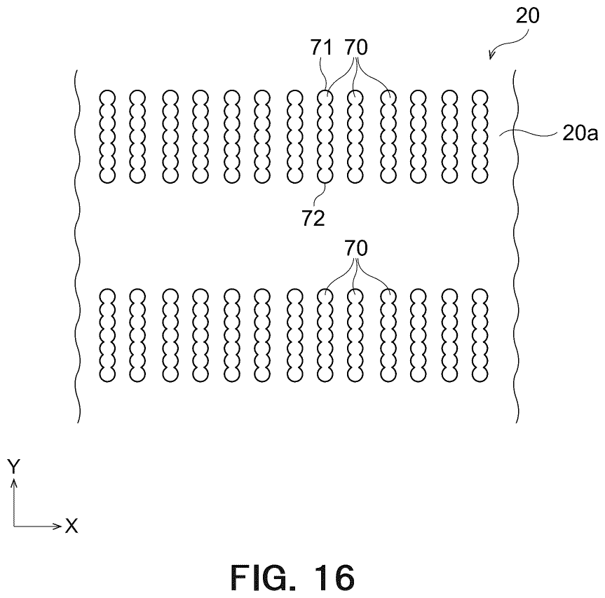

Having been described in the present embodiment above is an example in which the planar shape of the upper sheet groove 70 is an elongated rectangle (see FIG. 9). However, this does not imply any limitation. For example, as illustrated in FIG. 14, the planar shape of the upper sheet groove 70 may be an elongated shape extending in the Y direction and having rounded ends in the Y direction (the first end portion 71 and the second end portion 72). In another example, as illustrated in FIG. 15, the planar shape of the upper sheet groove 70 may be an elongated elliptical shape extending in the Y direction. In another example, as illustrated in FIG. 16, the planar shape of the upper sheet groove 70 may be a chain-of-beads-like shape made up of a plurality of circles arranged in the Y direction with partial overlaps with one another. As described here, the planar shape of the upper sheet groove 70 may be any shape.

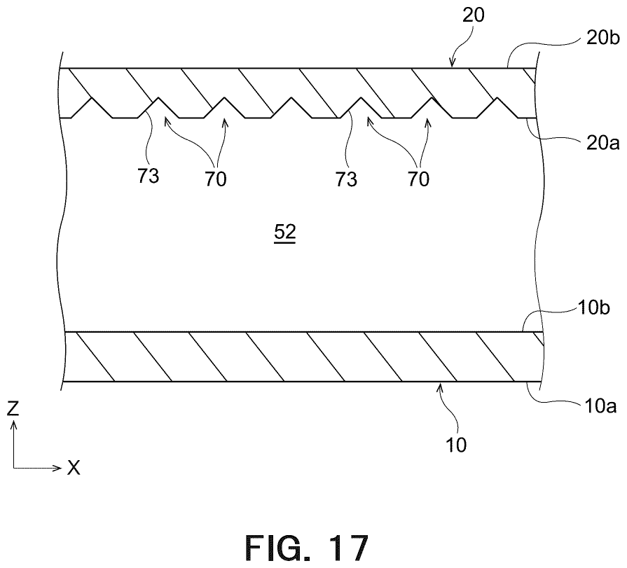

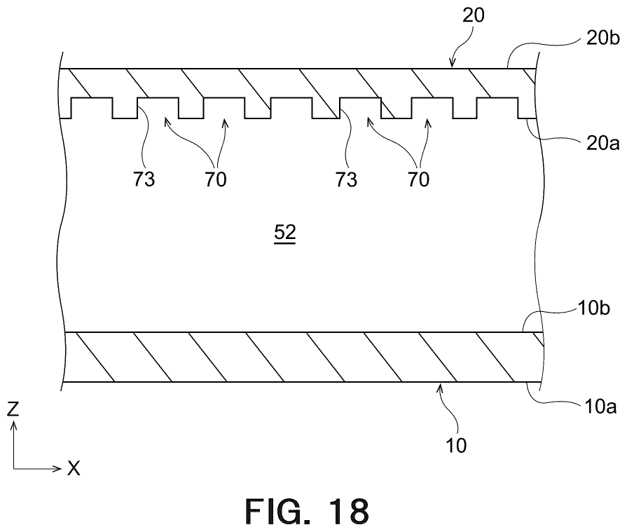

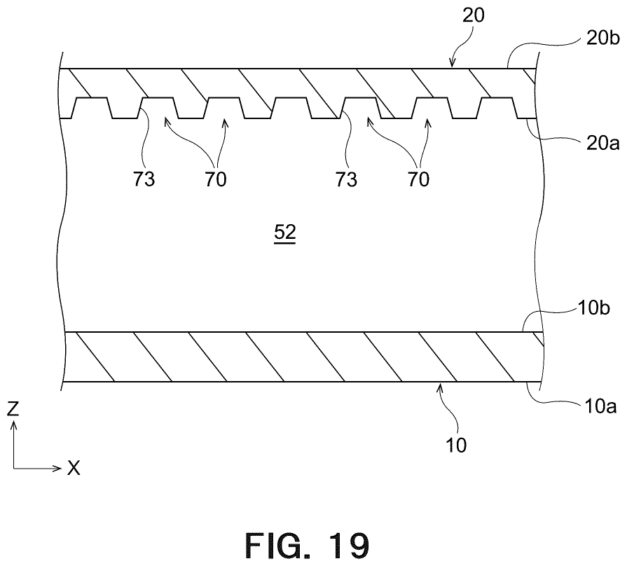

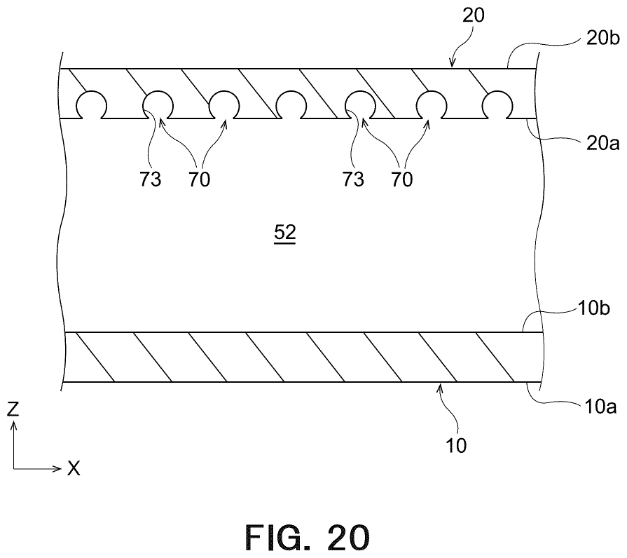

Having been described in the present embodiment above is an example in which the cross-sectional shape of the upper sheet groove 70 is a semicircle (see FIG. 11). However, this does not imply any limitation. For example, as illustrated in FIG. 17, the cross-sectional shape of the upper sheet groove 70 may be a triangle. In another example, as illustrated in FIG. 18, the cross-sectional shape of the upper sheet groove 70 may be a rectangle. In another example, as illustrated in FIG. 19, the cross-sectional shape of the upper sheet groove 70 may be a trapezoid. In another example, as illustrated in FIG. 20, the cross-sectional shape of the upper sheet groove 70 may be a partial circle having a greater width inside than at its opening. As described here, the cross-sectional shape of the upper sheet groove 70 may be any shape as long as its cross-sectional passage area is smaller than that of the vapor passage 51, 52.

### Second Embodiment

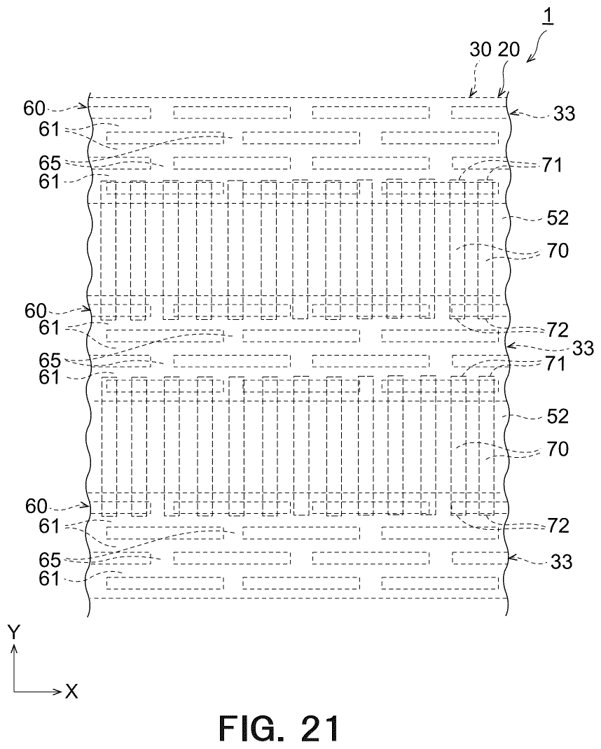

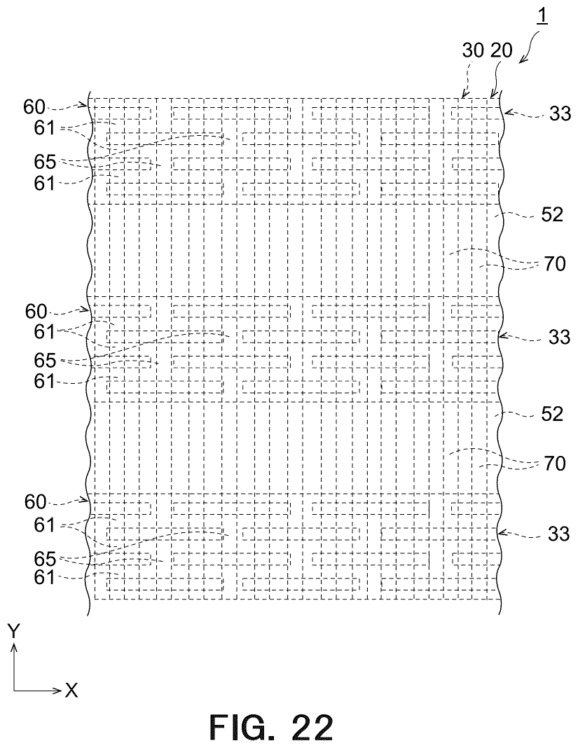

Next, a vapor chamber and an electronic apparatus according to a second embodiment of the present disclosure will now be described with reference to FIGS. 21 and 22.

In the second embodiment illustrated in FIGS. 21 and 22, the main difference lies in that a first sheet groove is provided continuously also at a position where it overlaps with a liquid flow channel portion in a plan view and is provided in such a way as to traverse a vapor passage in a direction intersecting with a first direction, and, except for this difference, the configuration of this embodiment is substantially the same as that of the first embodiment illustrated in FIGS. 1 to 20. In FIGS. 21 and 22, the same reference signs are assigned to portions that are the same as those of the first embodiment illustrated in FIGS. 1 to 20, and a detailed explanation thereof is omitted.

In the present embodiment, as illustrated in FIG. 21, the upper sheet groove 70 is provided continuously also at a position where it overlaps with the liquid flow channel portion 60 in a plan view. That is, the upper sheet groove 70 overlaps with the land portion 33, too, in a plan view. As illustrated in FIG. 21, the upper sheet groove 70 may overlap with the liquid flow channel mainstream groove 61 in a plan view.

Moreover, in the present embodiment, the upper sheet groove 70 is provided in such a way as to traverse the vapor passage 51, 52 in a direction intersecting with the X direction. In the example illustrated in FIG. 21, the upper sheet groove 70 is provided in such a way as to traverse the second vapor passage 52 in the Y direction. The first end portion 71 and the second end portion 72 of the upper sheet groove 70 are provided at positions where they overlap with the land portion 33 in a plan view. More specifically, the first end portion 71 is provided at a position where it overlaps with certain one land 33 in a plan view, and the second end portion 72 is provided at a position where it overlaps with, of the lands 33, another one located next to this one land 33 in a plan view.

As described above, according to the present embodiment, the upper sheet groove 70 is provided continuously also at a position where it overlaps with the liquid flow channel portion 60 in a plan view. This facilitates the transfer of the working liquid 2b between the vapor passage 51, 52 and the liquid flow channel portion 60 effectively. Therefore, in a case where the upper sheet groove 70 having this configuration is disposed at the vaporization region SR, it is possible to facilitate the movement of the working liquid 2b from the liquid flow channel portion 60 to the vapor passage 51, 52 at the vaporization region SR effectively. Moreover, when there is a sudden rise in temperature, it is possible to cause the working vapor 2a having turned from the working liquid 2b due to evaporation inside the liquid flow channel portion 60 to move to the vapor passage 51, 52 quickly through the upper sheet groove 70 and thus to facilitate the movement of the working vapor 2a from the liquid flow channel portion 60 to the vapor passage 51, 52 at the vaporization region SR effectively. Furthermore, in a case where the cross-sectional passage area of the upper sheet groove 70 is larger than that of the liquid flow channel mainstream groove 61, it is possible to facilitate the movement of the working vapor 2a from the liquid flow channel portion 60 to the vapor passage 51, 52 at the vaporization region SR more effectively. Consequently, it is possible to further facilitate the circulation of the working fluid 2a, 2b inside the vapor chamber 1.

Moreover, according to the present embodiment, the upper sheet groove 70 is provided in such a way as to traverse the vapor passage 51, 52 in a direction intersecting with the first direction. This makes it possible to, for example, make an amount of the working liquid 2b moving to each liquid flow channel portion 60 provided between the lands 33 located next to each other uniform. Therefore, it is possible to suppress imbalanced presence of a larger amount of the working liquid 2b at any particular liquid flow channel portion 60. Consequently, it is possible to improve the efficiency of sending the working liquid 2b and thus to further facilitate the circulation of the working fluid 2a, 2b inside the vapor chamber 1.

Having been described in the present embodiment above is an example in which the first end portion 71 and the second end portion 72 of the upper sheet groove 70 are provided at positions where they overlap with the land portion 33 in a plan view. However, this does not imply any limitation. For example, as illustrated in FIG. 22, the upper sheet groove 70 may be provided in such a way as to traverse the land portion 33 in a direction intersecting with the X direction. In the example illustrated in FIG. 22, the upper sheet groove 70 extends linearly in the Y direction in such a way as to traverse the vapor passage 51, 52 and the land portion 33 in a plan view.

Even when this configuration is adopted, it is possible to facilitate the transfer of the working liquid 2b between the vapor passage 51, 52 and the liquid flow channel portion 60 effectively. Therefore, in a case where the upper sheet groove 70 having this configuration is disposed at the vaporization region SR, it is possible to facilitate the movement of the working liquid 2b from the liquid flow channel portion 60 to the vapor passage 51, 52 at the vaporization region SR effectively. Moreover, when there is a sudden rise in temperature, it is possible to cause the working vapor 2a having turned from the working liquid 2b due to evaporation inside the liquid flow channel portion 60 to move to the vapor passage 51, 52 quickly through the upper sheet groove 70 and thus to facilitate the movement of the working vapor 2a from the liquid flow channel portion 60 to the vapor passage 51, 52 at the vaporization region SR effectively. Furthermore, in a case where the cross-sectional passage area of the upper sheet groove 70 is larger than that of the liquid flow channel mainstream groove 61, it is possible to facilitate the movement of the working vapor 2a from the liquid flow channel portion 60 to the vapor passage 51, 52 at the vaporization region SR more effectively. Consequently, it is possible to further facilitate the circulation of the working fluid 2a, 2b inside the vapor chamber 1. Moreover, it is possible to make an amount of the working liquid 2b moving to each liquid flow channel portion 60 uniform and thus to suppress imbalanced presence of a larger amount of the working liquid 2b at any particular liquid flow channel portion 60. Therefore, it is possible to improve the efficiency of sending the working liquid 2b and thus to further facilitate the circulation of the working fluid 2a, 2b inside the vapor chamber 1.

### Third Embodiment

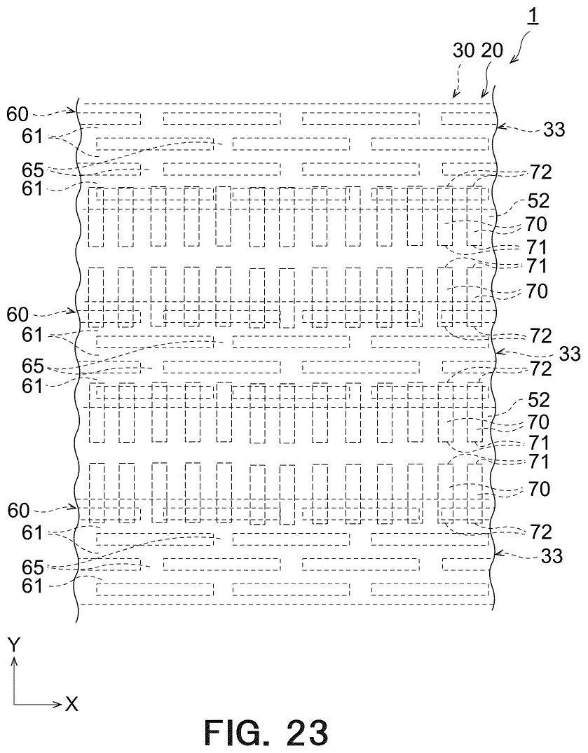

Next, a vapor chamber and an electronic apparatus according to a third embodiment of the present disclosure will now be described with reference to FIG. 23.

In the third embodiment illustrated in FIG. 23, the main difference lies in that a first sheet groove includes a first end portion provided at a position where it overlaps with a vapor passage in a plan view and a second end portion provided at a position where it overlaps with a liquid flow channel portion in a plan view, and, except for this difference, the configuration of this embodiment is substantially the same as that of the second embodiment illustrated in FIGS. 21 and 22. In FIG. 23, the same reference signs are assigned to portions that are the same as those of the second embodiment illustrated in FIGS. 21 and 22, and a detailed explanation thereof is omitted.

In the present embodiment, as illustrated in FIG. 23, the upper sheet groove 70 includes the first end portion 71 provided at a position where it overlaps with the vapor passage 51, 52 in a plan view and the second end portion 72 provided at a position where it overlaps with the liquid flow channel portion 60 in a plan view. The first end portion 71 is defined as, of two ends in a direction intersecting with the X direction, the end overlapping with the vapor passage 51, 52 in a plan view. The second end portion 72 is defined as, of the two ends in the direction intersecting with the X direction, the end overlapping with the liquid flow channel portion 60 in a plan view. In the example illustrated in FIG. 23, the first end portion 71 overlaps with the second vapor passage 52 in a plan view, and the second end portion 72 overlaps with the liquid flow channel mainstream groove 61 in a plan view.

As illustrated in FIG. 23, the upper sheet grooves 70 may be provided at positions of overlapping with an edge on the positive side in the Y direction of the land 33 in a plan view and at positions of overlapping with an edge on the negative side in the Y direction of the land 33 in a plan view, respectively. At the positions of overlapping with the edge on the positive side in the Y direction of the land 33 in a plan view, the upper sheet grooves 70 may be arranged in the X direction. Also at the positions of overlapping with the edge on the negative side in the Y direction of the land 33 in a plan view, the upper sheet grooves 70 may be arranged in the X direction.

As described above, according to the present embodiment, the upper sheet groove 70 includes the first end portion 71 provided at a position where it overlaps with the vapor passage 51, 52 in a plan view and the second end portion 72 provided at a position where it overlaps with the liquid flow channel portion 60 in a plan view. This facilitates the transfer of the working liquid 2b between the vapor passage 51, 52 and the liquid flow channel portion 60 effectively. Therefore, in a case where the upper sheet groove 70 having this configuration is disposed at the vaporization region SR, it is possible to facilitate the movement of the working liquid 2b from the liquid flow channel portion 60 to the vapor passage 51, 52 at the vaporization region SR effectively. Moreover, when there is a sudden rise in temperature, it is possible to cause the working vapor 2a having turned from the working liquid 2b due to evaporation inside the liquid flow channel portion 60 to move to the vapor passage 51, 52 quickly through the upper sheet groove 70 and thus to facilitate the movement of the working vapor 2a from the liquid flow channel portion 60 to the vapor passage 51, 52 at the vaporization region SR effectively. Furthermore, in a case where the cross-sectional passage area of the upper sheet groove 70 is larger than that of the liquid flow channel mainstream groove 61, it is possible to facilitate the movement of the working vapor 2a from the liquid flow channel portion 60 to the vapor passage 51, 52 at the vaporization region SR more effectively. Consequently, it is possible to further facilitate the circulation of the working fluid 2a, 2b inside the vapor chamber 1.

### Fourth Embodiment

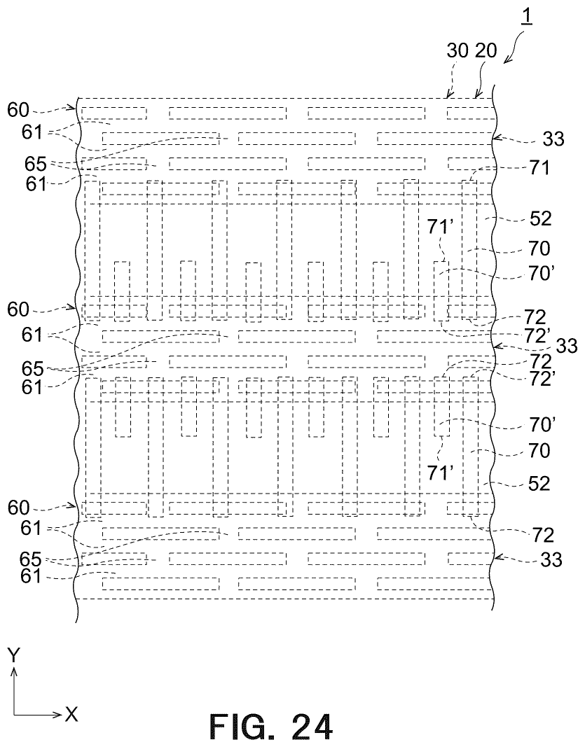

Next, a vapor chamber and an electronic apparatus according to a fourth embodiment of the present disclosure will now be described with reference to FIG. 24.

In the fourth embodiment illustrated in FIG. 24, the main difference lies in that a plurality of first sheet grooves includes a first sheet groove provided in such a way as to traverse a vapor passage in a direction intersecting with a first direction and a first sheet groove including a first end portion provided at a position where it overlaps with the vapor passage in a plan view and a second end portion provided at a position where it overlaps with a liquid flow channel portion in a plan view, and, except for this difference, the configuration of this embodiment is substantially the same as that of the second embodiment illustrated in FIG. 21. In FIG. 24, the same reference signs are assigned to portions that are the same as those of the second embodiment illustrated in FIG. 21, and a detailed explanation thereof is omitted.

In the present embodiment, as illustrated in FIG. 24, a plurality of upper sheet grooves 70, 70′ includes the upper sheet grooves 70 each provided in such a way as to traverse the vapor passage 51, 52 in a direction intersecting with the X direction and upper sheet grooves 70′ each including a first end portion 71′ provided at a position where it overlaps with the vapor passage 51, 52 in a plan view and a second end portion 72′ provided at a position where it overlaps with the liquid flow channel portion 60 in a plan view.

In the example illustrated in FIG. 24, the upper sheet groove 70 is provided in such a way as to traverse the second vapor passage 52 in the Y direction. The first end portion 71 and the second end portion 72 of the upper sheet groove 70 are provided at positions where they overlap with the land portion 33 in a plan view. More specifically, the first end portion 71 is provided at a position where it overlaps with certain one land 33 in a plan view, and the second end portion 72 is provided at a position where it overlaps with, of the lands 33, another one located next to this one land 33 in a plan view.

In addition, in the example illustrated in FIG. 24, the first end portion 71′ of the upper sheet groove 70′ overlaps with the second vapor passage 52 in a plan view, and the second end portion 72′ of the upper sheet groove 70′ overlaps with the liquid flow channel mainstream groove 61 in a plan view.

As illustrated in FIG. 24, the upper sheet grooves 70′ may be provided at positions of overlapping with an edge on the positive side in the Y direction of certain one land 33 (for example, the land 33 disposed at the center in FIG. 24) in a plan view and at positions of overlapping with an edge on the negative side in the Y direction of this one land 33 in a plan view, respectively. At the positions of overlapping with the edge on the positive side in the Y direction of this one land 33 in a plan view, the upper sheet grooves 70 and the upper sheet grooves 70′ may be arranged alternately in the X direction. Also at the positions of overlapping with the edge on the negative side in the Y direction of this one land 33 in a plan view, the upper sheet grooves 70 and the upper sheet grooves 70′ may be arranged alternately in the X direction.

On the other hand, as illustrated in FIG. 24, the upper sheet grooves 70′ may be absent at the positions of overlapping with the edge on the positive side in the Y direction of, of the lands 33, others (for example, the lands 33 disposed at the lower side and the upper side in FIG. 24) located next to this one land 33 in a plan view and at the positions of overlapping with the edge on the negative side in the Y direction of these other lands 33 in a plan view. At the positions of overlapping with the edge on the positive side in the Y direction of the other land 33 in a plan view, the upper sheet grooves 70 may be arranged in the X direction. Also at the positions of overlapping with the edge on the negative side in the Y direction of the other land 33 in a plan view, the upper sheet grooves 70 may be arranged alternately in the X direction.

As described above, according to the present embodiment, the plurality of upper sheet grooves 70, 70′ includes the upper sheet grooves 70 each provided in such a way as to traverse the vapor passage 51, 52 in a direction intersecting with the X direction and upper sheet grooves 70′ each including the first end portion 71′ provided at a position where it overlaps with the vapor passage 51, 52 in a plan view and the second end portion 72′ provided at a position where it overlaps with the liquid flow channel portion 60 in a plan view. This facilitates the transfer of the working liquid 2b between the vapor passage 51, 52 and the liquid flow channel portion 60 effectively. Therefore, in a case where the upper sheet groove 70 having this configuration is disposed at the vaporization region SR, it is possible to facilitate the movement of the working liquid 2b from the liquid flow channel portion 60 to the vapor passage 51, 52 at the vaporization region SR effectively. Moreover, when there is a sudden rise in temperature, it is possible to cause the working vapor 2a having turned from the working liquid 2b due to evaporation inside the liquid flow channel portion 60 to move to the vapor passage 51, 52 quickly through the upper sheet groove 70 and thus to facilitate the movement of the working vapor 2a from the liquid flow channel portion 60 to the vapor passage 51, 52 at the vaporization region SR effectively. Furthermore, in a case where the cross-sectional passage area of the upper sheet groove 70 is larger than that of the liquid flow channel mainstream groove 61, it is possible to facilitate the movement of the working vapor 2a from the liquid flow channel portion 60 to the vapor passage 51, 52 at the vaporization region SR more effectively. Consequently, it is possible to further facilitate the circulation of the working fluid 2a, 2b inside the vapor chamber 1.

According to the present embodiment, among other things, it is possible to facilitate the transfer of the working liquid 2b between the vapor passage 51, 52 and the liquid flow channel portion 60 provided in certain one land 33. This makes it possible to make the working liquid 2b present in an imbalanced manner among the channels of the liquid flow channel portion 60. Therefore, for example, it is possible to cause a larger amount of the working liquid 2b to move to, of the liquid flow channel portion 60, a particular channel that offers higher performance of sending the working liquid 2b than other channels of the liquid flow channel portion 60. Consequently, it is possible to improve the efficiency of sending the working liquid 2b and thus to further facilitate the circulation of the working fluid 2a, 2b inside the vapor chamber 1.

### Fifth Embodiment

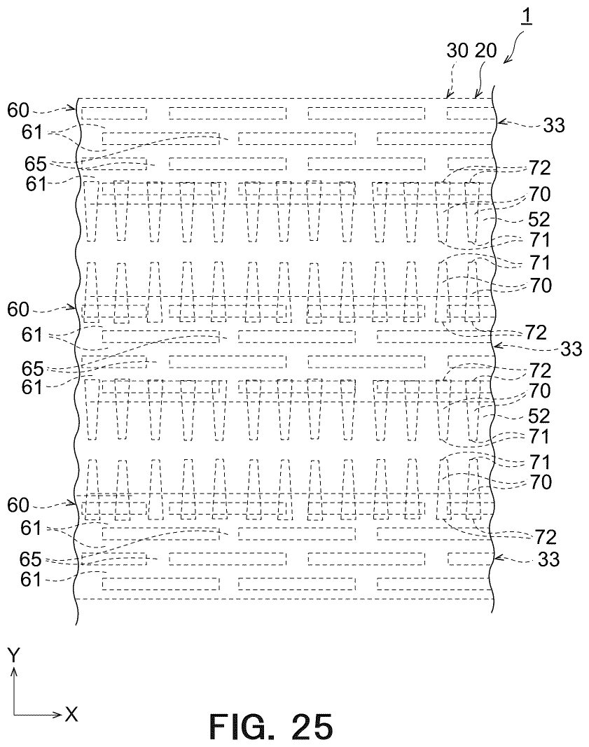

Next, a vapor chamber and an electronic apparatus according to a fifth embodiment of the present disclosure will now be described with reference to FIG. 25.

In the fifth embodiment illustrated in FIG. 25, the main difference lies in that a first sheet groove is formed in such a way as to have a decreasing cross-sectional passage area from a second end portion toward a first end portion, and, except for this difference, the configuration of this embodiment is substantially the same as that of the third embodiment illustrated in FIG. 23. In FIG. 25, the same reference signs are assigned to portions that are the same as those of the third embodiment illustrated in FIG. 23, and a detailed explanation thereof is omitted.

In the present embodiment, as illustrated in FIG. 25, the upper sheet groove 70 is formed in such a way as to have a decreasing cross-sectional passage area from the second end portion 72 toward the first end portion 71. That is, the upper sheet groove 70 is tapered from the second end portion 72 toward the first end portion 71. For example, the upper sheet groove 70 may be formed such that the width w6 of the upper sheet groove 70 decreases from the second end portion 72 toward the first end portion 71. The upper sheet groove 70 may be formed such that the depth h2 of the upper sheet groove 70 decreases from the second end portion 72 toward the first end portion 71.

As described above, according to the present embodiment, the upper sheet groove 70 is formed in such a way as to have a decreasing cross-sectional passage area from the second end portion 72 toward the first end portion 71. Through the capillary action of the upper sheet groove 70, this applies, to the working liquid 2b, a motive force for going from the liquid flow channel portion 60 toward the upper sheet groove 70 and thus makes it possible to cause the working liquid 2b present in the liquid flow channel portion 60 to move to the vapor passage 51, 52 quickly through the upper sheet groove 70. Therefore, in a case where the upper sheet groove 70 having this configuration is disposed at the vaporization region SR, it is possible to facilitate the movement of the working liquid 2b from the liquid flow channel portion 60 to the vapor passage 51, 52 at the vaporization region SR effectively. Moreover, when there is a sudden rise in temperature, it is possible to cause the working vapor 2a having turned from the working liquid 2b due to evaporation inside the liquid flow channel portion 60 to move to the vapor passage 51, 52 quickly through the upper sheet groove 70 and thus to facilitate the movement of the working vapor 2a from the liquid flow channel portion 60 to the vapor passage 51, 52 at the vaporization region SR effectively. Furthermore, in a case where the cross-sectional passage area of the upper sheet groove 70 is larger than that of the liquid flow channel mainstream groove 61, it is possible to facilitate the movement of the working vapor 2a from the liquid flow channel portion 60 to the vapor passage 51, 52 at the vaporization region SR more effectively. Consequently, it is possible to further facilitate the circulation of the working fluid 2a, 2b inside the vapor chamber 1.

### Sixth Embodiment

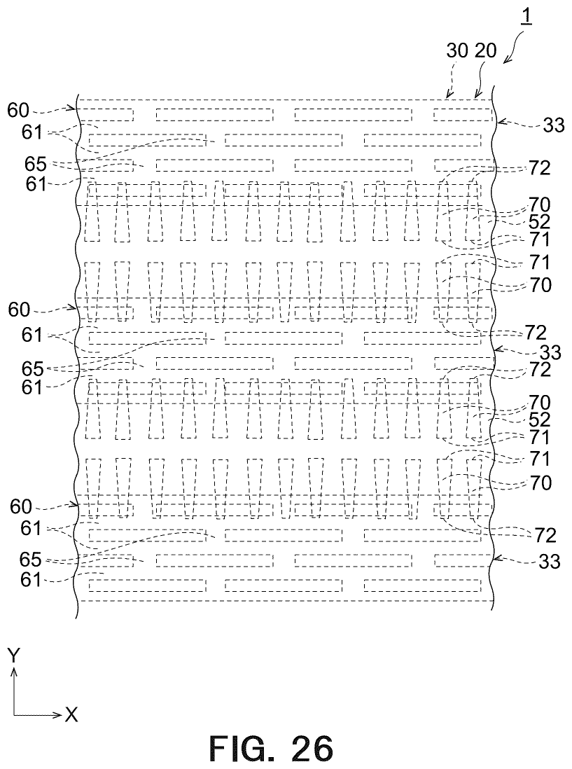

Next, a vapor chamber and an electronic apparatus according to a sixth embodiment of the present disclosure will now be described with reference to FIG. 26.

In the sixth embodiment illustrated in FIG. 26, the main difference lies in that a first sheet groove is formed in such a way as to have a decreasing cross-sectional passage area from a first end portion toward a second end portion, and, except for this difference, the configuration of this embodiment is substantially the same as that of the third embodiment illustrated in FIG. 23. In FIG. 26, the same reference signs are assigned to portions that are the same as those of the third embodiment illustrated in FIG. 23, and a detailed explanation thereof is omitted.

In the present embodiment, as illustrated in FIG. 26, the upper sheet groove 70 is formed in such a way as to have a decreasing cross-sectional passage area from the first end portion 71 toward the second end portion 72. That is, the upper sheet groove 70 is tapered from the first end portion 71 toward the second end portion 72. For example, the upper sheet groove 70 may be formed such that the width w6 of the upper sheet groove 70 decreases from the first end portion 71 toward the second end portion 72. The upper sheet groove 70 may be formed such that the depth h2 of the upper sheet groove 70 decreases from the first end portion 71 toward the second end portion 72.

As described above, according to the present embodiment, the upper sheet groove 70 is formed in such a way as to have a decreasing cross-sectional passage area from the first end portion 71 toward the second end portion 72. Through the capillary action of the upper sheet groove 70, this applies, to the working liquid 2b, a motive force for going from the upper sheet groove 70 toward the liquid flow channel portion 60 and thus makes it possible to cause the working liquid 2b present in the vapor passage 51, 52 to move to the liquid flow channel portion 60 quickly through the upper sheet groove 70. Therefore, in a case where the upper sheet groove 70 having this configuration is disposed at the condensation region CR, it is possible to facilitate the movement of the working liquid 2b from the vapor passage 51, 52 to the liquid flow channel portion 60 at the condensation region CR effectively. Moreover, in a case where the upper sheet groove 70 having this configuration is disposed at the vaporization region SR, when there is a sudden rise in temperature, it is possible to cause the working vapor 2a having turned from the working liquid 2b due to evaporation inside the liquid flow channel portion 60 to move to the vapor passage 51, 52 quickly through the upper sheet groove 70 and thus to facilitate the movement of the working vapor 2a from the liquid flow channel portion 60 to the vapor passage 51, 52 at the vaporization region SR effectively. Furthermore, in a case where the cross-sectional passage area of the upper sheet groove 70 is larger than that of the liquid flow channel mainstream groove 61, it is possible to facilitate the movement of the working vapor 2a from the liquid flow channel portion 60 to the vapor passage 51, 52 at the vaporization region SR more effectively. Consequently, it is possible to further facilitate the circulation of the working fluid 2a, 2b inside the vapor chamber 1.

### Seventh Embodiment

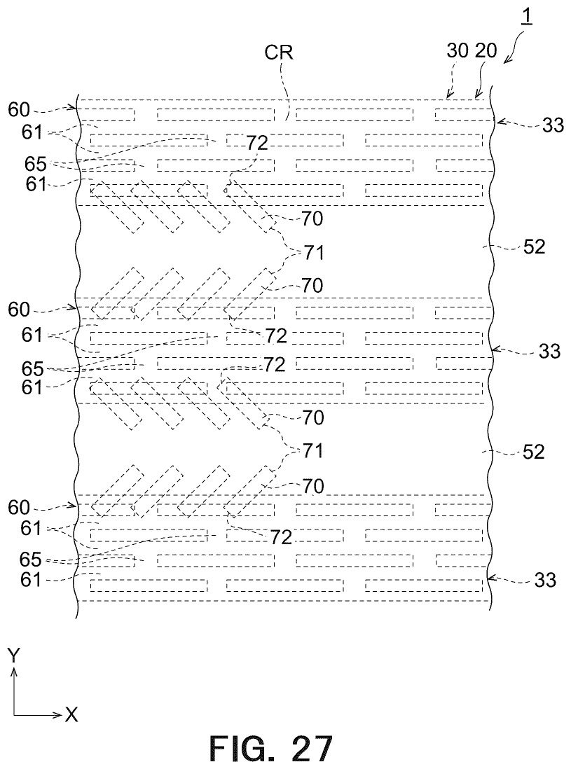

Next, a vapor chamber and an electronic apparatus according to a seventh embodiment of the present disclosure will now be described with reference to FIGS. 27 to 29.

In the seventh embodiment illustrated in FIGS. 27 to 29, the main difference lies in that first sheet grooves are arranged obliquely with respect to a first direction in a plan view, and, except for this difference, the configuration of this embodiment is substantially the same as that of the third embodiment illustrated in FIG. 23. In FIGS. 27 to 29, the same reference signs are assigned to portions that are the same as those of the third embodiment illustrated in FIG. 23, and a detailed explanation thereof is omitted.

In the present embodiment, as illustrated in FIG. 27, the upper sheet grooves 70 are arranged in an inclined manner with respect to the X direction in a plan view. The angle of inclination of the upper sheet grooves 70 may be any angle that is greater than 0° but not greater than 90°. It can also be said that the upper sheet grooves 70 are inclined with respect to the Y direction in a plan view.

In the example illustrated in FIG. 27, at positions of overlapping with the edge on the positive side in the Y direction of the land 33 in a plan view, the upper sheet grooves 70 are inclined such that the first end portion 71 of each of them is located on the positive side in the X direction and on the positive side in the Y direction relative to the second end portion 72 thereof. In addition, at positions of overlapping with the edge on the positive side in the Y direction of the land 33 in a plan view, the upper sheet grooves 70 are arranged in the X direction in parallel with one another. In the example illustrated in FIG. 27, four upper sheet grooves 70 are arranged thereat.

On the other hand, at positions of overlapping with the edge on the negative side in the Y direction of the land 33 in a plan view, the upper sheet grooves 70 are inclined such that the first end portion 71 of each of them is located on the positive side in the X direction and on the negative side in the Y direction relative to the second end portion 72 thereof. In addition, at positions of overlapping with the edge on the negative side in the Y direction of the land 33 in a plan view, the upper sheet grooves 70 are arranged in the X direction in parallel with one another. In the example illustrated in FIG. 27, four upper sheet grooves 70 are arranged thereat.

Each of the upper sheet grooves 70 may be located at a position near an end portion of the vapor chamber 1 (for example, an end portion on the negative side in the X direction of the vapor chamber 1). However, this does not imply any limitation. Each of the upper sheet grooves 70 may be located at any position in the vapor chamber 1.

As described above, according to the present embodiment, the upper sheet grooves 70 are arranged in an inclined manner with respect to the X direction in a plan view. This makes it possible to cause the working liquid 2b present in the vapor passage 51, 52 to move in such a way as to concentrate on the liquid flow channel portion 60 inside the condensation region CR, for example. Especially, even in a case where the liquid flow channel portion 60 is located at a position near an end portion of the vapor chamber 1, it is possible to cause a sufficient amount of the working liquid 2b to move to the liquid flow channel portion 60. Moreover, in a case where the upper sheet groove 70 having this configuration is disposed at the vaporization region SR, when there is a sudden rise in temperature, it is possible to cause the working vapor 2a having turned from the working liquid 2b due to evaporation inside the liquid flow channel portion 60 to move to the vapor passage 51, 52 quickly through the upper sheet groove 70 and thus to facilitate the movement of the working vapor 2a from the liquid flow channel portion 60 to the vapor passage 51, 52 at the vaporization region SR effectively. Especially, in a case where the upper sheet grooves 70 are inclined such that the first end portion 71 is oriented toward the condensation region CR, it is possible to direct the flow of the working vapor 2a toward the condensation region CR and thus to send the working vapor 2a to the condensation region CR quickly. Therefore, it is possible to improve the efficiency of sending the working liquid 2b and thus to facilitate the circulation of the working fluid 2a, 2b inside the vapor chamber 1.

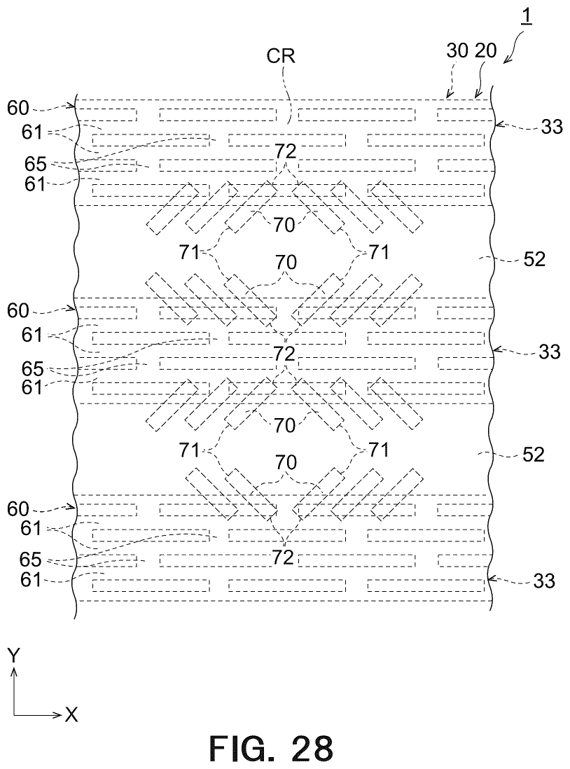

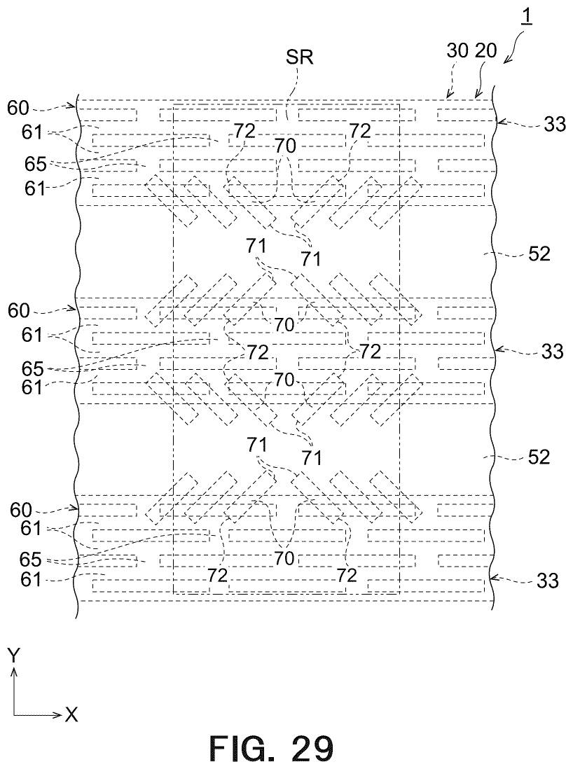

Having been described in the present embodiment above is an example in which, at the positions of overlapping with the edge of the land 33 in a plan view, the upper sheet grooves 70 are arranged in the X direction in parallel with one another. However, this does not imply any limitation. For example, as illustrated in FIGS. 28 and 29, the upper sheet grooves 70 may be arranged not in parallel with one another.

In the example illustrated in FIG. 28, six upper sheet grooves 70 are arranged in the X direction at positions of overlapping with the edge on the positive side in the Y direction of the land 33 in a plan view. Among these upper sheet grooves 70, three upper sheet grooves 70 located on the negative side in the X direction are inclined such that the first end portion 71 of each of them is located on the negative side in the X direction and on the positive side in the Y direction relative to the second end portion 72 thereof. Three upper sheet grooves 70 located on the positive side in the X direction are inclined such that the first end portion 71 of each of them is located on the positive side in the X direction and on the positive side in the Y direction relative to the second end portion 72 thereof.

On the other hand, six upper sheet grooves 70 are arranged in the X direction also at positions of overlapping with the edge on the negative side in the Y direction of the land 33 in a plan view. Among these upper sheet grooves 70, three upper sheet grooves 70 located on the negative side in the X direction are inclined such that the first end portion 71 of each of them is located on the negative side in the X direction and on the negative side in the Y direction relative to the second end portion 72 thereof. Three upper sheet grooves 70 located on the positive side in the X direction are inclined such that the first end portion 71 of each of them is located on the positive side in the X direction and on the negative side in the Y direction relative to the second end portion 72 thereof.

In this case, for example, it is possible to cause the working liquid 2b present in the vapor passage 51, 52 to move in such a way as to concentrate on the liquid flow channel portion 60 inside the condensation region CR. This makes it possible to cause a sufficient amount of the working liquid 2b to move to the liquid flow channel portion 60. Moreover, in a case where the upper sheet groove 70 having this configuration is disposed at the vaporization region SR, when there is a sudden rise in temperature, it is possible to cause the working vapor 2a having turned from the working liquid 2b due to evaporation inside the liquid flow channel portion 60 to move to the vapor passage 51, 52 quickly through the upper sheet groove 70 and thus to facilitate the movement of the working vapor 2a from the liquid flow channel portion 60 to the vapor passage 51, 52 at the vaporization region SR effectively. Especially, in a case where plural condensation regions CR are arranged, it is possible to direct the flow of the working vapor 2a toward each of the condensation regions CR and thus to send the working vapor 2a to each of the condensation regions CR quickly. Therefore, it is possible to improve the efficiency of sending the working liquid 2b and thus to facilitate the circulation of the working fluid 2a, 2b inside the vapor chamber 1.

In the example illustrated in FIG. 29, six upper sheet grooves 70 are arranged in the X direction at positions of overlapping with the edge on the positive side in the Y direction of the land 33 in a plan view. Among these upper sheet grooves 70, three upper sheet grooves 70 located on the negative side in the X direction are inclined such that the first end portion 71 of each of them is located on the positive side in the X direction and on the positive side in the Y direction relative to the second end portion 72 thereof. Three upper sheet grooves 70 located on the positive side in the X direction are inclined such that the first end portion 71 of each of them is located on the negative side in the X direction and on the positive side in the Y direction relative to the second end portion 72 thereof.

On the other hand, six upper sheet grooves 70 are arranged in the X direction also at positions of overlapping with the edge on the negative side in the Y direction of the land 33 in a plan view. Among these upper sheet grooves 70, three upper sheet grooves 70 located on the negative side in the X direction are inclined such that the first end portion 71 of each of them is located on the positive side in the X direction and on the negative side in the Y direction relative to the second end portion 72 thereof. Three upper sheet grooves 70 located on the positive side in the X direction are inclined such that the first end portion 71 of each of them is located on the negative side in the X direction and on the negative side in the Y direction relative to the second end portion 72 thereof.

In this case, for example, it is possible to cause the working liquid 2b present in the liquid flow channel portion 60 to move in such a way as to concentrate on the vapor passage 51, 52 inside the vaporization region SR. This makes it possible to cause the working liquid 2b to vaporize at the vaporization region SR efficiently. Therefore, it is possible to facilitate the circulation of the working fluid 2a, 2b inside the vapor chamber 1.

### Eighth Embodiment

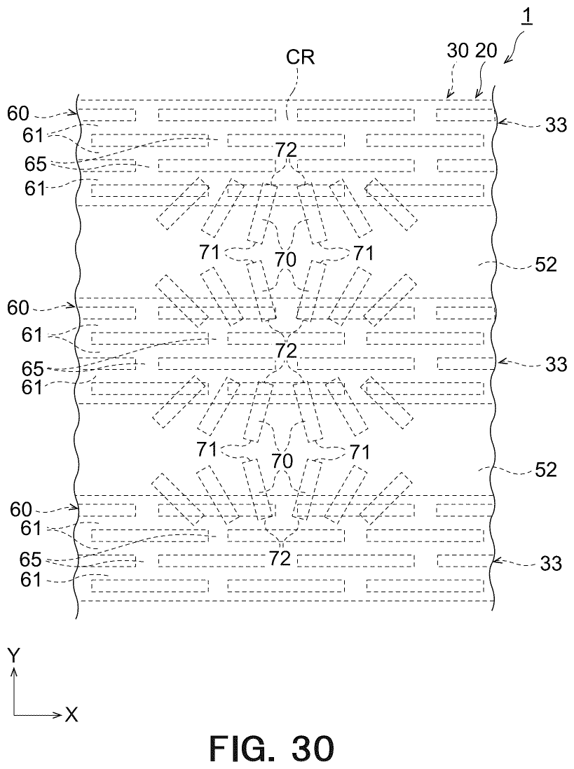

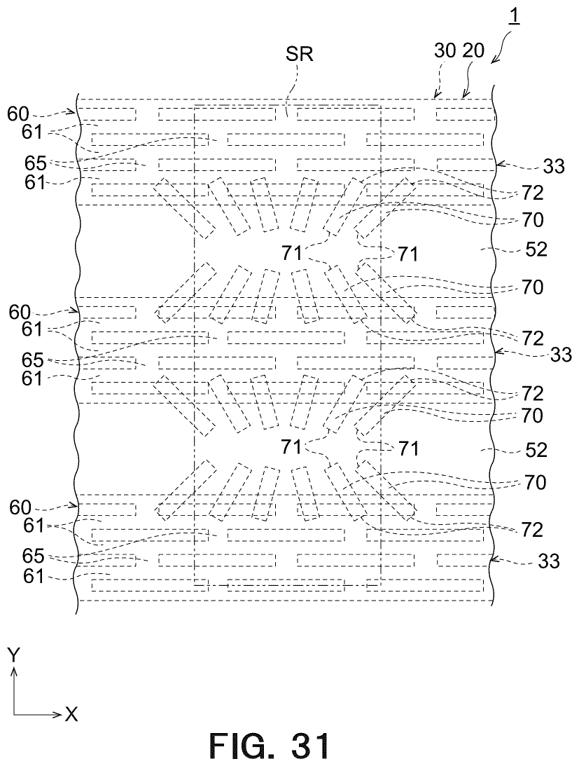

Next, a vapor chamber and an electronic apparatus according to an eighth embodiment of the present disclosure will now be described with reference to FIGS. 30 and 31.

In the eighth embodiment illustrated in FIGS. 30 and 31, the main difference lies in that a plurality of first sheet grooves is in a radial layout of arrangement in a plan view, and, except for this difference, the configuration of this embodiment is substantially the same as that of the third embodiment illustrated in FIG. 23. In FIGS. 30 and 31, the same reference signs are assigned to portions that are the same as those of the third embodiment illustrated in FIG. 23, and a detailed explanation thereof is omitted.

In the present embodiment, as illustrated in FIG. 30, the plurality of upper sheet grooves 70 is in a radial layout of arrangement in a plan view. In the example illustrated in FIG. 30, each of the upper sheet grooves 70 is disposed in an inclined manner with respect to the X direction. Each of the upper sheet grooves 70 is disposed such that its second end portion 72 is oriented toward a particular position in the liquid flow channel portion 60. The upper sheet grooves 70 are arranged in a radial layout such that each gap w7 (see FIG. 11) between the upper sheet grooves 70 located next to each other in the X direction decreases from the side where the vapor passage 51, 52 is located toward the side where the liquid flow channel portion 60 is located.

As described above, according to the present embodiment, the upper sheet grooves 70 are arranged in a radial layout in a plan view. This makes it possible to cause the working liquid 2b present in the vapor passage 51, 52 to move in such a way as to concentrate on the liquid flow channel portion 60 inside the condensation region CR, for example. Therefore, it is possible to cause a sufficient amount of the working liquid 2b to move to the liquid flow channel portion 60. Moreover, in a case where the upper sheet groove 70 having this configuration is disposed at the vaporization region SR, when there is a sudden rise in temperature, it is possible to cause the working vapor 2a having turned from the working liquid 2b due to evaporation inside the liquid flow channel portion 60 to move to the vapor passage 51, 52 quickly through the upper sheet groove 70 and thus to facilitate the movement of the working vapor 2a from the liquid flow channel portion 60 to the vapor passage 51, 52 at the vaporization region SR effectively. Especially, in a case where plural condensation regions CR are arranged, it is possible to direct the flow of the working vapor 2a toward each of the condensation regions CR and thus to send the working vapor 2a to each of the condensation regions CR quickly. Consequently, it is possible to improve the efficiency of sending the working liquid 2b and thus to facilitate the circulation of the working fluid 2a, 2b inside the vapor chamber 1.

Having been described in the present embodiment above is an example in which the upper sheet grooves 70 are arranged in a radial layout such that each gap w7 between the upper sheet grooves 70 located next to each other in the X direction decreases from the side where the vapor passage 51, 52 is located toward the side where the liquid flow channel portion 60 is located. However, this does not imply any limitation. For example, as illustrated in FIG. 31, the upper sheet grooves 70 may be arranged in a radial layout such that each gap w7 between the upper sheet grooves 70 located next to each other in the X direction decreases from the side where the liquid flow channel portion 60 is located toward the side where the vapor passage 51, 52 is located. Each of the upper sheet grooves 70 may be arranged such that its first end portion 71 is oriented toward a particular position in the vapor passage 51, 52.

In this case, for example, it is possible to cause the working liquid 2b present in the liquid flow channel portion 60 to move in such a way as to concentrate on the vapor passage 51, 52 inside the vaporization region SR. This makes it possible to cause the working liquid 2b to vaporize at the vaporization region SR efficiently. Therefore, it is possible to facilitate the circulation of the working fluid 2a, 2b inside the vapor chamber 1.

### Ninth Embodiment

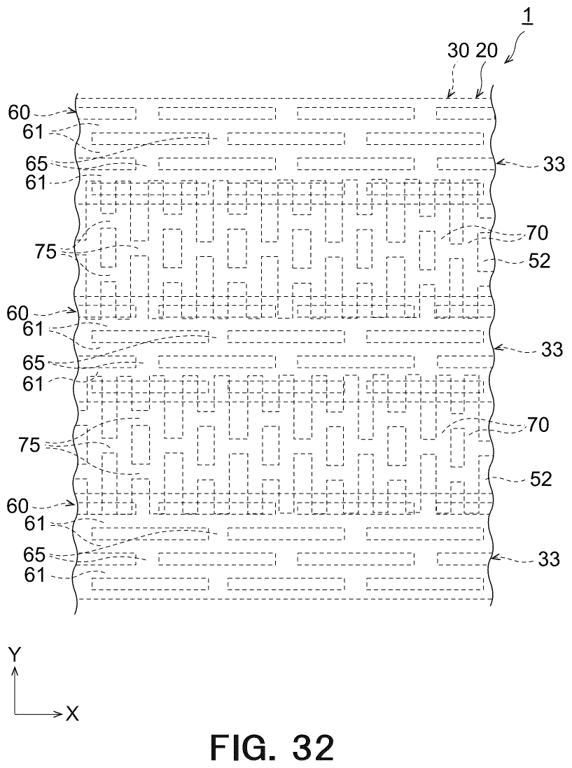

Next, a vapor chamber and an electronic apparatus according to a ninth embodiment of the present disclosure will now be described with reference to FIGS. 32 to 34.

In the ninth embodiment illustrated in FIGS. 32 to 34, the main difference lies in that a first sheet includes a communication groove(s) providing communication between first sheet grooves located next to each other, and, except for this difference, the configuration of this embodiment is substantially the same as that of the second embodiment illustrated in FIGS. 21 and 22. In FIGS. 32 to 34, the same reference signs are assigned to portions that are the same as those of the second embodiment illustrated in FIGS. 21 and 22, and a detailed explanation thereof is omitted.

In the present embodiment, as illustrated in FIG. 32, the upper sheet 20 includes an upper sheet communication groove 75 (communication groove) providing communication between the upper sheet grooves 70 located next to each other. The upper sheet 20 may include a plurality of upper sheet communication grooves 75. In the example illustrated in FIG. 32, each of the upper sheet grooves 70 extends in the Y direction. Each of the upper sheet grooves 70 is provided in such a way as to traverse the second vapor passage 52 in the Y direction. Each of the upper sheet communication grooves 75 is provided at a position where it overlaps with the second vapor passage 52 in a plan view. Each of the upper sheet communication grooves 75 extends in the X direction. Each of the upper sheet communication grooves 75 is connected to the upper sheet grooves 70 located next to each other.

The upper sheet communication groove 75 has a small cross-sectional passage area so that, mainly, the working liquid 2b will flow by capillary action. The cross-sectional passage area of the upper sheet communication groove 75 is smaller than that of the vapor passage 51, 52. The cross-sectional passage area of the upper sheet communication groove 75 may be equal to that of the upper sheet groove 70. However, this does not imply any limitation. The cross-sectional passage area of the upper sheet communication groove 75 may be smaller than, or larger than, that of the upper sheet groove 70.

Similarly to the upper sheet grooves 70, the upper sheet communication grooves 75 may be formed by etching the upper sheet 20 from the upper sheet inner surface 20a. Due to this etching, the upper sheet communication groove 75 may have a wall surface (not illustrated) that is curved, similarly to the upper sheet groove 70. The upper sheet communication grooves 75 may be formed in such a way as to be continuous to the upper sheet grooves 70 integrally.

The upper sheet communication grooves 75 may be arranged in the X direction and the Y direction. As illustrated in FIG. 32, the upper sheet communication grooves 75 may be in a staggered layout of arrangement. That is, the upper sheet communication grooves 75 located next to one another in the X direction may be arranged in a manner of being shifted from one another in the Y direction. The amount of this shift may be a half of the arrangement pitch of the upper sheet communication grooves 75 in the X direction.

As described above, according to the present embodiment, the upper sheet 20 includes the upper sheet communication groove(s) 75 providing communication between the upper sheet grooves 70 located next to each other. Through the capillary action of the upper sheet communication groove 75, this makes it possible to cause the working liquid 2b to move between the upper sheet grooves 70. Therefore, it is possible to suppress an imbalance between the upper sheet grooves 70 in terms of the presence of the working liquid 2b thereat. Consequently, it is possible to improve the efficiency of sending the working liquid 2b and thus to further facilitate the circulation of the working fluid 2a, 2b inside the vapor chamber 1.

Having been described in the present embodiment above is an example in which each of the upper sheet grooves 70 is provided in such a way as to traverse the second vapor passage 52 in the Y direction and the upper sheet communication grooves 75 are in a staggered layout of arrangement. However, this does not imply any limitation. The upper sheet grooves 70 and the upper sheet communication grooves 75 may be in any layout of arrangement.

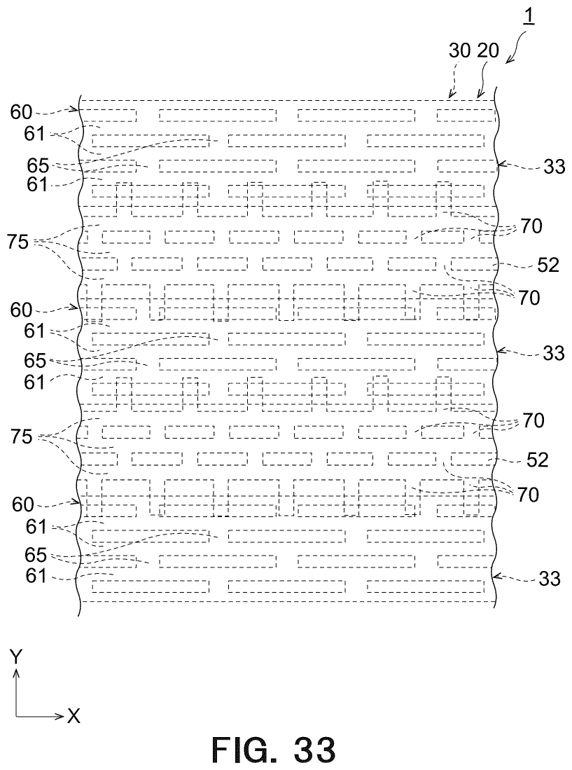

In the example illustrated in FIG. 33, the upper sheet grooves 70 are in a staggered layout of arrangement. That is, the upper sheet grooves 70 located next to one another in the X direction are arranged in a manner of being shifted from one another in the Y direction. The amount of this shift may be a half of the arrangement pitch of the upper sheet grooves 70 in the X direction.

In addition, in the example illustrated in FIG. 33, each of the upper sheet communication grooves 75 extends linearly in the X direction. Each of the upper sheet communication grooves 75 is connected to an end portion (the first end portion 71 or the second end portion 72) of each of the upper sheet grooves 70 to provide communication to each of the upper sheet grooves 70, 70′. Each of the upper sheet communication grooves 75 is provided at a position where it overlaps with the second vapor passage 52 in a plan view. The upper sheet communication grooves 75 are arranged in the Y direction. In the example illustrated in FIG. 33, three upper sheet communication grooves 75 are arranged in parallel with one another.

Even when this configuration is adopted, through the capillary action of the upper sheet communication groove 75, it is possible to cause the working liquid 2b to move between the upper sheet grooves 70. Therefore, it is possible to suppress an imbalance between the upper sheet grooves 70 in terms of the presence of the working liquid 2b thereat. Consequently, it is possible to improve the efficiency of sending the working liquid 2b and thus to further facilitate the circulation of the working fluid 2a, 2b inside the vapor chamber 1.

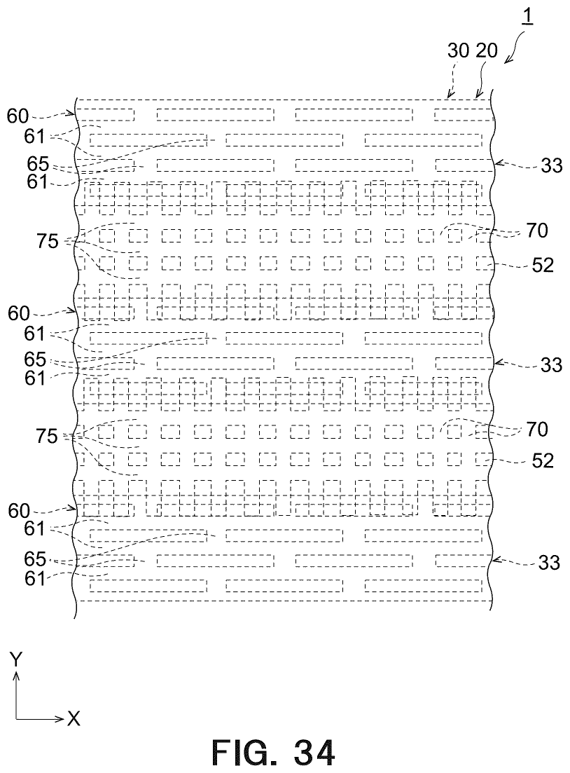

Having been described in the present embodiment above is an example in which the upper sheet communication grooves 75 are in a staggered layout of arrangement. However, this does not imply any limitation. As illustrated in FIG. 34, the upper sheet communication grooves 75 may be in a grid layout of arrangement. That is, the upper sheet communication grooves 75 may be lined up in the X direction and the Y direction.

Even when this configuration is adopted, through the capillary action of the upper sheet communication groove 75, it is possible to cause the working liquid 2b to move between the upper sheet grooves 70. Therefore, it is possible to suppress an imbalance between the upper sheet grooves 70 in terms of the presence of the working liquid 2b thereat. Consequently, it is possible to improve the efficiency of sending the working liquid 2b and thus to further facilitate the circulation of the working fluid 2a, 2b inside the vapor chamber 1.

### Tenth Embodiment

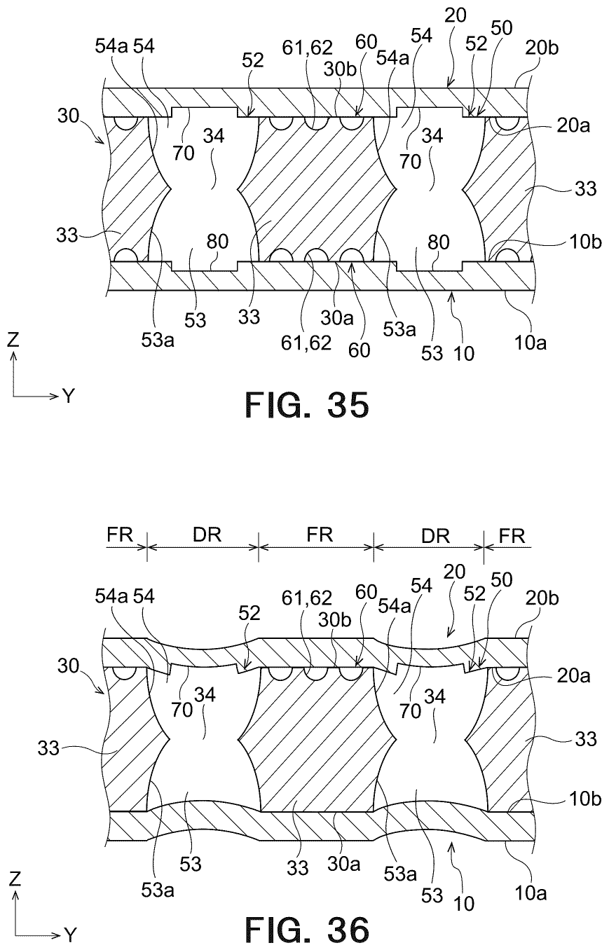

Next, a vapor chamber and an electronic apparatus according to a tenth embodiment of the present disclosure will now be described with reference to FIG. 35.

In the tenth embodiment illustrated in FIG. 35, the main difference lies in that a liquid flow channel portion is provided also in a second body surface, and a second sheet includes a second sheet groove provided in a second sheet inner surface, provided at a position of overlapping with a vapor passage in a plan view, and extending in a direction intersecting with a first direction, and, except for this difference, the configuration of this embodiment is substantially the same as that of the first embodiment illustrated in FIGS. 1 to 20. In FIG. 35, the same reference signs are assigned to portions that are the same as those of the first embodiment illustrated in FIGS. 1 to 20, and a detailed explanation thereof is omitted.

In the present embodiment, as illustrated in FIG. 35, the liquid flow channel portion 60 is provided in the wick sheet lower surface 30a, too. That is, the liquid flow channel portion 60 is provided not only in the wick sheet upper surface 30b but also in the wick sheet lower surface 30a.

In the present embodiment, as illustrated in FIG. 35, the lower sheet 10 includes a lower sheet groove(s) 80 (second sheet groove) provided in the lower sheet inner surface 10b. The lower sheet 10 may include a plurality of lower sheet grooves 80. Similarly to the upper sheet grooves 70, the lower sheet grooves 80 are provided at positions where they overlap with the vapor passage 51, 52 in a plan view. The lower sheet grooves 80 may be provided at positions where they are opposed to the upper sheet grooves 70. Similarly to the upper sheet groove 70, the lower sheet groove 80 extends in a direction intersecting with the X direction. For example, similarly to the upper sheet groove 70, the lower sheet groove 80 may extend in the Y direction, which is orthogonal to the X direction. Other aspects of the configuration of the lower sheet groove 80 are the same as those of the upper sheet groove 70 described above.

As described above, according to the present embodiment, the liquid flow channel portion 60 is provided in the wick sheet lower surface 30a, too. This makes it possible to make effective use of the space inside the vapor chamber 1 and thus to further facilitate the circulation of the working fluid 2a, 2b inside the vapor chamber 1.

Moreover, according to the present embodiment, the lower sheet 10 includes the lower sheet groove 80 provided in the lower sheet inner surface 10b; the lower sheet groove 80 is provided at a position of overlapping with the vapor passage 51, 52 in a plan view and extends in a direction intersecting with the X direction. This makes it possible to further facilitate the transfer of the working liquid 2b between the vapor passage 51, 52 and the liquid flow channel portion 60 in a case where the liquid flow channel portion 60 is provided in the wick sheet lower surface 30a, too. Therefore, it is possible to further facilitate the circulation of the working fluid 2a, 2b inside the vapor chamber 1.

### Eleventh Embodiment

Next, a vapor chamber and an electronic apparatus according to an eleventh embodiment of the present disclosure will now be described with reference to FIG. 36.

In the eleventh embodiment illustrated in FIG. 36, the main difference lies in that there is a depressed region where a first sheet is depressed toward a vapor passage, and a first sheet groove is located at the depressed region, and, except for this difference, the configuration of this embodiment is substantially the same as that of the first embodiment illustrated in FIGS. 1 to 20. In FIG. 36, the same reference signs are assigned to portions that are the same as those of the first embodiment illustrated in FIGS. 1 to 20, and a detailed explanation thereof is omitted.

In the present embodiment, as illustrated in FIG. 36, the vapor chamber 1 includes a flat region(s) FR where the upper sheet 20 has a flat shape and a depressed region(s) DR where the upper sheet 20 is depressed toward the vapor passage 51, 52 of the vapor flow channel portion 50. At the flat region FR, the lower sheet 10 may also have a flat shape. At the depressed region DR, the lower sheet 10 may also be depressed toward the vapor passage 51, 52 of the vapor flow channel portion 50. The depressed region DR can be formed by pressing a part of the vapor chamber 1 having a flat plate-like shape from the outside or by bending the vapor chamber 1 having a flat plate-like shape.

In the present embodiment, as illustrated in FIG. 36, the upper sheet groove 70 is located at the depressed region DR. That is, the upper sheet groove 70 is provided in, of the upper sheet inner surface 20a, the part located at the depressed region DR. On the other hand, the upper sheet groove 70 may be absent at a region other than the depressed region DR, that is, at the flat region FR.

As described above, according to the present embodiment, the upper sheet groove 70 is located at the depressed region DR. The cross-sectional passage area of the vapor passage 51, 52 at the depressed region DR is smaller than the cross-sectional passage area of the vapor passage 51, 52 at other regions. Because of this relationship, the working vapor 2a is prone to condensation at the depressed region DR and, therefore, the working liquid 2b is likely to be generated thereat. For this reason, there is a possibility that the working liquid 2b might stagnate at the depressed region DR. Addressing this issue, the upper sheet groove 70 is located at the depressed region DR. By this means, it is possible to facilitate the transfer of the working liquid 2b between the vapor passage 51, 52 and the liquid flow channel portion 60 at the depressed region DR. Therefore, it is possible to suppress the stagnation of the working liquid 2b at the depressed region DR. Consequently, it is possible to facilitate the circulation of the working fluid 2a, 2b inside the vapor chamber 1 effectively.

### Twelfth Embodiment

Next, a vapor chamber and an electronic apparatus according to a twelfth embodiment of the present disclosure will now be described with reference to FIG. 37.

In the twelfth embodiment illustrated in FIG. 37, the main difference lies in that a first sheet groove is provided at a position where it overlaps with a coupling portion in a plan view, and, except for this difference, the configuration of this embodiment is substantially the same as that of the first embodiment illustrated in FIGS. 1 to 20. In FIG. 37, the same reference signs are assigned to portions that are the same as those of the first embodiment illustrated in FIGS. 1 to 20, and a detailed explanation thereof is omitted.

In the present embodiment, as illustrated in FIG. 37, the upper sheet groove 70 is provided at a position where it overlaps with the coupling portion 38 in a plan view. It can also be said that the upper sheet groove 70 is provided at a position where it faces the coupling portion 38. As described earlier, the coupling portion 38 is a member that connects the lands 33 located next to each other.

In the example illustrated in FIG. 37, the coupling portion 38 is located at a position near the wick sheet lower surface 30a of the wick sheet 30. More specifically, the coupling portion 38 is disposed in a space that forms the lower vapor flow channel recessed portion 53 of the vapor passage 51, 52. The upper vapor flow channel recessed portion 54 of the vapor passage 51, 52 is allocated at a position near the wick sheet upper surface 30b of the wick sheet 30. The upper sheet groove 70 may be absent except at the position where it faces the coupling portion 38.

As described above, according to the present embodiment, the upper sheet groove 70 is provided at a position where it overlaps with the coupling portion 38 in a plan view. The cross-sectional passage area of the vapor passage 51, 52 at the position where the coupling portion 38 is provided is smaller than the cross-sectional passage area of the vapor passage 51, 52 at other positions. Because of this relationship, the working vapor 2a is prone to condensation at the position where the coupling portion 38 is provided and, therefore, the working liquid 2b is likely to be generated thereat. For this reason, there is a possibility that the working liquid 2b might stagnate thereat. Addressing this issue, the upper sheet groove 70 is provided at a position where it overlaps with the coupling portion 38 in a plan view. By this means, it is possible to facilitate the transfer of the working liquid 2b between the vapor passage 51, 52 and the liquid flow channel portion 60 thereat and thus to suppress the stagnation of the working liquid 2b. Therefore, it is possible to facilitate the circulation of the working fluid 2a, 2b inside the vapor chamber 1 effectively.

### Thirteenth Embodiment

Next, a vapor chamber and an electronic apparatus according to a thirteenth embodiment of the present disclosure will now be described with reference to FIG. 38.

In the thirteenth embodiment illustrated in FIG. 38, the main difference lies in that a first sheet groove is provided at a region located adjacent to a coupling portion in a first direction in a plan view, and, except for this difference, the configuration of this embodiment is substantially the same as that of the first embodiment illustrated in FIGS. 1 to 20. In FIG. 38, the same reference signs are assigned to portions that are the same as those of the first embodiment illustrated in FIGS. 1 to 20, and a detailed explanation thereof is omitted.

In the present embodiment, as illustrated in FIG. 38, the upper sheet groove 70 is provided at a region located adjacent to the coupling portion 38 in the X direction in a plan view. As described earlier, the coupling portion 38 is a member that connects the lands 33 located next to each other.

The coupling portion 38 may be disposed at a position near the wick sheet lower surface 30a of the wick sheet 30. The coupling portion 38 may be disposed in a space that forms the lower vapor flow channel recessed portion 53 of the vapor passage 51, 52, and the upper vapor flow channel recessed portion 54 of the vapor passage 51, 52 may be allocated at a position near the wick sheet upper surface 30b of the wick sheet 30. The upper sheet groove 70 may be absent except at the region located adjacent to the coupling portion 38 in the X direction in a plan view, that is, at a position away from the coupling portion 38 in a plan view. The region located adjacent to the coupling portion 38 in the X direction in a plan view may be, for example, a region within 300 μm from the coupling portion 38 in the X direction in a plan view, a region within 150 μm therefrom, or a region within 50 μm therefrom.

In the example illustrated in FIG. 38, the upper sheet groove 70 is provided at, of regions located adjacent to the coupling portion 38 in the X direction in a plan view, both in the X direction. However, this does not imply any limitation. The upper sheet groove 70 may be provided at a region on either one of the two sides in the X direction.

In the example illustrated in FIG. 38, the upper sheet groove 70 is not provided at a position where it overlaps with the coupling portion 38 in a plan view. However, this does not imply any limitation. The upper sheet groove 70 may be provided also at a position where it overlaps with the coupling portion 38 in a plan view.

As described above, according to the present embodiment, the upper sheet groove 70 is provided at a region located adjacent to the coupling portion 38 in the X direction in a plan view. The cross-sectional passage area of the vapor passage 51, 52 at the position where the coupling portion 38 is provided is smaller than the cross-sectional passage area of the vapor passage 51, 52 at other positions. Because of this relationship, also at the region located adjacent to the coupling portion 38 in the X direction, the working vapor 2a is prone to condensation and, therefore, the working liquid 2b is likely to be generated thereat. For this reason, there is a possibility that the working liquid 2b might stagnate thereat. Addressing this issue, the upper sheet groove 70 is provided at a region located adjacent to the coupling portion 38 in the X direction in a plan view. By this means, it is possible to facilitate the transfer of the working liquid 2b between the vapor passage 51, 52 and the liquid flow channel portion 60 thereat and thus to suppress the stagnation of the working liquid 2b. Therefore, it is possible to facilitate the circulation of the working fluid 2a, 2b inside the vapor chamber 1 effectively.

### Fourteenth Embodiment

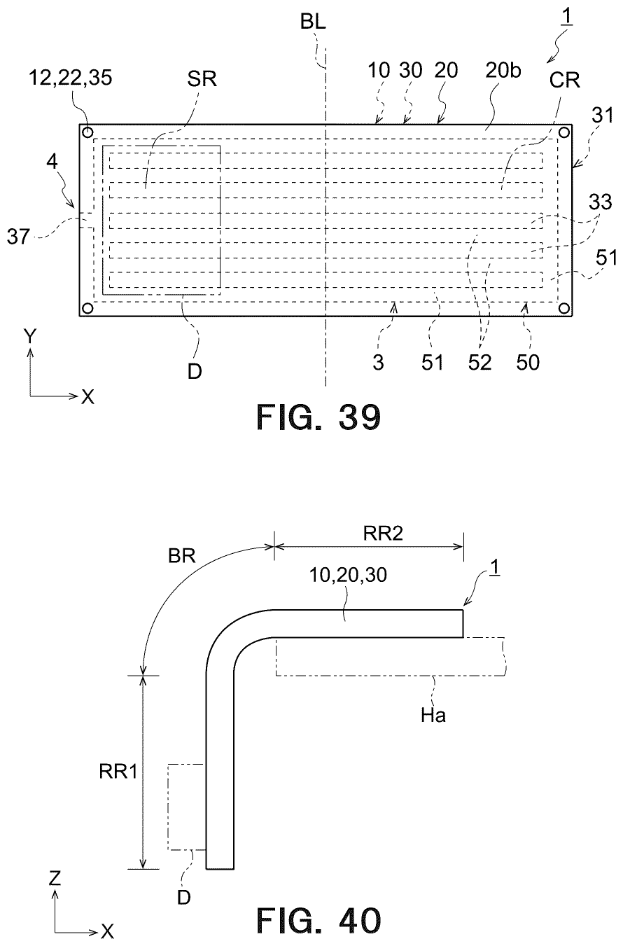

Next, a vapor chamber and an electronic apparatus according to a fourteenth embodiment of the present disclosure will now be described with reference to FIGS. 39 and 40.

In the fourteenth embodiment illustrated in FIGS. 39 and 40, the main difference lies in that there is a bending region where a vapor chamber is bent along a bending line, and a first sheet groove is located at the bending region, and, except for this difference, the configuration of this embodiment is substantially the same as that of the first embodiment illustrated in FIGS. 1 to 20. In FIGS. 39 and 40, the same reference signs are assigned to portions that are the same as those of the first embodiment illustrated in FIGS. 1 to 20, and a detailed explanation thereof is omitted.

In the present embodiment, the vapor chamber 1 is bent along a bending line BL illustrated in FIG. 39. FIG. 39 illustrates the vapor chamber 1 having a flat plate-like shape before being bent. In the example illustrated in FIG. 39, the bending line BL is provided at the center of the vapor chamber 1 in the X direction and extends in the Y direction. By bending the vapor chamber 1 along the bending line BL, it is possible to obtain the vapor chamber 1 in a bent form that includes a bending region BR where the vapor chamber 1 is bent along the bending line BL, and a first region RR1 and a second region RR2 where the vapor chamber 1 is separated region-wise with the bending region BR interposed therebetween, as illustrated in FIG. 40. As illustrated in FIG. 40, the device D may be mounted at the first region RR1, and the housing member Ha may be mounted at the second region RR2.

The vapor chamber 1 may be bent such that the lower sheet 10 is located at the inner side and the upper sheet 20 is located at the outer side. The bending angle may be any angle. In the example illustrated in FIG. 40, the bending angle is 90° (right angle). Therefore, the cross-sectional shape of the vapor chamber 1 is substantially an L shape. However, this does not imply any limitation. For example, the vapor chamber 1 may be bent in a curved manner to form the cross-sectional shape of the vapor chamber 1 into a U shape. In another example, the vapor chamber 1 may be bent more than once to form the cross-sectional shape of the vapor chamber 1 into a square-bracket shape or the like. Bending the vapor chamber 1 as described here makes it possible to enhance the degree of freedom in layout of the vapor chamber 1 inside the housing H. The bending angle means an angle formed by the lower sheet outer surface 10a or the upper sheet outer surface 20b at the first region RR1 of the vapor chamber 1 and the lower sheet outer surface 10a or the upper sheet outer surface 20b at the second region RR2 of the vapor chamber 1.

The vapor chamber 1 bent as described above can be manufactured by bending the vapor chamber 1 having a flat plate-like shape along the bending line BL in a bending process after a sealing process during the manufacturing of the vapor chamber 1.

In the present embodiment, the upper sheet groove 70 is located at the bending region BR. That is, the upper sheet groove 70 is provided in the upper sheet inner surface 20a of the upper sheet 20 at the bending region BR. The upper sheet groove 70 may be absent except at the bending region BR, that is, at the first region RR1 and the second region RR2.

As described above, according to the present embodiment, the upper sheet groove 70 is located at the bending region BR. When the vapor chamber 1 is bent, the lower sheet 10 located at the inner side receives a compressive stress at the bending region BR and thus could deform in such a way as to yield toward the lower vapor flow channel recessed portion 53. The upper sheet 20 located at the outer side receives a tensile stress at the bending region BR and thus could deform in such a way as to yield toward the upper vapor flow channel recessed portion 54. Due to this deformation, the depressed region DR having been described above in the eleventh embodiment while referring to FIG. 36 could be formed at the bending region BR of the vapor chamber 1 that is bent. For this reason, at the bending region BR, the cross-sectional passage area of the vapor passage 51, 52 could be small. Therefore, the working vapor 2a is prone to condensation at the bending region BR, and the working liquid 2b is likely to be generated thereat. For this reason, there is a possibility that the working liquid 2b might stagnate at the bending region BR. Addressing this issue, the upper sheet groove 70 is located at the bending region BR. By this means, it is possible to facilitate the transfer of the working liquid 2b between the vapor passage 51, 52 and the liquid flow channel portion 60 at the bending region BR. Therefore, it is possible to suppress the stagnation of the working liquid 2b at the bending region BR. Consequently, it is possible to facilitate the circulation of the working fluid 2a, 2b inside the vapor chamber 1 effectively.

Especially in the vapor chamber 1 in a bent form, the working vapor 2a is prone to condensation at the upper sheet inner surface 20a of the upper sheet 20 located at the outer side, and the working liquid 2b is likely to be generated thereat. As described above, the upper sheet groove 70 is provided in the upper sheet inner surface 20a. With this configuration, for example, through the capillary action of the upper sheet groove 70, it is possible to cause the working liquid 2b generated due to condensation at the upper sheet inner surface 20a to move to the liquid flow channel portion 60 quickly. Therefore, in a case where the vapor chamber 1 is bent such that the lower sheet 10 is located at the inner side and the upper sheet 20 is located at the outer side, it is possible to facilitate the movement of the working liquid 2b from the vapor passage 51, 52 to the liquid flow channel portion 60 at the condensation region CR effectively. Consequently, it is possible to further facilitate the circulation of the working fluid 2a, 2b inside the vapor chamber 1.

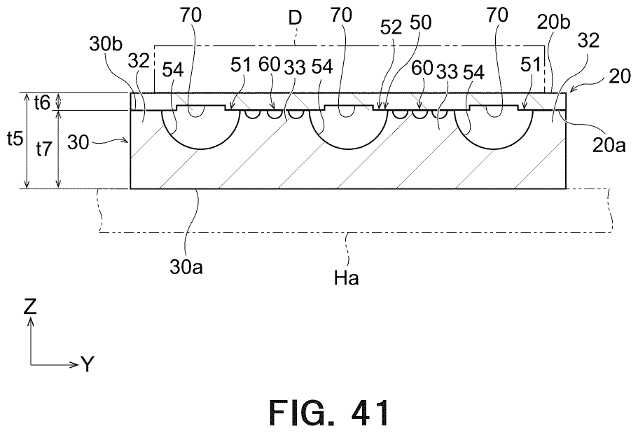

Having been described in each of the embodiments above is an example in which the vapor chamber 1 is made up of the lower sheet 10, the upper sheet 20, and the wick sheet 30. However, this does not imply any limitation. As illustrated in FIG. 41, the vapor chamber 1 may be made up of the upper sheet 20 and the wick sheet 30.

In the example illustrated in FIG. 41, the vapor chamber 1 includes the upper sheet 20 and the wick sheet 30 but does not include the lower sheet 10. In this case, the housing member Ha may be mounted on the wick sheet lower surface 30a of the wick sheet 30. The heat of the working vapor 2a is transferred to the housing member Ha through the wick sheet 30.

In the example illustrated in FIG. 41, the vapor flow channel portion 50 is provided in the wick sheet upper surface 30b but does not span to the wick sheet lower surface 30a through the wick sheet 30. That is, the first vapor passage 51 and the second vapor passages 52 of the vapor flow channel portion 50 are formed of the upper vapor flow channel recessed portion 54, and the lower vapor flow channel recessed portion 53 is not provided in the wick sheet 30.

In the example illustrated in FIG. 41, the upper sheet groove 70 is provided at a position where it faces the vapor flow channel portion 50 of the upper sheet 20. That is, the upper sheet 20 includes the upper sheet groove 70 provided in the upper sheet inner surface 20a; the upper sheet groove 70 is provided at a position of overlapping with the vapor passage 51, 52 in a plan view.

The thickness t5 of the vapor chamber 1 illustrated in FIG. 41 may be, for example, 100 μm to 1000 μm. The thickness t6 of the upper sheet 20 illustrated in FIG. 41 may be, for example, 6 μm to 200 μm. The thickness t7 of the wick sheet 30 illustrated in FIG. 41 may be, for example, 50 μm to 800 μm.

In the example illustrated in FIG. 41, the liquid flow channel portion 60 is not provided in the upper sheet inner surface 20a of the upper sheet 20. However, this does not imply any limitation. The liquid flow channel portion 60 may be provided in the upper sheet inner surface 20a of the upper sheet 20. In this case, the liquid flow channel portion 60 of the upper sheet 20 may be provided at a position where it faces the liquid flow channel portion 60 of the wick sheet 30.

As described above, the vapor chamber 1 may be made up of the upper sheet 20 and the wick sheet 30. Even when this configuration is adopted, since the upper sheet 20 includes the upper sheet groove 70, it is possible to facilitate the transfer of the working liquid 2b between the vapor passage 51, 52 and the liquid flow channel portion 60. Therefore, it is possible to facilitate the circulation of the working fluid 2a, 2b inside the vapor chamber 1. Moreover, in this case, it is possible to further reduce the thickness of the vapor chamber 1.

### Fifteenth Embodiment

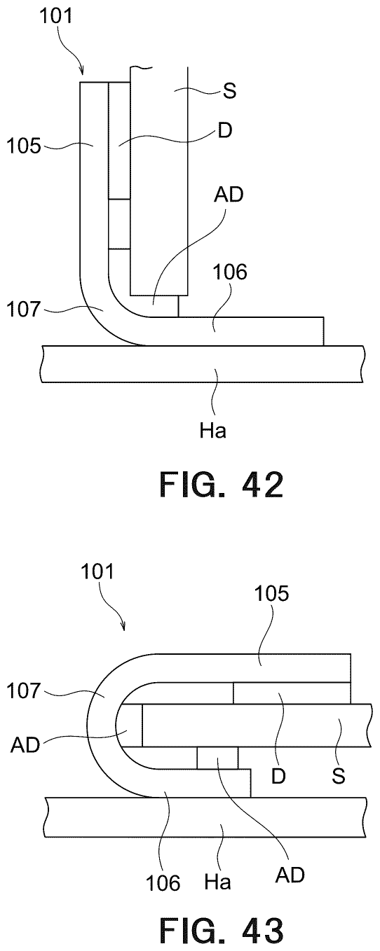

Next, a vapor chamber and an electronic apparatus according to a fifteenth present embodiment of the present disclosure will now be described with reference to FIGS. 42 to 66.

In some instances a vapor chamber is bent, depending on the internal structure of an electronic apparatus in which it is provided. In this case, since a vapor flow channel is bent, the vapor flow channel tends to collapse. For this reason, there is a problem that a flow channel resistance increases to obstruct the flow of working vapor inside a vapor flow channel portion.

An object of the present embodiment is to provide a vapor chamber capable of improving heat dissipation efficiency even when it is bent, and an electronic apparatus.

As illustrated in FIGS. 42 and 43, a vapor chamber 101 according to the present embodiment is bent. The vapor chamber 101 is bent in accordance with the internal structure of an electronic apparatus E. Depending on a positional relationship between the electronic apparatus E that involves heat generation and a housing member Ha that releases the heat, in some instances the vapor chamber 101 is bent. The housing member Ha is a member that is a constituent of the housing H.

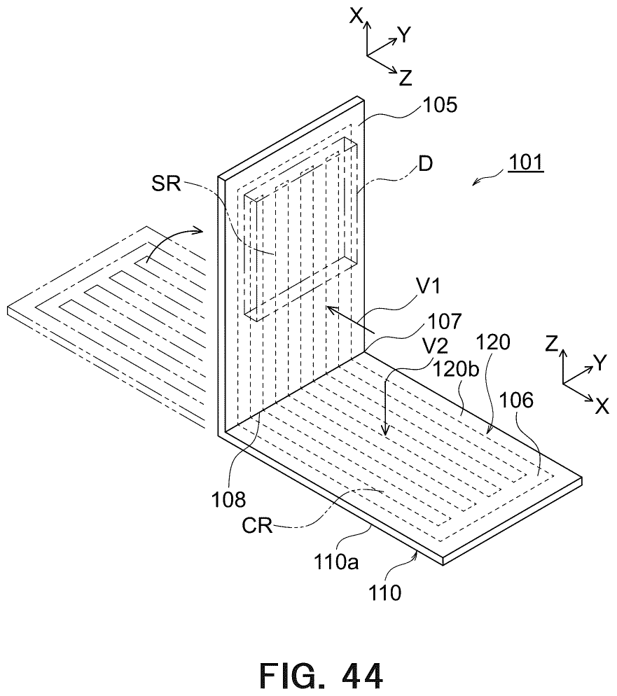

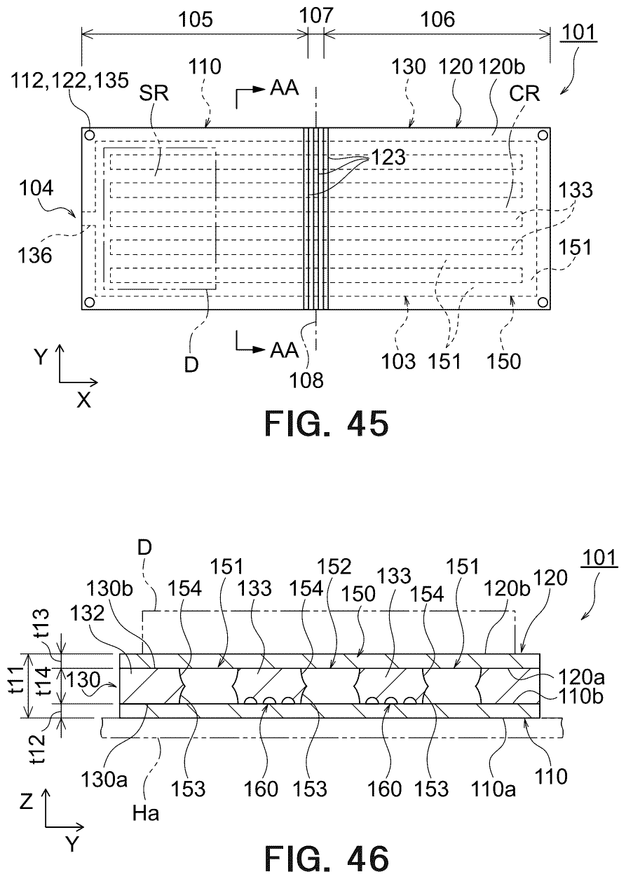

A case where an electronic device D and the housing member Ha are disposed as illustrated in FIG. 42 can be mentioned as an example. In this case, the vapor chamber 101 is bent at a right angle in such a way as to be in contact with the electronic device D and the housing member Ha. The electronic device D is mounted on a substrate S. The vapor chamber 101 may be bonded to the substrate S by using an adhesive AD. The adhesive AD may be pasted to a bending region 107 to be described later or pasted to a first region 105 or a second region 106 to be described later. Another example is a case where the electronic device D and the housing member Ha are disposed as illustrated in FIG. 43. In this case, the vapor chamber 101 is bent by 180° in such a way as to be in contact with the electronic device D and the housing member Ha. The vapor chamber 101 may be bonded to the substrate S by using the adhesive AD, as is the case with the example illustrated in FIG. 42. Though an example in which the vapor chamber 101 is bent along a single bending line 108 (see FIGS. 44 and 45) is illustrated in FIGS. 42 and 42, this does not imply any limitation. The vapor chamber 101 may be bent at different positions along two or more bending lines 108.

In the present embodiment, as illustrated in FIG. 44, the vapor chamber 101 bent at a right angle along a single bending line 108 will be taken as an example. The vapor chamber 101 illustrated in FIG. 44 is divided into the first region 105, the second region 106, and the bending region 107 located between the first region 105 and the second region 106. The bending region 107 is an example of a third region. The vapor chamber 101 is bent at a right angle at the bending region 107. The first region 105 and the second region 106 are substantially flat. The electronic device D may be in contact with the first region 105, and the housing member Ha may be in contact with the second region 106 (see FIG. 42). A detailed explanation of each region will be given later.

First, with reference to FIGS. 45 to 58, which illustrate the vapor chamber 101 before being bent, the structure of the vapor chamber 101 will be described here. The vapor chamber 101 illustrated in FIG. 44 can be obtained by bending the vapor chamber 101 having a flat plate-like shape illustrated in FIG. 45.

As illustrated in FIGS. 45 and 46, the vapor chamber 101 includes a sealed space 103 in which a working fluid 102a, 102b is enclosed. The electronic device D described above is cooled through repetition of phase changes of the working fluid 102a, 102b contained in the sealed space 103. Examples of the working fluid 102a, 102b include pure water, ethanol, methanol, acetone, etc., and a mixed solution thereof.

As illustrated in FIGS. 45 and 46, the vapor chamber 101 includes a first sheet 110, a second sheet 120, a wick sheet for vapor chamber use 130, a vapor flow channel portion 150, and a liquid flow channel portion 160. The second sheet 120 is provided on the side opposite of the first sheet 110 with respect to the wick sheet 130. The wick sheet for vapor chamber use 130 is an example of a body sheet and is sandwiched between the first sheet 110 and the second sheet 120. The wick sheet for vapor chamber use 130 will be hereinafter simply referred to as the wick sheet 130. In the vapor chamber 101 according to the present embodiment, the first sheet 110, the wick sheet 130, and the second sheet 120 are stacked in this order. Though the wick sheet 130 has a structure of a single sheet in the example disclosed in the present embodiment, the wick sheet 130 may be made up of two sheets or more. The number of sheets making up the wick sheet 130 may be any number.

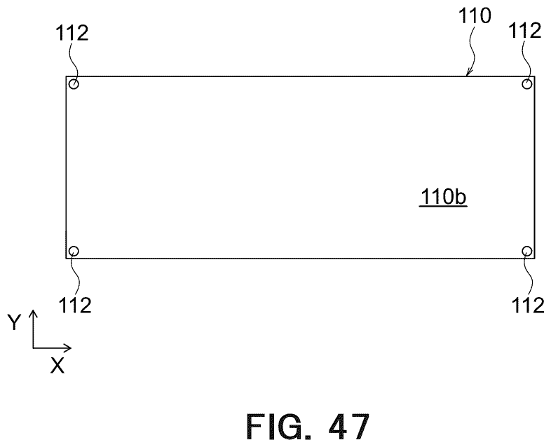

The vapor chamber 101 illustrated in FIG. 45, roughly speaking, has a thin flat plate-like shape. The planar shape of the vapor chamber 101 before being bent, though not limited to any particular shape, may be a rectangular shape as illustrated in FIG. 45. For example, the planar shape of the vapor chamber 101 may be a rectangular shape with one side having a length of 1 cm and the other side having a length of 3 cm, or a square shape with one side having a length of 15 cm. The planar dimensions of the vapor chamber 101 before being bent may be any dimensions. In the present embodiment, an example in which the planar shape of the vapor chamber 101 before being bent is a rectangular shape having an X direction to be described later as its longer-side direction will be described. In this case, as illustrated in FIGS. 47 to 55, the first sheet 110, the second sheet 120, and the wick sheet 130 may have a planar shape similar to that of the vapor chamber 101. The planar shape of the vapor chamber 101 before being bent is not limited to a rectangular shape but may be any shape such as a circular shape, an elliptical shape, an L shape, or a T shape.

As illustrated in FIGS. 44 and 45, the vapor chamber 101 has a vaporization region SR where the working liquid 102b vaporizes and a condensation region CR where the working vapor 102a condenses. The working vapor 102a is a working fluid that is in a gaseous state. The working liquid 102b is a working fluid that is in a liquid state.

The vaporization region SR is a region that overlaps with the electronic device D in a plan view and is in contact with the electronic device D. The vaporization region SR is located inside the first region 105; however, the position of the vaporization region SR may be any position. In the present embodiment, the vaporization region SR is formed on the negative side in the X direction (left side in FIG. 45) of the vapor chamber 101. Heat from the electronic device D is transferred to the vaporization region SR, the working liquid 102b vaporizes due to the heat, and the working vapor 102a is thus generated. Heat from the electronic device D can be transferred not only to the region that overlaps with the electronic device D in a plan view but also to the neighborhood of the region of overlap with the electronic device D. For this reason, the vaporization region SR may include the region that overlaps with the electronic device D and the neighborhood of this region in a plan view.

The condensation region CR is a region that does not overlap with the electronic device D in a plan view and where, mainly, the working vapor 102a releases heat to condense. The condensation region CR may be located inside the second region 106. The condensation region CR may be a region located around the vaporization region SR, including the second region 106. Heat from the working vapor 102a is released at the condensation region CR. The working vapor 102a cools to condense, and the working liquid 102b is thus generated.

The term “plan view” as used herein corresponds to a state of view in a direction orthogonal to a surface where the vapor chamber 101 receives heat from the electronic device D and a surface where the received heat is released. In the present embodiment, the surface where the heat is received corresponds to a second sheet outer surface 120b, which will be described later, of the second sheet 120, and the surface where the heat is released corresponds to a first sheet outer surface 110a, which will be described later, of the first sheet 110. The surface where the heat is received may correspond to the first sheet outer surface 110a. The surface where the heat is released may correspond to the second sheet outer surface 120b. For example, as illustrated in FIG. 44, at the first region 105 of the vapor chamber 101 that is bent, a state of view in a direction indicated by an arrow V1 corresponds to a plan view. At the second region 106, a state of view in a direction indicated by an arrow V2 corresponds to a plan view. As illustrated in FIG. 45, with regard to the vapor chamber 101 before being bent, a state of view of the vapor chamber 101 from above or a state of view thereof from below corresponds to a plan view.

As illustrated in FIG. 46, the first sheet 110 includes the first sheet outer surface 110a located at the opposite side facing away from the wick sheet 130 and a first sheet inner surface 110b facing the wick sheet 130. The housing member Ha described above may be in contact with the first sheet outer surface 110a at the second region 106 described above. A first body surface 130a, which will be described later, of the wick sheet 130 is in contact with the first sheet inner surface 110b. As illustrated in FIGS. 46 and 47, the first sheet 110 may be substantially flat. The first sheet 110 may have a substantially constant thickness.

As illustrated in FIG. 47, alignment holes 112 may be formed at four corners of the first sheet 110. In FIG. 47, an example in which the planar shape of the alignment hole 112 is a circle is illustrated; however, this does not imply any limitation. The alignment holes 112 may go through the first sheet 110.

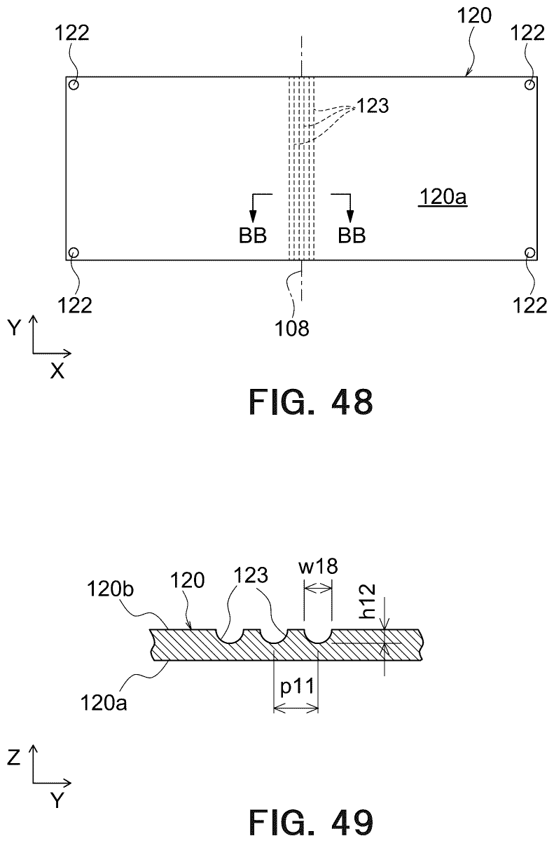

As illustrated in FIG. 47, the second sheet 120 includes a second sheet inner surface 120a facing the wick sheet 130 and the second sheet outer surface 120b located at the opposite side facing away from the wick sheet 130. The electronic device D described above may be in contact with the second sheet outer surface 120b at the first region 105 described above. A second body surface 130b, which will be described later, of the wick sheet 130 is in contact with the second sheet inner surface 120a. As illustrated in FIGS. 46 and 48, the second sheet 120 may be substantially flat. The second sheet 120 may have a substantially constant thickness.

As illustrated in FIG. 48, alignment holes 122 may be formed at four corners of the second sheet 120. In FIG. 48, an example in which the planar shape of the alignment hole 122 is a circle is illustrated; however, this does not imply any limitation. The alignment holes 122 may go through the second sheet 120.

As illustrated in FIGS. 45, 48, and 49, the second sheet 120 includes a plurality of second sheet outer surface recesses 123 located in the second sheet outer surface 120b. The second sheet outer surface recesses 123 may be located at the bending region 107 as illustrated in FIG. 45.

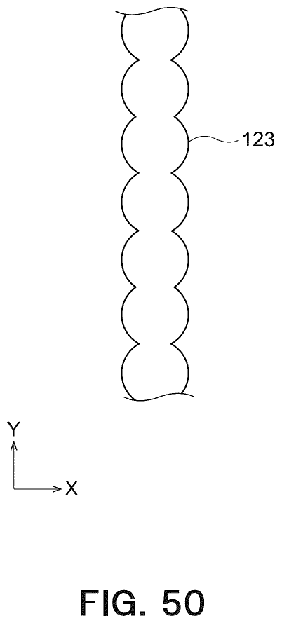

As illustrated in FIGS. 45 and 48, the second sheet outer surface recess 123 extends in a direction intersecting with the X direction in a plan view. The second sheet outer surface recess 123 may extend in the Y direction, and may extend along the bending line 108. The second sheet outer surface recess 123 may traverse a first vapor passage 151 or a second vapor passage 152 in a plan view. In the present embodiment, the second sheet outer surface recess 123 is formed throughout the entire area in the Y direction of the second sheet 120. In this case, the second sheet outer surface recess 123 extends in such a way as to traverse a frame portion 132, each of lands 133, and each of vapor passages 151 and 152 in a plan view. However, this does not imply any limitation. The second sheet outer surface recess 123 does not necessarily have to be formed throughout the entire area in the Y direction of the second sheet 120 as long as sufficient bendability of the vapor chamber 101 and sufficient cross-sectional passage area of each vapor passage 151, 152 after being bent are ensured. In the example illustrated in FIG. 45, the second sheet outer surface recess 123 has a linear shape extending in the Y direction in a plan view; however, this does not imply any limitation. For example, as illustrated in FIG. 50, the second sheet outer surface recess 123 may have a chain-of-beads-like shape made up of a plurality of circles arranged in the Y direction with partial overlaps with one another in a plan view. As described here, the planar shape of the second sheet outer surface recess 123 may be any shape.

As illustrated in FIG. 49, the second sheet outer surface recesses 123 are formed in a recessed manner in the second sheet outer surface 120b. The second sheet outer surface recesses 123 may be formed like grooves extending in the Y direction. The second sheet outer surface recesses 123 may be arranged in the X direction, and may be spaced at equal intervals in the X direction. The second sheet outer surface recesses 123 may be located in parallel with one another.

The bending region 107 is a region where the vapor chamber 101 is bent. Therefore, after the vapor chamber 101 is bent, the second sheet outer surface recesses 123 are located at the bending region 107. The second sheet outer surface recesses 123 extend along the bending line 108.

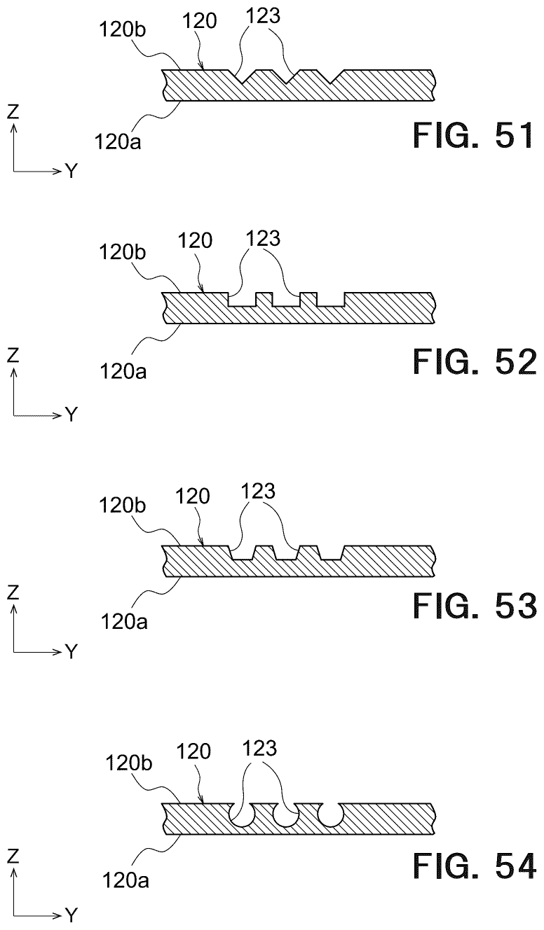

The second sheet outer surface recesses 123 are formed by performing etching from the second sheet outer surface 120b of the second sheet 120 in a second sheet etching process to be described later. Due to this etching, as illustrated in FIG. 49, the second sheet outer surface recess 123 may have a wall surface that is curved. This wall surface may demarcate the second sheet outer surface recess 123 and may be curved in such a way as to arch toward the second sheet inner surface 120a. In FIG. 49, an example in which the second sheet outer surface recess 123 has a semicircular cross-sectional shape is illustrated. However, the cross-sectional shape of the second sheet outer surface recess 123 may be any shape as long as it is possible to absorb stress acting on the second sheet 120 when the vapor chamber 101 is bent. For example, as illustrated in FIG. 51, the cross-sectional shape of the second sheet outer surface recess 123 may be a triangle. In another example, as illustrated in FIG. 52, the cross-sectional shape of the second sheet outer surface recess 123 may be a rectangle. In another example, as illustrated in FIG. 53, the cross-sectional shape of the second sheet outer surface recess 123 may be a trapezoid. In another example, as illustrated in FIG. 54, the cross-sectional shape of the second sheet outer surface recess 123 may be a partial circle having a greater width inside than at its opening. The second sheet outer surface recess 123 may be formed using a non-etching method. Any forming method may be used. For example, the second sheet outer surface recess 123 may be formed using press machining or router machining.

As illustrated in FIG. 49, the width w18 of the second sheet outer surface recess 123 may be, for example, 10 μm to 60 μm. The width w18 means the size of the second sheet outer surface recess 123 measured at the second sheet outer surface 120b. The width w18 corresponds to the X-dimensional size of the second sheet outer surface recess 123. The X-dimensional pitch p11 of the second sheet outer surface recesses 123 may be, for example, 20 μm to 100 μm. The depth h12 of the second sheet outer surface recess 123 may be, for example, 5 μm to 30 μm when the thickness t13 of the second sheet 120 is 35 μm or so. The depth h12 corresponds to the Z-dimensional size of the second sheet outer surface recess 123.

As illustrated in FIG. 45, the wick sheet 130 includes the first body surface 130a and the second body surface 130b located at the side opposite of the first body surface 130a. The first sheet inner surface 110b of the first sheet 110 is in contact with the first body surface 130a. The second sheet inner surface 120a of the second sheet 120 is in contact with the second body surface 130b.

The first sheet inner surface 110b of the first sheet 110 may be diffusion-bonded to the first body surface 130a of the wick sheet 130. The first sheet inner surface 110b and the first body surface 130a may be permanently bonded to each other.

Similarly, the second sheet inner surface 120a of the second sheet 120 may be diffusion-bonded to the second body surface 130b of the wick sheet 130. The second sheet inner surface 120a and the second body surface 130b may be permanently bonded to each other.

The term “permanently bonded” is not bound by its strict meaning but is used as a term that means bonding sufficient for keeping the hermetic property of the sealed space 103 when the vapor chamber 101 is operating.

As illustrated in FIGS. 45, 55, and 56, the wick sheet 130 according to the present embodiment includes the frame portion 132 and a plurality of lands 133. The frame portion 132 demarcates vapor flow channel portion 150 and, in a plan view, has a shape of a rectangular frame in the X direction and the Y direction. The land portion 133 is provided inside the frame portion 132 in a plan view. The vapor flow channel portion 150 is located around the lands 133. Therefore, the working vapor 102a flows around the lands 133. The frame portion 132 and the land portion 133 are portions where the material of the wick sheet 130 is left without being etched away in a wick sheet etching process to be described later. The first vapor passage 151 to be described later, through which the working vapor 102a flows, is formed between the frame portion 132 and the land portion 133 located next thereto. The second vapor passage 152 to be described later, through which the working vapor 102a flows, is formed between the lands 133 located next to each other.

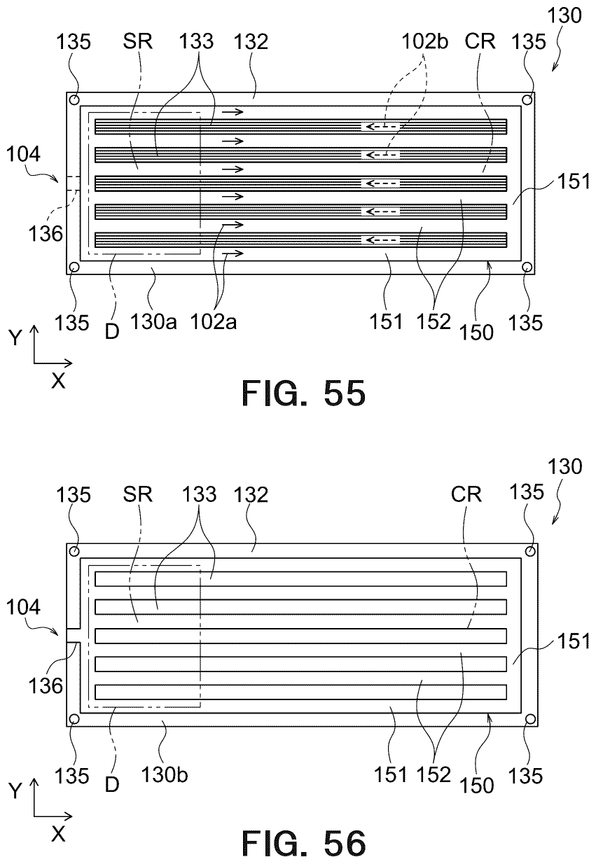

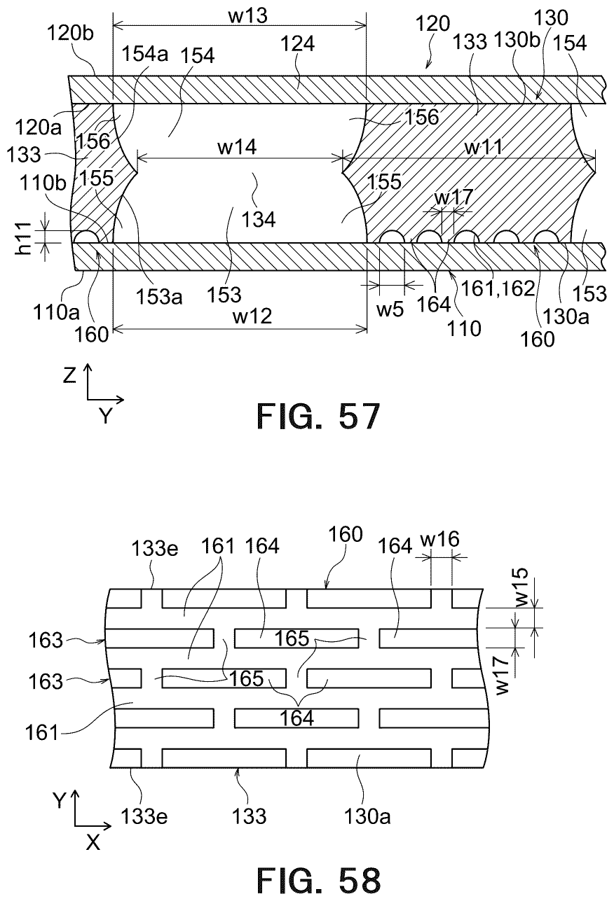

The land 133 may extend in an elongated manner, with its longer-side direction oriented in the X direction, in a plan view. The planar shape of the land 133 may be an elongated rectangle. The X direction is an example of a first direction, and corresponds to the horizontal direction in FIGS. 55 and 56. The lands 133 may be spaced at equal intervals in the Y direction. The Y direction is an example of a second direction, and is orthogonal to the X direction in a plan view. The Y direction is the width direction of the land 133, and corresponds to the vertical direction in FIGS. 55 and 56. The lands 133 may be located in parallel with one another. The direction orthogonal to each of the X direction and the Y direction is defined as the Z direction. The Z direction corresponds to the vertical direction in FIGS. 46 and 57, and corresponds to the thickness direction.

As illustrated in FIG. 57, the width w11 of the land 133 may be, for example, 100 μm to 1500 μm. The width w11 of the land 133 means the size of the land 133 in the Y direction. The width w11 means the size measured at a position in the Z direction of the wick sheet 130 where a penetrating-through portion 134 to be described later is located.

The X direction at the first region 105 and the second region 106 of the vapor chamber 101 illustrated in FIG. 44 corresponds to the direction that is along the longer sides of the lands 133. The X direction at the first region 105 corresponds to the vertical direction in FIG. 44. The Y direction at the first region 105 and the second region 106 of the vapor chamber 101 illustrated in FIG. 44 corresponds to the direction in which the lands 133 are arranged. The Z direction corresponds to, at the first region 105 and the second region 106 of the vapor chamber 101 illustrated in FIG. 44, the direction orthogonal to the vapor chamber 101. The Z direction at the second region 106 corresponds to the vertical direction in FIG. 44.

The frame portion 132 and each of the lands 133 are diffusion-bonded to the first sheet 110 and the second sheet 120. This enhances the mechanical strength of the vapor chamber 101. A wall surface 153a of a first vapor flow channel recessed portion 153 to be described later and a wall surface 154a of a second vapor flow channel recessed portion 154 to be described later constitute a sidewall of the land portion 133. The first body surface 130a of the wick sheet 130 and the second body surface 130b thereof may be flat throughout the frame portion 132 and each of the lands 133.

As illustrated in FIGS. 55 and 56, alignment holes 135 may be formed at four corners of the wick sheet 130. In FIGS. 55 and 56, an example in which the planar shape of the alignment hole 135 is a circle is illustrated; however, this does not imply any limitation. The alignment holes 135 may go through the wick sheet 130.

As illustrated in FIG. 46, the vapor flow channel portion 150 may be provided in the first body surface 130a of the wick sheet 130. The vapor flow channel portion 150 is an example of a space portion. The vapor flow channel portion 150 may be a channel through which, mainly, the working vapor 102a flows. The working liquid 102b may also flow through the vapor flow channel portion 150. In the present embodiment, the vapor flow channel portion 150 may span from the first body surface 130a to the second body surface 130b through the wick sheet 130. The vapor flow channel portion 150 may be covered by the first sheet 110 at the first body surface 130a and covered by the second sheet 120 at the second body surface 130b.

As illustrated in FIGS. 55 and 56, the vapor flow channel portion 150 according to the present embodiment may include a first vapor passage 151 and a plurality of second vapor passages 152. Each of the first vapor passage 151 and the second vapor passage 152 is an example of a working fluid passage. The first vapor passage 151 is provided between the frame portion 132 and the land portion 133. The first vapor passage 151 is formed in a continuous manner inside the frame portion 132 and outside the land portion 133. The planar shape of the first vapor passage 151 may be a rectangular frame in the X direction and the Y direction. The second vapor passage 152 is formed between the lands 133 located next to each other. The planar shape of the second vapor passage 152 may be an elongated rectangle. The vapor flow channel portion 150 is partitioned into the first vapor passage 151 and the plurality of second vapor passages 152 by the plurality of lands 133.

As illustrated in FIG. 46, the first vapor passage 151 and the second vapor passage 152 may span from the first body surface 130a of the wick sheet 130 to the second body surface 130b thereof. In this case, the first vapor passage 151 and the second vapor passage 152 are through-hole passages from the first body surface 130a to the second body surface 130b. The first vapor passage 151 and the second vapor passage 152 include the first vapor flow channel recessed portion 153, which is provided in the first body surface 130a, and the second vapor flow channel recessed portion 154, which is provided in the second body surface 130b. The first vapor flow channel recessed portion 153 and the second vapor flow channel recessed portion 154 are in communication with each other.

The first vapor flow channel recessed portion 153 may be formed by performing etching from the first body surface 130a of the wick sheet 130 in a wick sheet etching process to be described later. The first vapor flow channel recessed portion 153 is formed in a recessed manner in the first body surface 130a. As illustrated in FIG. 57, the first vapor flow channel recessed portion 153 may have a wall surface 153a that is curved. FIG. 57 illustrates a cross section orthogonal to the X direction. The wall surface 153a may demarcate the first vapor flow channel recessed portion 153, and may be curved in such a way as to come closer to the opposed wall surface 153a as it approaches the second body surface 130b. The first vapor flow channel recessed portion 153 constitutes, of the first vapor passage 151, the part located relatively near the first sheet 110, and, of the second vapor passage 152, the part located relatively near the first sheet 110.

The width w12 of the first vapor flow channel recessed portion 153 at the first region 105 and the second region 106 may be, for example, 100 μm to 5000 μm. The width w12 of the first vapor flow channel recessed portion 153 is the Y-directional size of the first vapor flow channel recessed portion 153 measured at the first body surface 130a. The width w12 corresponds to the Y-directional size of, of the first vapor passage 151, the part extending in the X direction, and corresponds to the Y-directional size of the second vapor passage 152. The width w12 corresponds also to the X-directional size of, of the first vapor passage 151, the part extending in the Y direction.

The second vapor flow channel recessed portion 154 may be formed by performing etching from the second body surface 130b of the wick sheet 130 in a wick sheet etching process to be described later. The second vapor flow channel recessed portion 154 is formed in a recessed manner in the second body surface 130b. As illustrated in FIG. 57, the second vapor flow channel recessed portion 154 may have a wall surface 154a that is curved. The wall surface 154a may demarcate the second vapor flow channel recessed portion 154, and may be curved in such a way as to come closer to the opposed wall surface 154a as it approaches the first body surface 130a. The second vapor flow channel recessed portion 154 constitutes, of the first vapor passage 151, the part located relatively near the second sheet 120, and, of the second vapor passage 152, the part located relatively near the second sheet 120.

Similarly to the width w12 of the first vapor flow channel recessed portion 153 described above, the width w13 of the second vapor flow channel recessed portion 154 at the first region 105 and the second region 106 may be, for example, 100 μm to 5000 μm. The width w13 of the second vapor flow channel recessed portion 154 is the Y-directional size of the second vapor flow channel recessed portion 154 measured at the second body surface 130b. The width w13 corresponds to the Y-directional size of, of the first vapor passage 151, the part extending in the X direction, and corresponds to the Y-directional size of the second vapor passage 152. The width w13 corresponds also to the X-directional size of, of the first vapor passage 151, the part extending in the Y direction. The width w13 of the second vapor flow channel recessed portion 154 may be equal to, or different from, the width w12 of the first vapor flow channel recessed portion 153.

As illustrated in FIG. 57, the wall surface 153a of the first vapor flow channel recessed portion 153 and the wall surface 154a of the second vapor flow channel recessed portion 154 may be connected to each other to form the penetrating-through portion 134. In the present embodiment, the planar shape of the penetrating-through portion 134 at the first vapor passage 151 may be a rectangular frame. The planar shape of the penetrating-through portion 134 at the second vapor passage 152 may be an elongated rectangle. The penetrating-through portion 134 may be defined by a ridgeline formed by the meeting of the wall surface 153a of the first vapor flow channel recessed portion 153 and the wall surface 154a of the second vapor flow channel recessed portion 154. As illustrated in FIG. 57, the ridgeline may be formed in such a way as to protrude inward of the vapor passage 151, 152. The planar area of the first vapor passage 151 at the penetrating-through portion 134 may be the smallest; the planar area of the second vapor passage 152 at the penetrating-through portion 134 may be the smallest. The width w14 of the penetrating-through portion 134 at each vapor passage 151, 152 may be, for example, 400 μm to 5000 μm. The width w14 of the penetrating-through portion 134 means the width w14 of the penetrating-through portion 134 at the first region 105 and the second region 106 and corresponds to the gap between the lands 133 located next to each other in the Y direction. As illustrated in FIG. 57, the width w14 may be the gap between the innermost points of the lands 133 protruding inward of the vapor passage 151, 152.

The position of the penetrating-through portion 134 in the Z direction may be the center between the first body surface 130a and the second body surface 130b. Alternatively, the position of the penetrating-through portion 134 may be closer to the first sheet 110 than the center, or closer to the second sheet 120 than the center. The position of the penetrating-through portion 134 in the Z direction may be any position.

In the present embodiment, as described above, the cross-sectional shape of each of the first vapor passage 151 and the second vapor passage 152 includes the penetrating-through portion 134 defined by a ridgeline formed in such a way as to protrude inward. However, this does not imply any limitation. For example, the cross-sectional shape of the first vapor passage 151, and the cross-sectional shape of the second vapor passage 152, may be a trapezoid, a parallelogram, or a barrel.

The vapor flow channel portion 150 including the first vapor passage 151 and the second vapor passages 152 configured as described above constitute a part of the sealed space 103 described above. Each vapor passage 151, 152 has a relatively large cross-sectional passage area so that the working vapor 102a will flow.

In FIG. 57, for the sake of clarity, the first, second vapor passage 151, 152 is illustrated in an enlarged manner. In this figure, the number of mainstream grooves 161 to be described later is different from that of FIG. 46.

Though not illustrated, a plurality of supports supporting the land portion 133 onto the frame portion 132 may be provided inside each vapor passage 151, 152. Supports supporting the lands 133 located next to one another may be provided. These supports may be provided on both sides with respect to the land portion 133 in the X direction, and may be provided on both sides with respect to the land portion 133 in the Y direction. The supports may be formed in such a way as not to obstruct the flow of the working vapor 102a diffusing in the vapor flow channel portion 150. For example, the supports may be located near either one, the first body surface 130a of the wick sheet 130 or the second body surface 130b thereof, and there may be a space that forms the vapor flow channel portion 150 near the other. This makes it possible to make the thickness of the supports less than the thickness of the wick sheet 130 and thus prevents the first vapor passage 151 and the second vapor passages 152 from being split in the X direction and the Y direction.

As illustrated in FIG. 45, the vapor chamber 101 may include an injection portion 104 for injecting the working liquid 102b into the sealed space 103. The injection portion 104 includes an injection flow channel 136 that is in communication with the first vapor passage 151. The position of the injection portion 104 may be any position. As illustrated in FIGS. 55 and 56, the injection flow channel 136 may be formed in a recessed manner in the second body surface 130b. Alternatively, the injection flow channel 136 may be formed in a recessed manner in the first body surface 130a. Depending on the structure of the liquid flow channel portion 160, the injection flow channel 136 may be in communication with the liquid flow channel portion 160.

As illustrated in FIGS. 46, 55, and 57, the liquid flow channel portion 160 may be formed between the first sheet 110 and the wick sheet 130. In the present embodiment, the liquid flow channel portion 160 is formed in the first body surface 130a of each of the lands 133. The liquid flow channel portion 160 may be a channel through which, mainly, the working liquid 102b flows. The working vapor 102a described above may flow through the liquid flow channel portion 160. The liquid flow channel portion 160 constitutes a part of the sealed space 103 described above and is in communication with the vapor flow channel portion 150. The liquid flow channel portion 160 is configured as a capillary structure for sending the working liquid 102b to the vaporization region SR. The liquid flow channel portion 160 is sometimes called a wick. The liquid flow channel portion 160 may be formed throughout the entirety of the first body surface 130a of each of the lands 133. Though not illustrated in FIG. 55, etc., the liquid flow channel portion 160 may be formed at an inner portion of the first body surface 130a of the frame portion 132. In the present embodiment, no liquid flow channel portion is formed in the second body surface 130b of the land portion 133 and the second body surface 130b of the frame portion 132.

As illustrated in FIG. 58, the liquid flow channel portion 160 is an example of a first groove aggregate that includes a plurality of grooves. More specifically, the liquid flow channel portion 160 includes a plurality of mainstream grooves 161 and a plurality of communication grooves 165. The mainstream groove 161 and the communication groove 165 of the liquid flow channel portion 160 are an example of a first groove. The mainstream groove 161 and the communication groove 165 are grooves through which the working liquid 102b flows. The communication groove 165 is in communication with the mainstream groove 161.

As illustrated in FIG. 58, each of the mainstream grooves 161 extends in the X direction. The mainstream groove 161 has a small cross-sectional passage area so that, mainly, the working liquid 102b will flow by capillary action. The cross-sectional passage area of the mainstream groove 161 is smaller than that of the vapor passage 151, 152. The mainstream groove 161 is configured to send, to the vaporization region SR, the working liquid 102b having condensed from the working vapor 102a. The mainstream grooves 161 may be spaced at equal intervals in the Y direction, which is orthogonal to the X direction. The mainstream grooves 161 may be located in parallel with one another.

The mainstream grooves 161 are formed by performing etching from the first body surface 130a of the wick sheet 130 in a wick sheet etching process to be described later. Due to this etching, as illustrated in FIG. 57, the mainstream groove 161 may have a wall surface 162 that is curved. The wall surface 162 may demarcate the mainstream groove 161 and may be curved in such a way as to arch toward the second body surface 130b.

As illustrated in FIGS. 57 and 58, the width w15 of the mainstream groove 161 may be less than the width w12 of the first vapor flow channel recessed portion 153. The width w15 of the mainstream groove 161 may be less than the width w11 of the land 133. The width w15 of the mainstream groove 161 may be, for example, 5 μm to 400 μm. The width w15 means the size of the mainstream groove 161 measured at the first body surface 130a. In FIGS. 57 and 58, the width w15 corresponds to the Y-dimensional size of the mainstream groove 161. The depth h11 of the mainstream groove 161 may be, for example, 3 μm to 300 μm. The depth h11 corresponds to the Z-dimensional size of the mainstream groove 161.

As illustrated in FIG. 58, each of the communication grooves 165 extends in a direction different from the X direction. Each of the communication grooves 165 according to the present embodiment extends in the Y direction and is formed perpendicularly to the mainstream grooves 161. Some of the communication grooves 165 provide communication between the mainstream grooves 161 located next to each other. Others of the communication grooves 165 provide communication between the first vapor passage 151 or the second vapor passage 152 and the mainstream groove 161. That is, the latter of the communication grooves 165 extends from an edge 133e of the land portion 133 in the Y direction to the mainstream groove 161 located next to the edge 133e. In this way, the first vapor passage 151 is in communication with the mainstream groove 161, and the second vapor passage 152 is in communication with the mainstream groove 161.

The communication groove 165 has a small cross-sectional passage area so that, mainly, the working liquid 102b will flow by capillary action. The cross-sectional passage area of the communication groove 165 is smaller than that of the vapor passage 151, 152. The communication grooves 165 are spaced at predetermined intervals in the X direction. The communication grooves 165 may be located in parallel with one another.

The communication grooves 165 may also be formed using etching, similarly to the mainstream grooves 161. Due to this etching, the communication groove 165 may also have a wall surface (not illustrated) that is curved, similarly to the mainstream groove 161. The width w16 of the communication groove 165 may be less than the width w12 of the first vapor flow channel recessed portion 153. The width w16 of the communication groove 165 may be less than the width w11 of the land 133. As illustrated in FIG. 58, the width w16 of the communication groove 165 may be equal to the width w15 of the mainstream groove 161. The width w16 may be greater than, or less than, the width w15. The width w16 means the size of the communication groove 165 measured at the first body surface 130a. In FIG. 58, the width w16 corresponds to the X-dimensional size of the communication groove 165. The depth of the communication groove 165 may be equal to the depth h11 of the mainstream groove 161. The depth of the communication groove 165 may be greater than, or less than, the depth h11.

As illustrated in FIG. 58, the liquid flow channel portion 160 includes a plurality of convex rows 163. The convex row 163 is formed on the first body surface 130a of each of the lands 133. The convex row 163 is located between the mainstream grooves 161 located next to each other. Each of the convex rows 163 includes a plurality of protrusions 164 arranged in the X direction. The protrusions 164 are in contact with the first sheet 110. Each of the protrusions 164 has a rectangular shape in a plan view, with its longer-side direction oriented in the X direction, as illustrated in FIG. 58. The mainstream groove 161 is disposed between the protrusions 164 located next to each other in the Y direction. The communication groove 165 is disposed between the protrusions 164 located next to each other in the X direction.

The protrusions 164 are portions where the material of the wick sheet 130 is left without being etched away in a wick sheet etching process to be described later. In the present embodiment, as illustrated in FIG. 58, the planar shape of the protrusion 164 is a rectangle. More specifically, the planar shape of the protrusion 164 corresponds to a planar shape at the position of the first body surface 130a.

In the present embodiment, the protrusions 164 are located in a staggered manner. More specifically, the protrusions 164 of the convex rows 163 located next to one another in the Y direction lie at positions of being shifted from one another in the X direction. The amount of this shift may be a half of the arrangement pitch of the protrusions 164 in the X direction. The width w17 of the protrusion 164 may be, for example, 5 μm to 500 μm. The width w17 means the size of the protrusion 164 measured at the first body surface 130a. In FIG. 58, the width w17 corresponds to the Y-dimensional size of the protrusion 164. The positions of the protrusions 164 are not limited to staggered positions. An arranged-abreast layout may be adopted. In this case, the protrusions 164 of the convex rows 163 located next to one another in the Y direction lie at the same X-directional position.

By the way, the material of the first sheet 110, the second sheet 120, and the wick sheet 130 is not specifically limited as long as it has good thermal conductivity to an extent that sufficient heat dissipation efficiency as the vapor chamber 101 is ensured. For example, each sheet 110, 120, 130 may be made of a metal material. For example, each sheet 110, 120, 130 may contain copper or copper alloy. Copper and copper alloy have good thermal conductivity, and exhibit corrosion resistance for cases where pure water is used as the working fluid. Examples of copper include pure copper and oxygen-free copper (C1020). Examples of copper alloy include copper alloy containing tin, copper alloy containing titanium (C1990, etc.), Corson copper alloy (C7025, etc.), which is copper alloy containing nickel, silicon, and magnesium, and the like. Copper alloy containing tin is, for example, phosphor bronze (C5210, etc.).

The thickness t11 of the vapor chamber 101 illustrated in FIG. 46 may be, for example, 100 am to 500 μm. Configuring the thickness t11 of the vapor chamber 101 to be 100 μm or greater makes it possible to ensure an adequate space for the vapor flow channel portion 150. Therefore, the vapor chamber 101 can fulfill its function properly. On the other hand, configuring the thickness t11 to be 500 μm or less makes it possible to avoid the thickness t11 of the vapor chamber 101 from being excessive. Therefore, it is possible to make the vapor chamber 101 thin.

The thickness of the wick sheet 130 may be greater than the thickness of the first sheet 110. Similarly, the thickness of the wick sheet 130 may be greater than the thickness of the second sheet 120. In the present embodiment, an example in which the thickness of the first sheet 110 and the thickness of the second sheet 120 are equal to each other is disclosed. However, this does not imply any limitation. The thickness of the first sheet 110 and the thickness of the second sheet 120 may be different from each other.

The thickness t12 of the first sheet 110 may be, for example, 6 μm to 100 μm. Configuring the thickness t12 of the first sheet 110 to be 6 μm or greater makes it possible to ensure sufficient mechanical strength and long-term reliability of the first sheet 110. On the other hand, configuring the thickness t12 of the first sheet 110 to be 100 μm or less makes it possible to avoid the thickness t11 of the vapor chamber 101 from being excessive. The thickness t13 of the second sheet 120 may be set in the same manner as the thickness t12 of the first sheet 110.

The thickness t14 of the wick sheet 130 may be, for example, 50 μm to 400 μm. Configuring the thickness t14 of the wick sheet 130 to be 50 μm or greater makes it possible to ensure an adequate space for the vapor flow channel portion 150. Therefore, the vapor chamber 101 can fulfill its function properly. On the other hand, configuring it to be 400 μm or less makes it possible to avoid the thickness t11 of the vapor chamber 101 from being excessive. Therefore, it is possible to make the vapor chamber 101 thin. The thickness t14 of the wick sheet 130 may be the distance between the first body surface 130a and the second body surface 130b.

As illustrated in FIG. 45, the vapor chamber 101 according to the present embodiment includes the bending region 107. At the bending region 107, the vapor chamber 101 is bent along the bending line 108 extending in a direction intersecting with the X direction in a plan view. As illustrated in FIGS. 44 and 45, the bending line 108 according to the present embodiment extends in the Y direction in a plan view. The Y direction is a direction orthogonal to the X direction in a plan view. The bending line 108 traverses the frame portion 132, the land portion 133, the first vapor passage 151, and the second vapor passages 152. Because of this configuration, it is possible to suppress such deformation that the first sheet 110 intrudes into each vapor passage 151, 152 and to suppress such deformation that the second sheet 120 intrudes into each vapor passage 151, 152. It is thus possible to ensure a sufficient cross-sectional passage area of the first vapor passage 151 and the second vapor passage 152. The first region 105, the second region 106, and the bending region 107 may be demarcated by borderlines extending along the bending line 108. In the example illustrated in FIGS. 44 and 45, the regions 105, 106, and 107 may be demarcated by borderlines extending in the Y direction in a plan view.

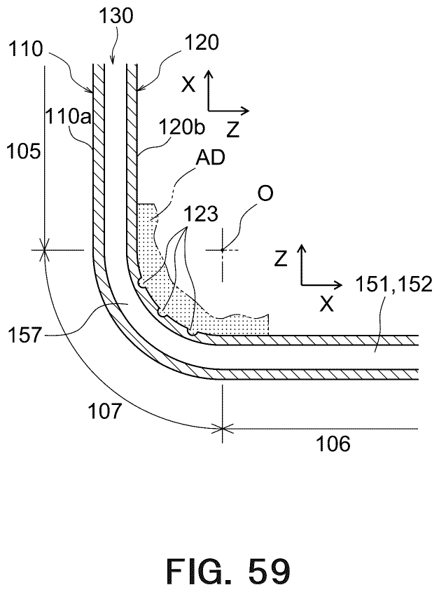

As illustrated in FIGS. 45 and 59, the second sheet outer surface recesses 123 described above are located at the bending region 107. The second sheet outer surface recesses 123 overlap with the bending line 108 when the bending region 107 is viewed from the inside or the outside of the bending.

The vapor chamber 101 is bent as illustrated in FIG. 59. The first sheet 110 is located at the outer side of the bending relative to the wick sheet 130. At the bending region 107, the first sheet 110 is located at the outer side relative to the wick sheet 130, with respect to the center O of the bending. The second sheet 120 is located at the inner side of the bending relative to the wick sheet 130. The second sheet 120 is located at the inner side relative to the wick sheet 130, with respect to the center O of the bending.

As illustrated in FIG. 59, each vapor passage 151, 152 may include a passage bending portion 157 located at the bending region 107. An example of the passage bending portion 157 is illustrated in FIG. 59. In FIG. 59, the shape of the passage bending portion 157 as viewed in the Y direction is a quarter arc; however, this does not imply any limitation. The passage bending portion 157 may include the first vapor flow channel recessed portion 153 and the second vapor flow channel recessed portion 154 described above.

Next, a method of manufacturing the vapor chamber 101 according to the present embodiment having the structure described above will now be described.

First, in a preparation process, the first sheet 110, the second sheet 120, and the wick sheet 130 are prepared. The preparation process may include a second sheet etching process of forming the second sheet 120 by etching and a wick sheet etching process of forming the wick sheet 130 by etching. In the respective etching processes, the second sheet 120 and the wick sheet 130 may be formed by etching using a patterned resist film (not illustrated) by means of a photolithography technique.

In a temporary joining process, the first sheet 110, the wick sheet 130, and the second sheet 120 are temporarily joined. For example, each sheet 110, 120, 130 may be temporarily joined using spot welding or laser welding. When this is performed, the alignment holes 112, 122, and 135 described earlier may be used for alignment of the respective sheets 110, 120, and 130.

Next, in a bonding process, the first sheet 110, the wick sheet 130, and the second sheet 120 are permanently bonded together. The sheets 110, 120, and 130 may be bonded together using diffusion bonding.

After the bonding process, in an injection process, the sealed space 103 is vacuumed, and the working liquid 102b is injected into the sealed space 103 through the injection portion 104 (see FIG. 45).

After the injection process, in a sealing process, the injection flow channel 136 described earlier is sealed. This sealing blocks communication between the sealed space 103 and the outside and thus hermetically closes the sealed space 103. Accordingly, the sealed space 103 in which the working liquid 102b is enclosed is obtained, and the leakage of the working liquid 102b contained in the sealed space 103 to the outside is prevented.

After the sealing process, in a bending process, the first sheet 110, the second sheet 120, and the wick sheet 130 may be bent. For example, each sheet 110, 120, 130 is bent along the bending line 108 extending in the Y direction as illustrated in FIG. 45. When this is performed, a jig that is not illustrated is held in contact with the second sheet outer surface 120b of the second sheet 120, which is located at the inner side of the bending. Each sheet 110, 120, 130 is bent at a desired angle, with both ends in the X direction of each sheet 110, 120, 130 gripped. By this means, the vapor chamber 101 that is bent as illustrated in FIG. 44 is obtained, and the bending region 107 of the vapor chamber 101 is formed. The bending process may be executed between the bonding process and the injection process.

In the present embodiment, the second sheet outer surface recesses 123 are formed in the second sheet outer surface 120b of the second sheet 120, which is located at the inner side of the bending. In the bending process, the vapor chamber 101 may be bent at the position where the second sheet outer surface recesses 123 are formed. The vapor chamber 101 may be bent such that the bending line 108 is along the direction in which the second sheet outer surface recesses 123 extend. The second sheet outer surface recesses 123 can be visually recognized easily and can serve as a positional mark for the bending.

When the bending is performed, a compressive stress acts on, of the second sheet 120, a second sheet cover portion 124 (see FIG. 57) covering each vapor passage 151, 152. Since the second sheet 120 is located at the inner side of the bending, the jig that is not illustrated is held in contact with the second sheet outer surface 120b of the second sheet 120. For this reason, the second sheet cover portion 124, since its deformation toward the inner side of the bending is restricted, tends to intrude into the second vapor flow channel recessed portion 154, which is located at the outer side of the bending relative to the second sheet 120. However, according to the present embodiment, the second sheet outer surface recesses 123 are formed in the second sheet outer surface 120b at the bending region 107. This makes it possible to absorb the compressive stress acting on the second sheet cover portion 124 at the time of the bending and thus to suppress the intrusion of the second sheet cover portion 124 into the second vapor flow channel recessed portion 154.

The vapor chamber 101 according to the present embodiment can be obtained as described above.

When the vapor chamber 101 obtained as described above is mounted onto the substrate S, as illustrated in FIG. 59, the adhesive AD may be used for bonding to the substrate S. The adhesive AD may be pasted to the second sheet outer surface 120b at the bending region 107. In this case, the adhesive AD enters the second sheet outer surface recesses 123. This enhances the adhesion between the vapor chamber 101 and the adhesive AD.

Next, a method of operation of the vapor chamber 101, that is, how to cool the electronic device D, will now be described.

The vapor chamber 101 obtained as described above is installed inside the housing H of a mobile terminal or the like. At the second region 106, the first sheet outer surface 110a of the first sheet 110 is in contact with the housing member Ha. At the first region 105, the second sheet outer surface 120b of the second sheet 120 is in contact with the electronic device D. The working liquid 102b contained in the sealed space 103 adheres to the wall surfaces of the sealed space 103 due to its surface tension. More specifically, the working liquid 102b adheres to the wall surface 153a of the first vapor flow channel recessed portion 153, to the wall surface 154a of the second vapor flow channel recessed portion 154, and to the wall surface 162 of each mainstream groove 161 and the wall surface of each communication groove 165 of the liquid flow channel portion 160. Moreover, the working liquid 102b could adhere also to, of the first sheet inner surface 110b of the first sheet 110, the part exposed to the first vapor flow channel recessed portion 153. Furthermore, the working liquid 102b could adhere also to, of the second sheet inner surface 120a of the second sheet 120, the part exposed to the second vapor flow channel recessed portion 154, the part exposed to the mainstream grooves 161, and the part exposed to the communication grooves 165.

When the electronic device D generates heat in this state, the working liquid 102b present at the vaporization region SR receives the heat from the electronic device D. The working liquid 102b vaporizes by absorbing the received heat as latent heat, and the working vapor 102a is thus generated. The working vapor 102a having been generated diffuses inside the first vapor passage 151 and the second vapor passages 152 that constitute the sealed space 103 (see solid-line arrows in FIG. 55). More specifically, the working vapor 102a diffuses mainly in the X direction at, of the first vapor passage 151 of the vapor flow channel portion 150, the part extending in the X direction, and at the second vapor passages 152 thereof. In this case, a part of the working vapor 102a diffuses through the passage bending portion 157. On the other hand, the working vapor 102a diffuses mainly in the Y direction at, of the first vapor passage 151, the part extending in the Y direction.

Then, the working vapor 102a present in each vapor passage 151, 152 flows away from the vaporization region SR to the condensation region CR where the temperature is relatively low. At the condensation region CR, the working vapor 102a cools by releasing the heat to, mainly, the first sheet 110. The heat received by the first sheet 110 from the working vapor 102a is transferred to outside air via the housing member Ha (see FIG. 46).

By releasing the heat to the first sheet 110 at the condensation region CR, the working vapor 102a loses the latent heat absorbed at the vaporization region SR. This causes the condensation of the working vapor 102a, and the working liquid 102b is thus generated. The working liquid 102b having been generated adheres to the wall surface 153a, 154a of each vapor flow channel recessed portion 153, 154, to the first sheet inner surface 110b of the first sheet 110, and to the second sheet inner surface 120a of the second sheet 120. Meanwhile the working liquid 102b keeps vaporizing at the vaporization region SR. Therefore, the working liquid 102b present at the condensation region CR of the liquid flow channel portion 160 flows toward the vaporization region SR due to capillary action of each of the mainstream grooves 161 (see broken-line arrows in FIG. 55). Therefore, the working liquid 102b adhering to each wall surface 153a, 154a, the first sheet inner surface 110b, and the second sheet inner surface 120a moves to the liquid flow channel portion 160 and enters the mainstream grooves 161 through the communication grooves 165. In this way, each of the mainstream grooves 161 and each of the communication grooves 165 become filled with the working liquid 102b. The working liquid 102b having filled them up obtains a motive force for going toward the vaporization region SR due to capillary action of each of the mainstream grooves 161 and is thus sent smoothly toward the vaporization region SR. Even in a case where the vaporization region SR is located at an upper portion of the vapor chamber 101 as illustrated in FIG. 44, the working liquid 102b is sent due to the capillary action.

At the liquid flow channel portion 160, each mainstream groove 161 is in communication with another mainstream groove 161 located next thereto via the corresponding communication grooves 165. This enables the working liquid 102b to transfer from one to the other of the mainstream grooves 161 located next to each other, thereby suppressing the occurrence of “dry out” in the mainstream grooves 161. Therefore, a capillary force is applied to the working liquid 102b present in each of the mainstream grooves 161; accordingly, the working liquid 102b is sent smoothly toward the vaporization region SR.

The working liquid 102b having reached the vaporization region SR vaporizes by receiving heat from the electronic device D again. The working vapor 102a having turned from the working liquid 102b due to evaporation flows through the communication grooves 165 inside the vaporization region SR to move to the first vapor flow channel recessed portion 153 and the second vapor flow channel recessed portion 154, the cross-sectional passage area of which is larger. Then, the working vapor 102a diffuses inside each vapor flow channel recessed portion 153, 154. A part of the working vapor 102a can diffuse through the passage bending portion 157. In this way, the working fluid 102a, 102b circulates inside the sealed space 103 while repeating phase changes, that is, vaporization and condensation. By this means, the heat of the electronic device D diffuses and dissipates. The electronic device D is cooled as a result of this heat release.

As described above, according to the present embodiment, the second sheet outer surface recess 123 is located in the second sheet outer surface 120b of the second sheet 120 at the bending region 107. By this means, when the vapor chamber 101 is bent, it is possible to absorb a stress acting on the second sheet 120 and thus to suppress the intrusion of the second sheet 120 into the first vapor passage 151 or the second vapor passage 152 at the bending region 107. Therefore, it is possible to ensure a sufficient cross-sectional passage area of the first vapor passage 151 and the second vapor passage 152 and thus to suppress obstruction to the flow of the working vapor 102a at the bending region 107. Consequently, it is possible to improve the heat dissipation efficiency of the vapor chamber 101 even when bent. Moreover, the second sheet outer surface recess 123 can be visually recognized easily and can therefore serve as a mark of the bending position of the vapor chamber 101 before being bent. Therefore, it is possible to improve the performance of bending work.

According to the present embodiment, the second sheet 120 is located at the inner side relative to the wick sheet 130. Therefore, when the vapor chamber 101 is bent, it is possible to absorb a compressive stress acting on the second sheet 120 by means of the second sheet outer surface recess 123. For this reason, it is possible to suppress the intrusion of the second sheet 120 into the first vapor passage 151 or the second vapor passage 152 at the bending region 107.

According to the present embodiment, the second sheet outer surface recess 123 extends along the bending line 108 and traverses the first vapor passage 151 or the second vapor passage 152. By this means, when the vapor chamber 101 is bent, it is possible to absorb a stress acting on the second sheet 120 effectively and thus to further suppress the intrusion of the second sheet 120 into the first vapor passage 151 or the second vapor passage 152 at the bending region 107. Moreover, it is possible to bend the vapor chamber 101 along the bending line 108 easily.

According to the present embodiment, a plurality of second sheet outer surface recesses 123 is located in the second sheet outer surface 120b at the bending region 107. These plural second sheet outer surface recesses 123 are arranged in the X direction. By this means, when the vapor chamber 101 is bent, it is possible to absorb a stress acting on the second sheet 120 effectively and thus to further suppress the intrusion of the second sheet 120 into the first vapor passage 151 or the second vapor passage 152. Moreover, it is possible to bend the vapor chamber 101 along the bending line 108 easily.

According to the present embodiment, the bending line 108 extends in the Y direction, which is orthogonal to the X direction. This makes it easier to bend the vapor chamber 101 in the direction orthogonal to the X direction, in which the lands 133 extend. Therefore, at the bending region 107, it is possible to suppress such deformation that the first sheet 110 intrudes into each vapor passage 151, 152 and to suppress such deformation that the second sheet 120 intrudes into each vapor passage 151, 152. Therefore, it is possible to ensure a sufficient cross-sectional passage area of the first vapor passage 151 and the second vapor passage 152 and thus to suppress obstruction to the flow of the working vapor 102a at the bending region 107.

Having been described in the present embodiment above is an example in which no liquid flow channel portion is formed in the second body surface 130b of the land portion 133 and the second body surface 130b of the frame portion 132. However, this does not imply any limitation. For example, a liquid flow channel portion that is not illustrated may be formed in the second body surface 130b of the land portion 133. Similarly to the liquid flow channel portion 160 described above, the liquid flow channel portion may include mainstream grooves 161 and communication grooves 165. The cross-sectional passage area of a groove of the liquid flow channel portion formed in the second body surface 130b may be equal to the cross-sectional passage area of a groove of the liquid flow channel portion 160; alternatively, the former may be greater than the latter. In a case where the liquid flow channel portion is formed in the second body surface 130b, the liquid flow channel portion 160 may be absent in the first body surface 130a.

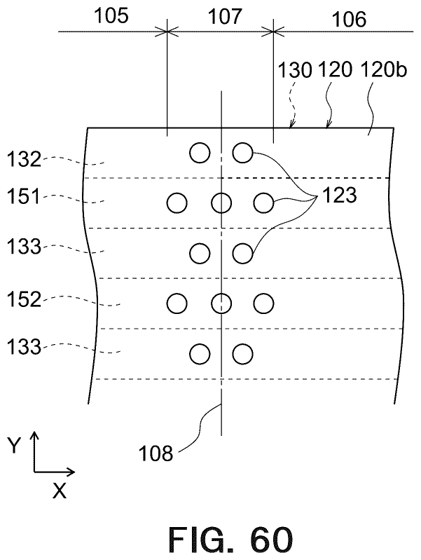

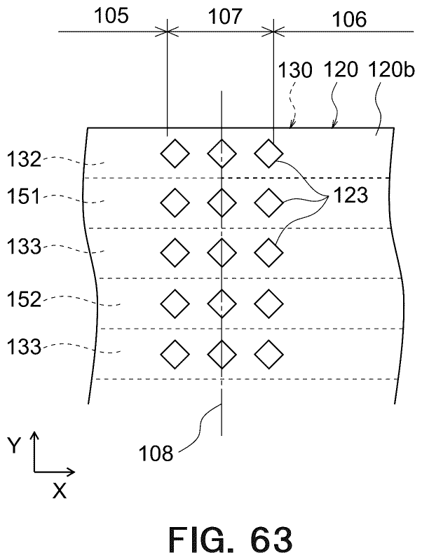

Having been described in the present embodiment above is an example in which the second sheet outer surface recess 123 extends in the Y direction. However, this does not imply any limitation. For example, as illustrated in FIG. 60, the plural second sheet outer surface recesses 123 may be arranged along the bending line 108, and may be arranged in the Y direction. The second sheet outer surface recesses 123 located next to one another are spaced apart from one another. The second sheet outer surface recesses 123 are arranged to form a staggered layout in the example illustrated in FIG. 60, but may be arranged to form a grid layout (see FIG. 63). Any layout of the second sheet outer surface recesses 123 may be adopted.

Among the plurality of second sheet outer surface recesses 123, some second sheet outer surface recesses 123 may overlap with the first vapor passage 151 or the second vapor passages 152 in a plan view. The rest of the second sheet outer surface recesses 123 may be non-overlapping with the first vapor passage 151 or the second vapor passages 152 in a plan view. Alternatively, all of the second sheet outer surface recesses 123 may overlap with the first vapor passage 151 or the second vapor passages 152 in a plan view. In the example illustrated in FIG. 60, the second sheet outer surface recesses 123 overlap with the lands 133, the frame portion 132, and the vapor passages 151 and 152.

Also in the example illustrated in FIG. 60, when the vapor chamber 101 is bent, it is possible to absorb a stress acting on the second sheet 120 and thus to suppress the intrusion of the second sheet 120 into the first vapor passage 151 or the second vapor passage 152 at the bending region 107. Moreover, in the example illustrated in FIG. 60, since the second sheet outer surface recesses 123 located next to one another are spaced apart from one another, it is possible to suppress a decrease in mechanical strength of the vapor chamber 101 in a particular direction.

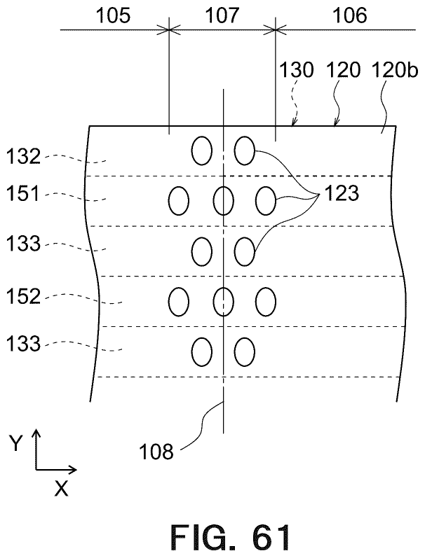

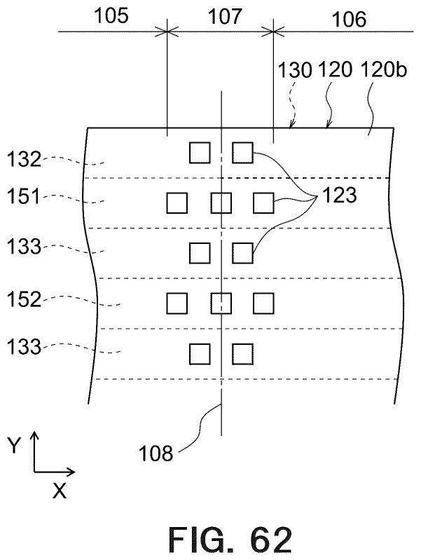

In the example illustrated in FIG. 60, the second sheet outer surface recess 123 has a circular shape in a plan view. However, the planar shape of the second sheet outer surface recess 123 may be any shape. For example, as illustrated in FIG. 61, the second sheet outer surface recess 123 may have an elliptical shape in a plan view. In another example, as illustrated in FIG. 62, the second sheet outer surface recess 123 may have a quadrangular shape in a plan view. As illustrated in FIG. 63, in a case where the second sheet outer surface recess 123 has a quadrangular shape in a plan view, the second sheet outer surface recesses 123 may be arranged such that each side of the quadrangle is inclined with respect to the X direction and the Y direction and such that opposed corners of the quadrangles lie along the bending line 108. In the example illustrated in FIG. 63, the second sheet outer surface recesses 123 are in a grid layout of arrangement. The second sheet outer surface recess 123 and the bending line 108 may extend in a direction inclined with respect to the X direction in a plan view.

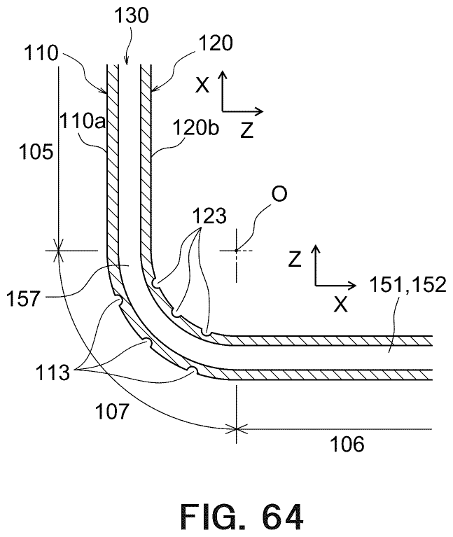

Having been described in the present embodiment above is an example in which the second sheet outer surface recesses 123 are located in the second sheet outer surface 120b of the second sheet 120 at the bending region 107. However, this does not imply any limitation. For example, as illustrated in FIG. 64, first sheet outer surface recesses 113 may be located in the first sheet outer surface 110a of the first sheet 110 at the bending region 107. In this case, when the vapor chamber 101 is bent, it is possible to absorb a tensile stress acting on the first sheet 110 and thus to suppress the intrusion of the first sheet 110 into the first vapor passage 151 or the second vapor passage 152 at the bending region 107.

The first sheet outer surface recesses 113 can be formed in the same manner as the second sheet outer surface recesses 123. As illustrated in FIG. 64, the first sheet outer surface recesses 113 may be formed in the first sheet outer surface 110a, and the second sheet outer surface recesses 123 may be formed in the second sheet outer surface 120b. Alternatively, though not illustrated, the first sheet outer surface recesses 113 may be formed in the first sheet outer surface 110a, and the second sheet outer surface recesses 123 may be absent in the second sheet outer surface 120b. The second sheet 120, with the second sheet outer surface recesses 123 formed therein, may be disposed at the outer side of the bending, and the first sheet 110, with the first sheet outer surface recesses 113 not formed therein, may be disposed at the inner side of the bending.

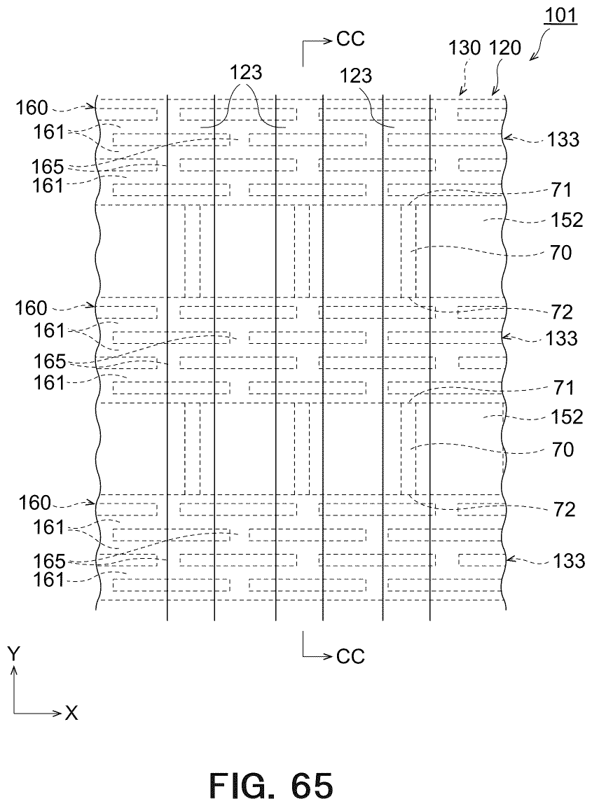

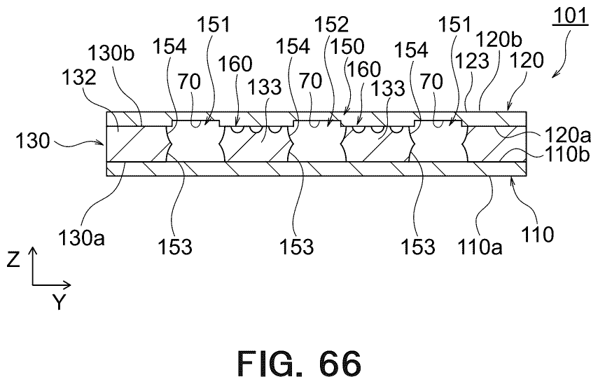

In the present embodiment described above, as illustrated in FIGS. 65 and 66, the sheet grooves 70, 80 such as those described earlier in the first to fourteenth embodiments may be provided. In the example illustrated in FIGS. 65 and 66, the sheet grooves 70 are provided in the second sheet inner surface 120a of the second sheet 120. As illustrated in FIGS. 65 and 66, the sheet grooves 70 may be provided at positions of overlapping with the vapor passages 151 and 152 and the second sheet outer surface recesses 123 in a plan view. The sheet grooves 70 may be absent at positions of not overlapping with the vapor passages 151 and 152, for example, positions of overlapping with the lands 133, in a plan view. In the example illustrated in FIG. 65, the first end 71 of the sheet groove 70 overlaps with the edge on the negative side in the Y direction (the lower edge in FIG. 65) of the land 133 in a plan view, and the second end 72 of the sheet groove 70 overlaps with the edge on the positive side in the Y direction (the upper edge in FIG. 65) of the land 133 in a plan view. Moreover, as illustrated in FIG. 65, the sheet grooves 70 may be absent at positions of not overlapping with the second sheet outer surface recesses 123 in a plan view. Thanks to the sheet grooves 70 described above, when the vapor chamber 101 is bent, it is possible to further absorb a stress acting on the second sheet 120 and thus to further suppress the intrusion of the second sheet 120 into the first vapor passage 151 or the second vapor passage 152 at the bending region 107.

In the example illustrated in FIGS. 65 and 66, the sheet grooves 70 are not provided at positions of not overlapping with the second sheet outer surface recesses 123 in a plan view. However, the sheet grooves 70 may be provided also at positions of not overlapping with the second sheet outer surface recesses 123 in a plan view. In this case, since the working vapor 102a is prone to condensation at the bending region 107, and since the working liquid 102b is likely to be generated thereat, it is possible to cause the working liquid 102b generated due to condensation to move to the liquid flow channel portion 160 quickly through the capillary action of the sheet grooves 70 and to further suppress an increase in flow channel resistance.

### Sixteenth Embodiment

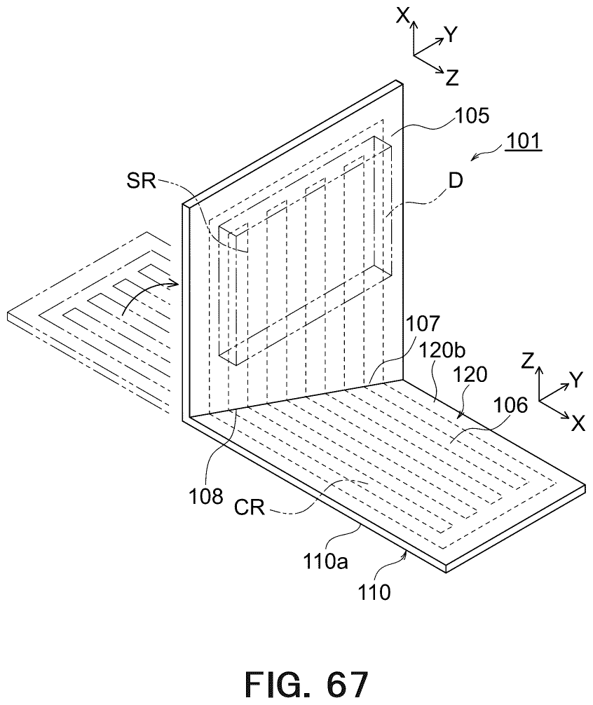

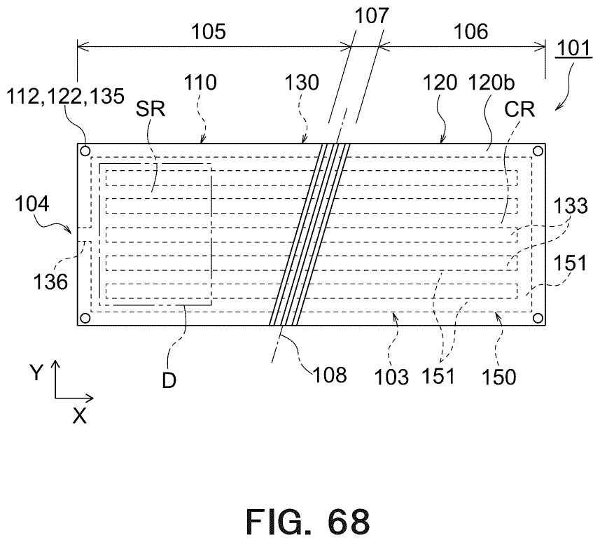

Next, a vapor chamber and an electronic apparatus according to a sixteenth embodiment of the present disclosure will now be described with reference to FIGS. 67 and 68.

In the sixteenth embodiment illustrated in FIGS. 67 and 68, the main difference lies in that the bending line extends in a direction inclined with respect to the first direction. Except for this difference, the configuration of this embodiment is substantially the same as that of the fifteenth embodiment illustrated in FIGS. 42 to 66. In FIGS. 67 and 68, the same reference signs are assigned to portions that are the same as those of the fifteenth embodiment illustrated in FIGS. 42 to 66, and a detailed explanation thereof is omitted.

As illustrated in FIGS. 67 and 68, the vapor chamber 101 according to the present embodiment is bent along the bending line 108 inclined with respect to the X direction in a plan view. The bending line 108 illustrated in FIGS. 67 and 68 extends in a direction inclined with respect to the X direction and inclined with respect to the Y direction. The bending line 108 according to the present embodiment also extends in a direction intersecting with the X direction in a plan view.

As illustrated in FIG. 68, each of the second sheet outer surface recesses 123 extends in a direction inclined with respect to the X direction in a plan view. Also in this case, the second sheet outer surface recess 123 intersects with the X direction. The second sheet outer surface recesses 123 may be arranged in the X direction, and may be spaced at equal intervals in the X direction. The second sheet outer surface recesses 123 may be located in parallel with one another.

As described above, according to the present embodiment, the bending line 108 extends in a direction inclined with respect to the X direction. By this means, even when the vapor chamber 101 is bent along the bending line 108 extending in a direction inclined with respect to the X direction, it is possible to suppress the intrusion of the second sheet 120 into the first vapor passage 151 or the second vapor passage 152 at the bending region 107. Therefore, it is possible to ensure a sufficient cross-sectional passage area of the first vapor passage 151 and the second vapor passage 152 and thus to suppress obstruction to the flow of the working vapor 102a at the bending region 107. Consequently, it is possible to improve the heat dissipation efficiency of the vapor chamber 101 even when bent.

Having been described in the present embodiment above is an example in which the second sheet outer surface recess 123 extends in a direction inclined with respect to the X direction in a plan view. However, this does not imply any limitation. For example, the plural second sheet outer surface recesses 123 may be arranged along the bending line 108, and may be arranged in a direction inclined with respect to the X direction. In this case, the second sheet outer surface recesses 123 may be formed in the same manner as in the examples illustrated in FIGS. 60 to 63.

### Seventeenth Embodiment

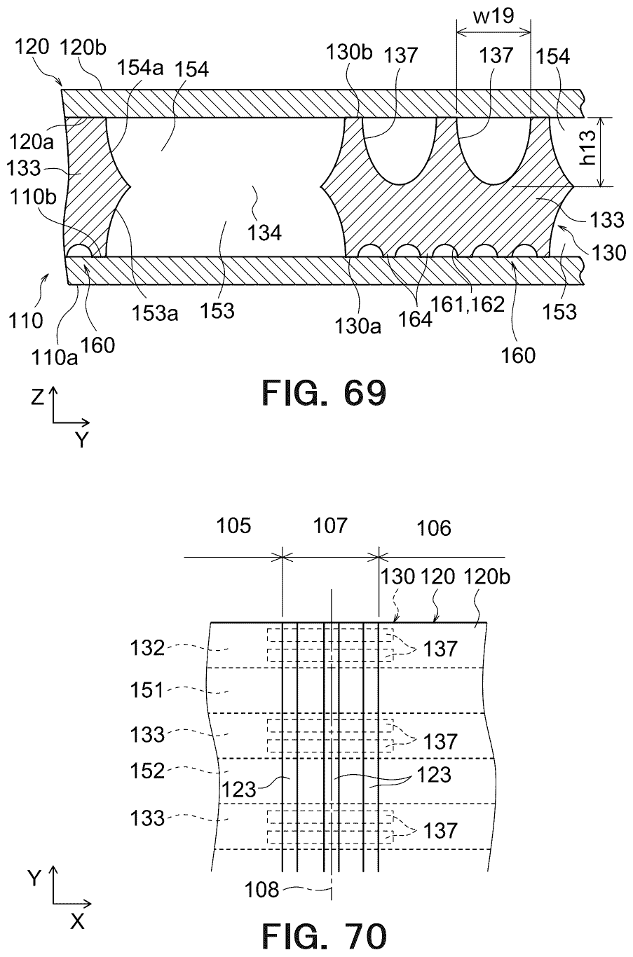

Next, a vapor chamber and an electronic apparatus according to a seventeenth embodiment of the present disclosure will now be described with reference to FIGS. 69 and 70.

In the seventeenth embodiment illustrated in FIGS. 69 and 70, the main difference lies in that land recesses are located in the first body surface or the second body surface of the land portion. Except for this difference, the configuration of this embodiment is substantially the same as that of the fifteenth embodiment illustrated in FIGS. 42 to 66. In FIGS. 69 and 70, the same reference signs are assigned to portions that are the same as those of the fifteenth embodiment illustrated in FIGS. 42 to 66, and a detailed explanation thereof is omitted.

In the vapor chamber 101 according to the present embodiment, as illustrated in FIG. 69, land recesses 137 are formed in the second body surface 130b of the land portion 133. The land recesses 137 are not in communication with the vapor passages 151 and 152. Nor are the land recesses 137 in communication with the mainstream grooves 161 and the communication grooves 165 of the liquid flow channel portion 160. As described above, the liquid flow channel portion 160 is located in the first body surface 130a of the land portion 133, and the land recesses 137 are formed in the second body surface 130b located at the opposite side facing away from the liquid flow channel portion 160. The liquid flow channel portion 160 may be formed in either one of the first body surface 130a and the second body surface 130b of the land portion 133, and the land recesses 137 may be formed in the other thereof. For example, in a case where the liquid flow channel portion 160 is located in the second body surface 130b of the land portion 133, the land recesses 137 may be formed in the first body surface 130a of the land portion 133.

As illustrated in FIG. 70, the land recess 137 overlaps with the second sheet outer surface recess 123 in a plan view. In other words, when the bending region 107 is viewed from the inner side or the outer side of the bending, the land recess 137 overlaps with the second sheet outer surface recess 123.

The land recess 137 is located at the bending region 107. The land recess 137 is formed in a recessed manner in the second body surface 130b and may be formed like a groove.

The land recess 137 extends in the X direction. The land recess 137 intersects with the second sheet outer surface recesses 123. The land recess 137 may extend to both sides in the X direction beyond the second sheet outer surface recesses 123.

The land recess 137 may be formed in each of the lands 133. A plurality of land recesses 137 may be formed in one land 133. The land recesses 137 may be arranged along the second sheet outer surface recess 123 and the bending line 108, and may be arranged in the Y direction. The land recesses 137 may be located in parallel with one another. The land recesses 137 may be formed in the frame portion 132.

The land recesses 137 are formed by performing etching from the second body surface 130b of the wick sheet 130 in the wick sheet etching process described above. Due to this etching, as illustrated in FIG. 69, the land recess 137 may have a wall surface that is curved. This wall surface may demarcate the land recess 137 and may be curved in such a way as to arch toward the first body surface 130a.

As illustrated in FIG. 69, the width w19 of the land recess 137 may be, for example, 50 μm to 150 μm. The width w19 means the size of the land recess 137 measured at the second body surface 130b. The width w19 corresponds to the Y-dimensional size of the land recess 137. The depth h13 of the land recess 137 may be, for example, 20 μm to 120 μm. The depth h13 corresponds to the Z-dimensional size of the land recess 137.

As described above, according to the present embodiment, the land recesses 137 that are not in communication with the vapor passages 151 and 152 are located in the second body surface 130b of the land portion 133, and the land recesses 137 overlap with the second sheet outer surface recesses 123. This makes it possible to reduce the rigidity of the land portion 133 at the bending region 107. Therefore, it is possible to bend the land portion 133 easily at the time of bending the vapor chamber 101.

According to the present embodiment, the land recess 137 extends to both sides in the X direction beyond the second sheet outer surface recesses 123. This makes it possible to reduce the rigidity of the land portion 133 in the neighborhood of the second sheet outer surface recesses 123, too. Therefore, it is possible to bend the land portion 133 more easily at the time of bending the vapor chamber 101.

Having been described in the present embodiment above is an example in which the second sheet outer surface recess 123 and the bending line 108 extend in the Y direction in a plan view. However, this does not imply any limitation. For example, the second sheet outer surface recess 123 may extend in a direction inclined with respect to the X direction in a plan view. As illustrated in FIGS. 67 and 68, the second sheet outer surface recess 123 and the bending line 108 may extend in a direction inclined with respect to the X direction in a plan view. Also in this case, the land recesses 137 formed in each of the lands 133 may overlap with the second sheet outer surface recesses 123, and they may be arranged along the second sheet outer surface recess 123 and the bending line 108.

The present invention shall not be construed to be limited in its scope to the foregoing embodiments and the variation examples as they are, and can be embodied in a specific manner in the phase of practical implementation, with modifications of constituting elements, within a range of not departing from its spirit. Various inventions can be formulated through appropriate combination of a plurality of constituting elements disclosed in the foregoing embodiments and the variation examples. Some of all constituting elements disclosed in the foregoing embodiments and the variation examples may be deleted from among them.

1.-21. (canceled)

22. A vapor chamber in which a working fluid is enclosed, comprising:
a body sheet; and
a first sheet stacked on the body sheet, wherein
the body sheet includes a vapor flow channel portion through which vapor of the working fluid flows and a liquid flow channel portion which is in communication with the vapor flow channel portion and through which liquid of the working fluid flows,
the vapor flow channel portion includes a vapor passage extending in a first direction, and
the first sheet includes a first sheet inner surface facing the body sheet and a first sheet groove provided in the first sheet inner surface, the first sheet groove is provided at a position of overlapping with the vapor passage in a plan view and extends in a direction intersecting with the first direction.

23. The vapor chamber according to claim 22, wherein
the liquid flow channel portion includes a liquid flow channel mainstream groove extending in the first direction, and
a cross-sectional passage area of the first sheet groove is smaller than a cross-sectional passage area of the liquid flow channel mainstream groove.

24. The vapor chamber according to claim 22, wherein
the liquid flow channel portion includes a liquid flow channel mainstream groove extending in the first direction, and
a cross-sectional passage area of the first sheet groove is larger than a cross-sectional passage area of the liquid flow channel mainstream groove.

25. The vapor chamber according to claim 22, wherein
the first sheet groove is provided also over a position of overlapping with the liquid flow channel portion in a plan view.

26. The vapor chamber according to claim 25, wherein
the first sheet groove is provided so as to traverse the vapor passage in the direction intersecting with the first direction.

27. The vapor chamber according to claim 22, wherein
the body sheet includes a first body surface facing the first sheet inner surface and a second body surface located at a side opposite of the first body surface, and
the liquid flow channel portion is provided in the first body surface.

28. The vapor chamber according to claim 27, further comprising:
a second sheet stacked on the second body surface of the body sheet, wherein
the liquid flow channel portion is provided also in the second body surface, and
the second sheet includes a second sheet inner surface facing the second body surface and a second sheet groove provided in the second sheet inner surface, the second sheet groove is provided at a position of overlapping with the vapor passage in a plan view and extends in the direction intersecting with the first direction.

29. The vapor chamber according to claim 22 including a depressed region where the first sheet is depressed toward the vapor passage, and
the first sheet groove is located at the depressed region.

30. The vapor chamber according to claim 22 including a bending region where the vapor chamber is bent along a bending line, and
the first sheet groove is located at the bending region.

31. An electronic apparatus, comprising:
a housing;
a device housed in the housing, and
the vapor chamber according to claim 22, said vapor chamber being thermally in contact with the device.

32. A vapor chamber in which a working fluid is enclosed, comprising:
a body sheet including a first body surface and a second body surface located at a side opposite of the first body surface;
a first sheet located at the first body surface of the body sheet;
a second sheet located at the second body surface of the body sheet; and
a space portion provided in the body sheet and covered by the first sheet and the second sheet, wherein
the body sheet includes a plurality of lands located inside the space portion and extending in a first direction,
the second sheet includes a second sheet outer surface located at an opposite side facing away from the body sheet,
the vapor chamber includes a bending region where the vapor chamber is bent along a bending line extending in a direction intersecting with the first direction in a plan view, and
a second sheet outer surface recess is located in the second sheet outer surface at the bending region.

33. The vapor chamber according to claim 32, wherein
the second sheet is located at an inner side of a bending relative to the body sheet.

34. The vapor chamber according to claim 32, wherein
the second sheet outer surface recess extends along the bending line and traverses the space portion.

35. The vapor chamber according to claim 34, wherein
a plurality of second sheet outer surface recesses is located in the second sheet outer surface at the bending region, and
the plural second sheet outer surface recesses are arranged in the first direction.

36. The vapor chamber according to claim 32, wherein
a plurality of second sheet outer surface recesses is located in the second sheet outer surface at the bending region,
the plural second sheet outer surface recesses are arranged along the bending line, and
at least some of the plural second sheet outer surface recesses overlap with the space portion.

37. The vapor chamber according to claim 32, wherein
the bending line extends in a direction orthogonal to the first direction in a plan view.

38. The vapor chamber according to claim 32, wherein
the bending line extends in a direction inclined with respect to the first direction.

39. The vapor chamber according to claim 32, wherein
the first sheet includes a first sheet outer surface located at an opposite side facing away from the body sheet, and
a first sheet outer surface recess is located in the first sheet outer surface at the bending region.

40. An electronic apparatus, comprising:
a housing;
a device housed in the housing, and
the vapor chamber according to claim 32, said vapor chamber being thermally in contact with the device.

41. A vapor chamber in which a working fluid is enclosed, comprising:
a body sheet including a first body surface and a second body surface located at a side opposite of the first body surface;
a first sheet located at the first body surface of the body sheet;
a second sheet located at the second body surface of the body sheet; and
a space portion provided in the body sheet and covered by the first sheet and the second sheet, wherein
the body sheet includes a plurality of lands located inside the space portion and extending in a first direction,
the second sheet includes a second sheet outer surface located at an opposite side facing away from the body sheet,
the vapor chamber is divided into a first region, a second region, and a third region located between the first region and the second region in the first direction, and
a second sheet outer surface recess is located in the second sheet outer surface at the third region.

42. The vapor chamber according to claim 41, wherein
the second sheet outer surface recess extends in a direction intersecting with the first direction in a plan view, and traverses the space portion.

43. The vapor chamber according to claim 41, wherein
a plurality of second sheet outer surface recesses is located in the second sheet outer surface at the third region,
the plural second sheet outer surface recesses are arranged in the direction intersecting with the first direction, and
at least some of the plural second sheet outer surface recesses overlap with the space portion.

44. An electronic apparatus, comprising:
a housing;
a device housed in the housing, and
the vapor chamber according to claim 41, said vapor chamber being thermally in contact with the device.
